(19) United States
(12) Patent Application Publication
(10) Pub. No.: US 2010/0219397 A1
(43) Pub. Date: Sep. 2, 2010

(54) TRANSITION METAL COMPLEX COMPOUND AND ORGANIC ELECTROLUMINESCENT DEVICE USING SAME

(75) Inventors: Masami Watanabe, Chiba (JP); Masahide Matsuura, Chiba (JP); Hideaki Nagashima, Chiba (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Idemitsu Kosan Co., Ltd., Chiyoda-ku (JP)

(21) Appl. No.: 11/997,931

(22) PCT Filed: Jul. 31, 2006
(86) PCT No.: PCT/JP2006/315163

§ 371 Date: Mar. 14, 2008

(30) Foreign Application Priority Data
Aug. 5, 2005 (JP) 2005-228007
Jan. 27, 2006 (JP) 2006-019776

(51) Int. Cl. H01L 51/52; H01L 51/54; C07F 15/00

(52) U.S. Cl. 257/40; 548/103; 257/E51.022; 257/E51.026

(57) ABSTRACT

Disclosed is a transition metal complex compound having a specific structure including a crosslinked stricture. Further, disclosed is an organic electroluminescence device including an organic thin film formed of one or more layers including at least a light-emitting layer, the organic thin film layer being interposed between a pair of electrodes. In this organic electroluminescence device, at least one layer of the organic thin film contains the transition metal complex compound and has high luminous efficiency and emits blue light. In addition, disclosed is the transition metal complex compound enables to realize the organic electroluminescence device.

### TECHNICAL FIELD

The present invention relates to a transition metal complex compound and an organic electroluminescence device using the same, in particular, an organic electroluminescence device having high luminous efficiency and emitting blue light, and a novel transition metal complex compound for realizing the organic electroluminescence device.

### BACKGROUND ART

An organic electroluminescence (EL) device is a spontaneous light emitting device which utilizes a principle that a fluorescent substance emits light by energy of recombination of holes injected from an anode and electrons injected from a cathode when an electric field is applied. Since an organic EL device of a laminate type driven under low electric voltage was reported by C. W. Tang et al. of Eastman Kodak Co. (for example, C. W. Tang and S. A. Vanslyke, Applied Physics Letters, Volume 51, P. 913, 1987), many studies have been conducted on organic EL devices using organic materials as constituting components. Tang et al. used tris(8-hydroxy quinolinol aluminum) for a light emitting layer and a triphenyldiamine derivative for a hole transporting layer. Advantages of the laminate structure include that the efficiency of hole injection into the light emitting layer can be increased, the efficiency of forming exciton which are formed by blocking and recombining electrons injected from the cathode can be increased, and exciton formed within the light emitting layer can be enclosed therein. For the structure of the organic EL device as in the example, a two-layered structure having a hole transporting (injecting) layer and an electron transporting and light emitting layer, a three-layered structure having a hole transporting (injecting) layer, a light emitting layer, and an electron transporting (injecting) layer, and the like are well known. To increase the efficiency of recombination of injected holes and electrons in the devices having such the laminate type structures, the structure of the device and a process for forming the device have been modified.

Known examples of the light emitting material of an organic EL device include: chelate complexes such as a tris(8-quinolinolato)aluminum complex; coumarin derivatives; tetraphenylbutadiene derivatives; distyrylarylene derivatives; and oxadiazole derivatives. It has been reported that light in a visible region ranging from a blue color to a red color can be emitted from each of those light emitting materials, so the realization of a color display device is expected (see, for example, Patent Document 1, Patent Document 2, and Patent Document 3).

In addition, in recent years, there has also been proposed that a phosphorescent material as well as a fluorescent material is used in the light emitting layer of the organic EL device (see, for example, Non-patent Document 1 and Non-patent Document 2). In this way, high luminous efficiency is achieved by utilizing a singlet state and a triplet state in excited states of the phosphorescent material in the light emitting layer of the organic EL device. When an electron and a hole recombine in the organic EL device, singlet excitons and triplet excitons are considered to be produced at a ratio of 1:3 owing to a difference in spin multiplicity. Accordingly, the use of a phosphorescent light emitting material is considered to achieve luminous efficiency three to four times that of a device using only the fluorescent material.

A constitution in which layers are sequentially laminated, for example, an anode, a hole transporting layer, an organic light emitting layer, an electron transporting layer (hole inhibiting layer), an electron transporting layer, and a cathode in the stated order has been used in the organic EL device in order that a triplet excited state or a triplet exciton does not quench. A host compound and a phosphorescent compound have been used in the organic light emitting layer (see, for example, Patent Document 4 and Patent Document 5). Those patent documents relate to technologies each concerning a phosphorescent material emitting light having a color ranging from a red color to a green color. A technology concerning a light emitting material having a blue-based luminescent color has also been disclosed (see, for example, Patent Document 6, Patent Document 7, and Patent Document 8). However, a device using any one of those materials has an extremely short lifetime. In particular, Patent Documents 7 and 8 each describe a ligand skeleton in which an Ir metal and a phosphorus atom are bonded to each other. The ligand skeleton described in each of those documents turns a luminescent color into a blue color, but a bonding force between the metal and the atom is so weak that the ligand skeleton is remarkably poor in heat resistance. Patent Document 9 similarly describes a complex in which an oxygen atom and a nitrogen atom are bonded to a central metal, but has no description concerning a specific effect of a group to be bonded to the oxygen atom, so the effect is unclear. Patent Document 10 discloses a complex in which nitrogen atoms in different ring structures are bonded one by one to a central metal. A device using the complex emits blue light, but has an external quantum efficiency as low as around 5%.

Meanwhile, research has been conducted on a transition metal complex compound having a metal carbene bond (which may hereinafter be referred to as “carbene complex”) in recent years (see, for example, Patent Documents 11 and Non-patent Documents 3 to 11).

The term “carbene” refers to dicoordination carbon having two electrons in a sp² hybrid orbital or a 2p orbital. The carbene can take four kinds of structures depending on a combination of an orbital which the two electrons enter and the orientation of a spin. The carbene is typically singlet carbene formed of a sp² hybrid, occupied orbital, and an empty 2p orbital.

A carbene complex, which has a short lifetime and is unstable, has been conventionally used as a synthesis conversion agent to be added to a reaction intermediate or olefin of an organic synthesis reaction. In about 1991, a stable carbene complex formed of a heteroaromatic ring structure and a stable carbene complex formed of a non-aromatic ring structure were found. Further, after that, it has been found that a non-cyclic carbene complex can be stably obtained by stabilization with nitrogen and phosphorus. In addition, the performance of a catalyst can be improved by bonding the non-cyclic carbene complex as a ligand to a transition metal. Accordingly, in a catalytic reaction in organic synthesis, expectations on a stable carbene complex have been raised in recent years.

In particular, in an olefin metathesis reaction, the addition or coordination of a stable carbene complex has been found to improve the performance of a catalyst significantly. In addition, researches on, for example, an improvement in efficiency of a Suzuki coupling reaction, the oxidation or selective hydroformylation reaction of an alkane, and an optically active carbene complex have been developed in recent years. Accordingly, the application of a carbene complex to the field of organic synthesis has been attracting attention.

In addition, specific examples of a complex having a carbene iridium bond are described in Non-patent Document 12 (tris(carbene) iridium complex formed of a non-heterocyclic carbene ligand) and Non-patent Document 13 (monodentate monocarbene iridium complex) to be described below. However, none of the documents describes the application of those complexes to, for example, the field of an organic EL device.

In addition, Patent Document 11 discloses the synthesis of an iridium complex having a carbene bond, the luminous wavelength of the complex, and the performance of a device using the complex. However, the complex has low energy efficiency and low external quantum efficiency, and its luminous wavelength is distributed to an ultraviolet region, so the complex has poor luminous efficiency. Therefore, the complex is not suitable for a light emitting device emitting light having a wavelength in a visible region, such as an organic EL. In addition, the complex cannot be used in vacuum deposition because of, for example, its low decomposition temperature and its large molecular weight, and the complex decomposes upon vapor deposition, so the complex involves a problem in that an impurity is mixed upon production of a device.

Further, Patent Documents 12 to 20 describe various complexes each having a carbene bond, and each disclose a blue light emitting complex. However, the energy efficiency and external quantum efficiency of the blue light emitting complex are low, and none of the documents mentions an increase in emission lifetime.

Meanwhile, Patent Documents 21 and 22 each disclose, as a method of increasing the lifetime of a tris(2-phenylpyridine-N, C²)iridium complex, the crosslinking of three 2-phenylpyridine-N, C² group sites in a tripod manner. However, the documents each report only a tripod crosslinked site having a benzene ring skeleton, so none of the documents has achieved a significant increase in lifetime of the complex. In addition, none of the documents describes a guideline for the emission of blue light.

Patent Document 1: JP-A-08-239655

Patent Document 2: JP-A-07-138561

Patent Document 3: JP-A-03-200889

Patent Document 4: U.S. Pat. No. 6,097,147

Patent Document 5: WO 01/41512

Patent Document 6: US 2001/0025108

Patent Document 7: US 2002/0182441

Patent Document 8: JP-A-2002-170684

Patent Document 9: JP-A-2003-123982

Patent Document 10: JP-A-2003-133074

Patent Document 11: WO 05/019373

Patent Document 12: US 2005/0258433

Patent Document 13: US 2005/0258742

Patent Document 14: US 2005/0260441

Patent Document 15: US 2005/0260444

Patent Document 16: US 2005/0260445

Patent Document 17: US 2005/0260446

Patent Document 18: US 2005/0260447

Patent Document 19: US 2005/0260448

Patent Document 20: US 2005/0260449

Patent Document 21: US 2005/0170206

Patent Document 22: US 2005/0170207

Non-patent Document 1: D. F. OBrien and M. A. Baldo et al “Improved energy transfer in electrophosphorescent devices” Vol. 74, No. 3, pp 442-444, Jan. 18, 1999

Non-patent Document 2: M. A. Baldo et al “Very high-efficiency green organic light-emitting devices based on electrophosphorescence” Applied Physics letters Vol. 75, No. 1, pp 4-6, Jul. 5, 1999

Non-patent Document 3: Chem. Rev. 2000, 100, p 39

Non-patent Document 4: J. Am. Chem. Soc., 1991, 113, p 361

Non-patent Document 5: Angnew. Chem. Int. Ed., 2002, 41, p 1290

Non-patent Document 6: J. Am. Chem. Soc., 1999, 121, p 2674

Non-patent Document 7: Organometallics, 1999, 18, p 2370

Non-patent Document 8: Angnew. Chem. Int. Ed., 2002, 41, p 1363

Non-patent Document 9: Angnew. Chem. Int. Ed., 2002, 41, p 1745

Non-patent Document 10: Organometallics, 2000, 19, p 3459

Non-patent Document 11: Tetrahedron Aymmetry, 2003, 14, p 951

Non-patent Document 12: J. Organomet. Chem., 1982, 239, C26-C30

Non-patent Document 13: Chem. Commun., 2002, p 2518

### DISCLOSURE OF THE INVENTION

### Problem to be Solved by the Invention

The present invention has been made with a view to solving the above-mentioned problems, and an object of the present invention is to provide an organic EL device having high luminous efficiency and emitting blue light, and a novel transition metal complex compound for realizing the device.

### Means for Solving the Problems

The inventors of the present invention have made extensive studies with a view to achieving the above object. As a result, the inventors have found that the luminous wavelength of a transition metal complex compound can be lengthened by coupling (crosslinking) the ligands of a complex in the compound. The phenomenon is useful as a technology for adjusting the luminous wavelength to a desired one, and is useful particularly in leading a material having a luminous wavelength in an ultraviolet region to a material having a luminous wavelength in a blue color region (a visual sense wavelength region can be extended). The inventors have found that the utilization of the technology provides an organic EL device having high luminous efficiency and emitting blue light. Thus, the inventors have completed the present invention.

The present invention provides a transition metal complex compound including a ligand having three or more coordination sites formed of a combination of covalent bonds and/or coordinate bonds and a transition metal complex compound including a ligand having four or more coordination sites formed of a combination of covalent bonds and/or coordinate bonds.

In addition, the present invention provides a transition metal complex compound having a metal carbene bond represented by the following general formulae (1) to (6):

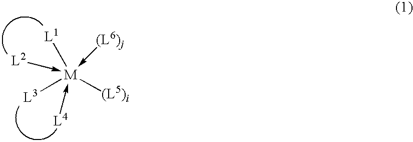

where:

a bond indicated by a solid line (-) means a covalent bond, a bond indicated by an arrow (→) means a coordinate bond, and at least one of L²→M and L⁴→M represents a metal carbene bond;

M represents a metal atom of iridium (Ir) or platinum (Pt);

L¹-L² and L³-L⁴ each represent a crosslinking bidentate ligand, L⁵ and L⁶ each independently represent a monodentate ligand, or are crosslinked with each other to represent a crosslinking bidentate ligand (L⁵-L⁶), and two ligands in at least one of combinations of L¹ and L³ , L¹ and L⁴, L² and L³, L² and L⁴, L¹ and L⁵, L¹ and L⁶, L² and L⁵, L² and L⁶, L³ and L⁵, L³ and L⁶, L⁴ and L⁵, and L⁴ and L⁶ are crosslinked with each other through a crosslinking group —Z¹— where Z¹ represents a divalent residue formed of a compound selected from an aromatic hydrocarbon, a heterocyclic group, an alkane, an alkene, and a compound obtained by substituting a carbon atom of each of the aromatic hydrocarbon, the heterocyclic group, the alkane, and the alkene by any one of a silicon atom, a nitrogen atom, a sulfur atom, an oxygen atom, a phosphorus atom, and a boron atom, or formed of a combination of two or more of these compounds, and the divalent residue may have a substituent;

when multiple crosslinking groups —Z¹—'s are present, the crosslinking groups may be identical to or different from each other;

i represents an integer of 0 to 1, 2+i represents a valence of the metal M, j represents an integer of 0 to 4, and, when i or j represents 2 or more, L⁵'s or L⁶'s maybe identical to or different from each other, or adjacent ligands may be crosslinked with each other;

L¹ and L³ each independently represent a divalent aromatic hydrocarbon group which has 6 to 30 ring carbon atoms and may have a substituent, a divalent heterocyclic group which has 3 to 30 ring atoms and which may have a substituent, a divalent carboxyl-containing group which has 1 to 30 carbon atoms and may have a substituent, a divalent amino group- or hydroxyl group-containing hydrocarbon group which may have a substituent, a cycloalkylene group which has 3 to 50 ring carbon atoms and may have a substituent, an alkylene group which has 1 to 30 carbon atoms and may have a substituent, an alkenylene group which has 2 to 30 carbon atoms and may have a substituent, or an aralkylene group which has 7 to 40 carbon atoms and may have a substituent;

L² and L⁴ each independently represent a monovalent group which has carbene carbon and which may have a substituent, a monovalent aromatic hydrocarbon group which has 6 to 30 ring carbon atoms and may have a substituent, or a monovalent heterocyclic group which has 3 to 30 ring atoms and which may have a substituent, and at least one of L² and L⁴ represent a monovalent group which has carbene carbon and which may have a substituent;

L⁵ represents a monovalent aromatic hydrocarbon group which has 6 to 30 ring carbon atoms and may have a substituent, a monovalent heterocyclic group which has 3 to 30 ring atoms and which may have a substituent, a monovalent carboxyl group which has 1 to 30 carbon atoms and may have a substituent, a monovalent amino group- or hydroxyl group-containing hydrocarbon group which may have a substituent, a cycloalkyl group which has 3 to 50 ring carbon atoms and may have a substituent, an alkyl group which has 1 to 30 carbon atoms and may have a substituent, an alkenyl group which has 2 to 30 carbon atoms and may have a substituent, or an aralkyl group which has 7 to 40 carbon atoms and may have a substituent, and, when L⁵ and L⁶ are crosslinked with each other, L⁵ represents a divalent group of each of the groups; and

L⁶ represents a heterocyclic ring which has 3 to 30 ring carbon atoms and may have a substituent, a carboxylate which has 1 to 30 carbon atoms and may have a substituent, a carboxylic amide having 1 to 30 carbon atoms, an amine which may have a substituent, a phosphine which may have a substituent, an isonitrile which may have a substituent, an ether which has 1 to 30 carbon atoms and may have a substituent, a thioether which has 1 to 30 carbon atoms and may have a substituent, or a double bond-containing compound which has 1 to 30 carbon atoms and may have a substituent, and, when L⁵ and L⁶ are crosslinked with each other, L⁶ represents a monovalent group of each of the compounds.

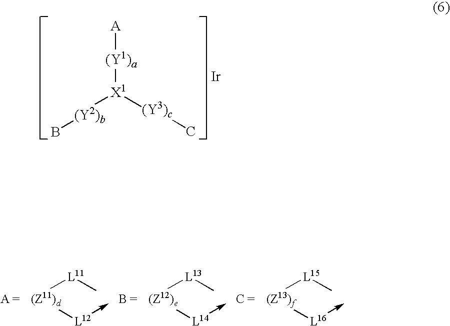

where:

A represents a crosslinking bidentate ligand group formed of L¹¹-(Z¹¹)_{d}-L¹², B represents a crosslinking bidentate ligand group formed of L¹³-(Z¹²)^{e}-L¹⁴, and C represents a crosslinking bidentate ligand group formed of L¹⁵-(Z¹³)_{f}-L¹⁶;

L¹¹-, L¹³-, and L¹⁵- each represent a covalent bond to iridium (Ir) (L¹¹-Ir, L¹³-Ir, and L¹⁵-Ir), and L¹²→, L¹⁴→, and L¹⁶→ each represent a coordinate bond to Ir (L¹²→Ir, L¹⁴→Ir, and L¹⁶→Ir);

X¹ represents a crosslinking group formed of a non-cyclic structure having 1 to 18 atoms, the crosslinking group being a trivalent residue of a compound formed of an atom selected from the group consisting of a hydrogen atom, a carbon atom, a silicon atom, a nitrogen atom, a sulfur atom, an oxygen atom, a phosphorus atom, and a boron atom, and the crosslinking group may have a substituent;

Y¹ represents a crosslinking group for bonding X and A, Y² represents a crosslinking group for bonding X and B, and Y³ represents a crosslinking group for bonding X and C, and Y¹ is bonded to L¹¹, L¹², or Z¹¹, Y² is bonded to L¹³, L¹⁴, or Z¹², and Y³ is bonded to L¹⁵, L¹⁶, or Z¹³;

Y¹, Y², and Y³ each independently represent a divalent residue of a compound formed of an atom selected from the group consisting of a hydrogen atom, a carbon atom, a silicon atom, a nitrogen atom, a sulfur atom, an oxygen atom, a phosphorus atom, and a boron atom, and the divalent residue may have a substituent;

a, b, and c each independently represent an integer of 0 to 10, and, when a, b, or c represents 2 or more, multiple Y¹'s, multiple Y²'s, or multiple Y³'s may be identical to or different from each other;

Z¹¹ represents a crosslinking group for bonding L¹¹ and L¹², Z¹² represents a crosslinking group for bonding L¹³ and L¹⁴, and Z¹³ represents a crosslinking group for bonding L¹⁵ and L¹⁶, and Z¹¹, Z¹², and Z¹³ each independently represent a divalent residue of a compound formed of an atom selected from the group consisting of a hydrogen atom, a carbon atom, a silicon atom, a nitrogen atom, a sulfur atom, an oxygen atom, a phosphorus atom, and a boron atom, and the divalent residue may have a substituent;

when Z¹¹ is directly bonded to Y¹, when Z¹² is directly bonded to Y², or when Z¹³ is directly bonded to Y³, Z¹¹, Z¹², and Z¹³ each represent a corresponding trivalent group;

d, e, and f each independently represent an integer of 0 to 10, and, when d, e, or f represents 2 or more, multiple Z¹¹'s, multiple Z¹²'s, or multiple Z¹³'s may be identical to or different from each other;

L¹¹, L¹³, and L¹⁵ each independently represent a divalent aromatic hydrocarbon group which has 6 to 30 ring carbon atoms and may have a substituent, a divalent heterocyclic group which has 3 to 30 ring atoms and which may have a substituent, a divalent carboxyl-containing group which has 1 to 30 carbon atoms and may have a substituent, a divalent amino group- or hydroxyl group-containing hydrocarbon group which may have a substituent, a cycloalkylene group which has 3 to 50 ring carbon atoms and may have a substituent, an alkylene group which has 1 to 30 carbon atoms and may have a substituent, an alkenylene group which has 2 to 30 carbon atoms and may have a substituent, or an aralkylene group which has 7 to 40 carbon atoms and may have a substituent, and, when L¹¹ is directly bonded to Y¹, when L¹³ is directly bonded to Y², or when L¹⁵ is directly bonded to Y³, L¹¹, L¹³, and L¹⁵ each represent a corresponding trivalent group; and

L¹², L¹⁴, and L¹⁶ each independently represent a monovalent group which has carbene carbon and which may have a substituent, or a monovalent heterocyclic group which has 3 to 30 ring atoms and which may have a substituent, and, when L¹² is directly bonded to Y¹, when L¹⁴ is directly bonded to Y², or when L¹⁶ is directly bonded to Y³, L¹², L¹⁴, and L¹⁶ each represent a corresponding divalent group.

In addition, the present invention provides an organic EL device including an organic thin film layer formed of one or more layers including at least a light emitting layer, the organic thin film layer being interposed between an anode and a cathode, in which at least one layer of the organic thin film layer contains the above-mentioned transition metal complex compound.

### Effects of the Invention

The organic EL device using the transition metal complex compound of the present invention has high luminous efficiency and a long emission lifetime, and emits blue light.

### BRIEF DESCRIPTION OF THE DRAWINGS

FIG. 1 is a view showing the ¹H-NMR spectrum of Metal Complex Compound 1 obtained in Example 1.

FIG. 2 is a view showing the ¹H-NMR spectrum of Comparative Compound 1 obtained in Comparative Example 1.

FIG. 3 is a view showing the ¹H-NMR spectrum of Comparative Compound 2 obtained in Comparative Example 2.

FIG. 4 is a view showing the emission spectrum of each of Metal Complex Compound 1, Comparative Compound 1, and Comparative Compound 2.

### BEST MODE FOR CARRYING OUT THE INVENTION

The present invention relates to a transition metal complex compound including a ligand having three or more coordination sites formed of a combination of covalent bonds and/or coordinate bonds and a transition metal complex compound including a ligand having four or more coordination sites formed of a combination of covalent bonds and/or coordinate bonds. The transition metal complex compound preferably has a metal carbene bond and a metal of the transition metal complex compound preferably includes iridium.

Examples of the transition metal complex compound include transition metal complex compounds each represented by the following general formula (1) or (6) and each having the metal carbene bond.

First, the general formula (1) will be described below.

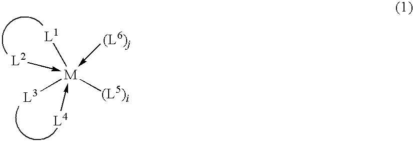

where:

a bond indicated by a solid line (-) means a covalent bond, a bond indicated by an arrow (→) means a coordinate bond, and at least one of L²→M and L⁴→M represents a metal carbene bond;

M represents a metal atom of iridium (Ir) or platinum (Pt) and Ir is preferable;

L¹-L² and L³-L⁴ each represent a crosslinking bidentate ligand, L⁵ and L⁶ each independently represent a monodentate ligand, or are crosslinked with each other to represent a crosslinking bidentate ligand (L⁵-L⁶), and two ligands in at least one of combinations of L¹ and L³, L¹ and L⁴, L² and L³, L² and L⁴, L¹ and L⁵, L¹ and L⁶, L² and L⁵, L² and L⁶, L³ and L⁵, L³ and L⁶, L⁴ and L⁵, and L⁴ and L⁶ are crosslinked with each other through a crosslinking group —Z¹—;

i represents an integer of 0 to 1, 2+i represents a valence of the metal M, and j represents an integer of 0 to 4. When i and j represents 2 or more, L⁵'s and L⁶'s may be identical to or different from each other, and adjacent ligands may be crosslinked with each other.

Z¹ represents a divalent residue formed of a compound selected from an aromatic hydrocarbon, a heterocyclic group, an alkane, an alkene, and a compound obtained by substituting a carbon atom of each of the aromatic hydrocarbon, the heterocyclic group, the alkane, and the alkene by any one of a silicon atom, a nitrogen atom, a sulfur atom, an oxygen atom, a phosphorus atom, and a boron atom, or formed of a combination of two or more of these compounds, and the divalent residue may have a substituent. When multiple crosslinking groups —Z¹—'s are present, the crosslinking groups may be identical to or different from each other.

Specific examples of Z¹ include: an α,ω-alkylene crosslinking group having 1 to 20 carbon atoms; an α,ω-alkylene crosslinking group having 1 to 20 carbon atoms and an ether bond; an α,ω-alkylene crosslinking group having 1 to 20 carbon atoms and a thioether bond; an α,ω-alkylene crosslinking group having 1 to 20 carbon atoms and a carbon-silicon bond; an α,ω-alkylene crosslinking group having 1 to 20 carbon atoms and a carbon-nitrogen bond; an α,ω-alkylene crosslinking group having 1 to 20 carbon atoms and a carbon-phosphorus bond; an α,ω-alkylene crosslinking group having 1 to 20 carbon atoms and a carbon-carbon double bond; an α,ω-alkylene crosslinking group having 1 to 20 carbon atoms and a carbon-carbon triple bond; an α,ω-alkylene crosslinking group having 1 to 20 carbon atoms and an arylene group; and an α,ω-alkylene crosslinking group having 1 to 20 ring atoms and a heterocyclic group. Of those, a compound constituted only of a carbon atom and a hydrogen atom is preferable.

When multiple Z¹'s are present, substituents for Z¹'s are each independently, for example, a hydrogen atom, a halogen atom, an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 30 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkoxy group which has 1 to 30 carbon atoms and may have a substituent, an aryloxy group which has 6 to 30 ring carbon atoms and may have a substituent, an alkylamino group which has 3 to 30 ring atoms and which may have a substituent, an alkylsilyl group which has 3 to 30 ring atoms and which may have a substituent, an arylsilyl group which has 6 to 30 carbon atoms and may have a substituent, or a carboxyl-containing group having 1 to 30 carbon atoms, but the substituents are not limited to those groups. Specific examples of each of those groups are similar to those described below. Of those, a halogen atom or a compound constituted only of a carbon atom and a hydrogen atom is preferable.

Specific examples of Z¹ include the following structures (* represents a bonding position, so, for example, the following structure (a) means 1,2-ethylene crosslinkage).

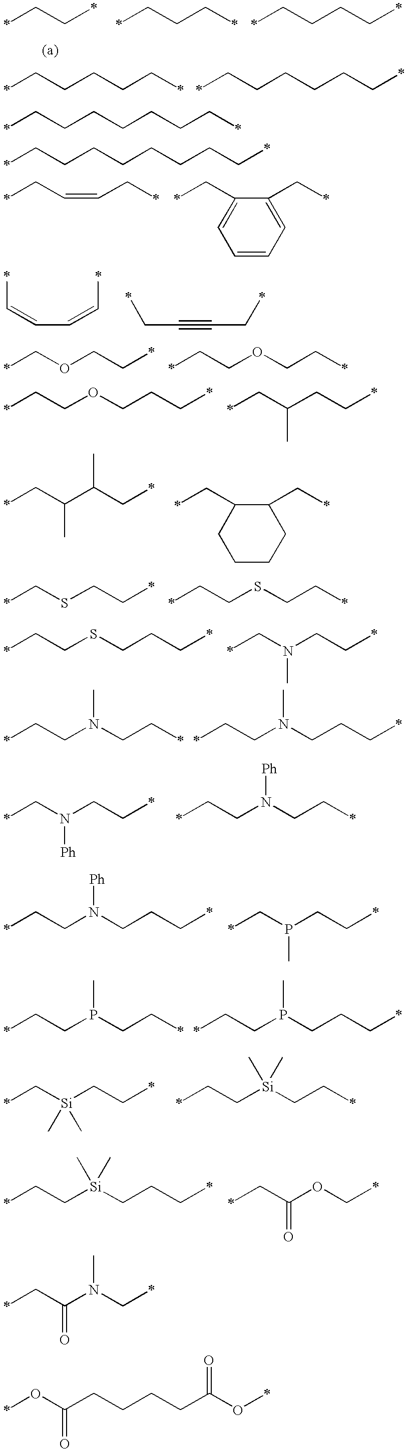

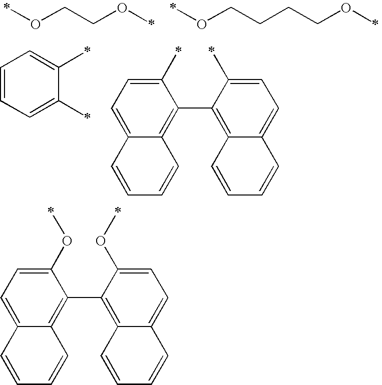

In the general formula (1), L¹ and L³ each independently represent a divalent aromatic hydrocarbon group which has 6 to 30 ring carbon atoms and may have a substituent, a divalent heterocyclic group which has 3 to 30 ring atoms and which may have a substituent, a divalent carboxyl-containing group which has 1 to 30 carbon atoms and may have a substituent, a divalent amino group- or hydroxyl group-containing hydrocarbon group which may have a substituent, a cycloalkylene group which has 3 to 50 ring carbon atoms and may have a substituent, an alkylene group which has 1 to 30 carbon atoms and may have a substituent, an alkenylene group which has 2 to 30 carbon atoms and may have a substituent, or an aralkylene group which has 7 to 40 carbon atoms and may have a substituent.

In the general formula (1), L² and L⁴ each independently represent a monovalent group which has carbene carbon and which may have a substituent, a monovalent aromatic hydrocarbon group which has 6 to 30 ring carbon atoms and may have a substituent, or a monovalent heterocyclic group which has 3 to 30 ring atoms and which may have a substituent, and at least one of L² and L⁴ represent a monovalent group which has carbene carbon and which may have a substituent.

In the general formula (1), L⁵ represents a monovalent aromatic hydrocarbon group which has 6 to 30 ring carbon atoms and may have a substituent, a monovalent heterocyclic group which has 3 to 30 ring atoms and which may have a substituent, a monovalent carboxyl group which has 1 to 30 carbon atoms and may have a substituent, a monovalent amino group- or hydroxyl group-containing hydrocarbon group which may have a substituent, a cycloalkyl group which has 3 to 50 ring carbon atoms and may have a substituent, an alkyl group which has 1 to 30 carbon atoms and may have a substituent, an alkenyl group which has 2 to 30 carbon atoms and may have a substituent, or an aralkyl group which has 7 to 40 carbon atoms and may have a substituent, and, when L⁵ and L⁶ are crosslinked with each other, L⁵ represents a divalent group of each of the groups.

Hereinafter, specific examples of the group represented by each of L¹ to L⁵ will be described.

For the aromatic hydrocarbon group, a hydrocarbon group having 6 to 18 ring carbon atoms is preferable, and examples thereof include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, 4″-t-butyl-p-terphenyl-4-yl group, an o-cumenyl group, an m-cumenyl group, a p-cumenyl group, a 2,3-xylylenyl group, a 3,4-xylylenyl group, a 2,5-xylylenyl group, a mesitylenyl group, a perfluorophenyl group, and divalent groups thereof.

Of those, a phenyl group, a 1-naphthyl group, a 2-naphthyl group, a 9-phenanthryl group, a 2-biphenylyl group, a 3-biphenylyl group, a 4-biphenylyl group, a p-tolyl group, a 3,4-xylylenyl group, and divalent groups thereof are preferable.

For the heterocyclic group, a heterocyclic group having 3 to 18 ring atoms is preferable, and examples thereof include a 1-pyrrolyl group, a 2-pyrrolyl group, a 3-pyrrolyl group, a pyrazinyl group, a 2-pyridinyl group, a 1-imidazolyl group, a 2-imidazolyl group, a 1-pyrazolyl group, a 1-indolydinyl group, a 2-indolydinyl group, a 3-indolydinyl group, a 5-indolydinyl group, a 6-indolydinyl group, a 7-indolydinyl group, an 8-indolydinyl group, a 2-imidazopyridinyl group, a 3-imidazopyridinyl group, a 5-imidazopyridinyl group, a 6-imidazopyridinyl group, a 7-imidazopyridinyl group, an 8-imidazopyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a 2-quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a β-carbolin-1-yl group, a β-carbolin-3-yl group, a β-carbolin-4-yl group, a β-carbolin-5-yl group, a β-carbolin-6-yl group, a β-carbolin-7-yl group, a β-carbolin-6-yl group, a β-carbolin-9-yl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthrolin-2-yl group, a 1,7-phenanthrolin-3-yl group, a 1,7-phenanthrolin-4-yl group, a 1,7-phenanthrolin-5-yl group, a 1,7-phenanthrolin-6-yl group, a 1,7-phenanthrolin-8-yl group, a 1,7-phenanthrolin-9-yl group, a 1,7-phenanthrolin-10-yl group, a 1,8-phenanthrolin-2-yl group, a 1,8-phenanthrolin-3-yl group, a 1,8-phenanthrolin-4-yl group, a 1,8-phenanthrolin-5-yl group, a 1,8-phenanthrolin-6-yl group, a 1,8-phenanthrolin-7-yl group, a 1,8-phenanthrolin-9-yl group, a 1,8-phenanthrolin-10-yl group, a 1,9-phenanthrolin-2-yl group, a 1,9-phenanthrolin-3-yl group, a 1,9-phenanthrolin-4-yl group, a 1,9-phenanthrolin-5-yl group, a 1,9-phenanthrolin-6-yl group, a 1,9-phenanthrolin-7-yl group, a 1,9-phenanthrolin-8-yl group, a 1,9-phenanthrolin-10-yl group, a 1,10-phenanthrolin-2-yl group, a 1,10-phenanthrolin-3-yl group, a 1,10-phenanthrolin-4-yl group, a 1,10-phenanthrolin-5-yl group, a 2,9-phenanthrolin-1-yl group, a 2,9-phenanthrolin-3-yl group, a 2,9-phenanthrolin-4-yl group, a 2,9-phenanthrolin-5-yl group, a 2,9-phenanthrolin-6-yl group, a 2,9-phenanthrolin-7-yl group, a 2,9-phenanthrolin-8-yl group, a 2,9-phenanthrolin-10-yl group, a 2,8-phenanthrolin-1-yl group, a 2,8-phenanthrolin-3-yl group, a 2,8-phenanthrolin-4-yl group, a 2,8-phenanthrolin-5-yl group, a 2,8-phenanthrolin-6-yl group, a 2,8-phenanthrolin-7-yl group, a 2,8-phenanthrolin-9-yl group, a 2,8-phenanthrolin-10-yl group, a 2,7-phenanthrolin-1-yl group, a 2,7-phenanthrolin-3-yl group, a 2,7-phenanthrolin-4-yl group, a 2,7-phenanthrolin-5-yl group, a 2,7-phenanthrolin-6-yl group, a 2,7-phenanthrolin-8-yl group, a 2,7-phenanthrolin-9-yl group, a 2,7-phenanthrolin-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxadinyl group, a 2-phenoxadinyl group, a 3-phenoxadinyl group, a 4-phenoxadinyl group, a 10-phenoxadinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrol-1-yl group, a 2-methylpyrrol-3-yl group, a 2-methylpyrrol-4-yl group, a 2-methylpyrrol-5-yl group, a 3-methylpyrrol-1-yl group, a 3-methylpyrrol-2-yl group, a 3-methylpyrrol-4-yl group, a 3-methylpyrrol-5-yl group, a 2-t-butylpyrrol-4-yl group, a 3-(2-phenylpropyl)pyrrol-1-yl group, a 2-methyl-1-indolyl group, a 4-methyl-1-indolyl group, a 2-methyl-3-indolyl group, a 4-methyl-3-indolyl group, a 2-t-butyl1-indolyl group, a 4-t-butyl1-indolyl group, a 2-t-butyl3-indolyl group, a 4-t-butyl3-indolyl group, pyrrolidine, pyrazolidine, piperalyzine, and divalent groups thereof.

Of those, a 2-pyridinyl group, a 1-indolydinyl group, a 2-indolydinyl group, a 3-indolydinyl group, a 5-indolydinyl group, a 6-indolydinyl group, a 7-indolydinyl group, an 8-indolydinyl group, a 2-imidazopyridinyl group, a 3-imidazopyridinyl group, a 5-imidazopyridinyl group, a 6-imidazopyridinyl group, a 7-imidazopyridinyl group, an 8-imidazopyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 1-carbazolyl group, a 2-carbazolyl group, a 3-carbazolyl group, a 4-carbazolyl group, a 9-carbazolyl, and divalent groups thereof are preferable.

Examples of the carboxyl-containing group include an ester bond (—C(═O)O—), methyl ester, ethyl ester, butyl ester, and divalent groups thereof.

Examples of the cycloalkyl group and cycloalkylene group include a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, and divalent groups thereof.

For the alkyl group and alkylene group, the group having 1 to 10 carbon atoms is preferable, and examples thereof include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, a 3-methylpentyl group, a hydroxymethyl group, a 1-hydroxyethyl group, a 2-hydroxyethyl group, a 2-hydoxyisobutyl group, a 1,2-dihydroxyethyl group, a 1,3-dihydroxyisopropyl group, a 2,3-dihydroxy-t-butyl group, a 1,2,3-trihydroxypropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 1,2-dinitroethyl group, a 2,3-dinitro-t-butyl group, a 1,2,3-trinitropropyl group, a cyclopentyl group, a cyclohexyl group, a cyclooctyl group, and a 3,5-tetramethylcyclohexyl group, and divalent groups thereof.

Of those, a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 1-pentylhexyl group, a 1-butylpentyl group, a 1-heptyloctyl group, a cyclohexyl group, a cyclooctyl group, a 3,5-tetramethylcyclohexyl group, and divalent groups thereof are preferable.

For the alkenyl group and alkylene group, the group having 2 to 16 carbon atoms is preferable, and examples thereof include a vinyl group, an allyl group, a 1-butenyl group, a 2-butenyl group, a 3-butenyl group, a 1,3-butandienyl group, a 1-methylvinyl group, a styryl group, a 2,2-diphenylvinyl group, a 1,2-diphenylvinyl group, a 1-methylallyl group, a 1,1-dimethylallyl group, a 2-methylallyl group, a 1-phenylallyl group, a 2-phenylallyl group, a 3-phenylallyl group, a 3,3-diphenylallyl group, a 1,2-dimethylallyl group, a 1-phenyl-1-butenyl group, and a 3-phenyl-1-butenyl group, and divalent groups thereof. Of those, a styryl group, a 2,2-diphenylvinyl group, a 1,2-diphenyl vinyl group, and divalent groups thereof are preferable.

For the aralkyl group and aralkylene group, the group having 7 to 18 carbon atoms is preferable, and examples thereof include divalent groups of a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, a 1-pyrrolylmethyl group, a 2-(1-pyrrolyl)ethyl group, a p-methylbenzyl group, an m-methylbenzyl group, an o-methylbenzyl group, a p-chlorobenzyl group, an m-chlorobenzyl group, an o-chlorobenzyl group, a p-bromobenzyl group, an m-bromobenzyl group, an o-bromobenzyl group, a p-iodobenzyl group, an m-iodobenzyl group, an o-iodobenzyl group, a p-hydroxybenzyl group, an m-hydroxybenzyl group, an o-hydroxybenzyl group, a p-aminobenzyl group, an m-aminobenzyl group, an o-aminobenzyl group, a p-nitrobenzyl group, an m-nitrobenzyl group, an o-nitrobenzyl group, a p-cyanobenzyl group, an m-cyanobenzyl group, an o-cyanobenzyl group, a 1-hydroxy-2-phenylisopropyl group, and a 1-chloro-2-phenylisopropyl group. Of those, a benzyl group, a p-cyanobenzyl group, an m-cyanobenzyl group, an o-cyanobenzyl group, a 1-phenylethyl group, a 2-phenylethyl group, a 1-phenylisopropyl group, and a 2-phenylisopropyl group, and divalent groups thereof are preferable.

Examples of the amino group- or hydroxyl group-containing hydrocarbon group include an amino group having a hydrocarbon group represented by each of L¹ to L⁵ described above and a group obtained by substituting a hydrogen atom of the hydrocarbon group by a hydroxyl group.

In the general formula (1), L⁶ represents a heterocyclic ring which has 3 to 30 ring carbon atoms and may have a substituent, a carboxylate which has 1 to 30 carbon atoms and may have a substituent, a carboxylic amide having 1 to 30 carbon atoms, an amine which may have a substituent, a phosphine which may have a substituent, an isonitrile which may have a substituent, an ether which has 1 to 30 carbon atoms and may have a substituent, a thioether which has 1 to 30 carbon atoms and may have a substituent, or a double bond-containing compound which has 1 to 30 carbon atoms and may have a substituent, and, when L⁵ and L⁶ are crosslinked with each other, L⁶ represents a monovalent group of each of the compounds.

Examples of the heterocyclic group include groups obtained by making groups similar to those described above for L¹ to L⁵ zero-valent.

Examples of the carboxylate include methyl formate, ethyl formate, methyl acetate, ethyl acetate, methyl propionate, ethyl propionate, methylbenzoate, ethylbenzoate, methyl 2-pyridine carboxylate, ethyl 2-pyridine carboxylate, methyl 3-pyridine carboxylate, ethyl 3-pyridine carboxylate, methyl 4-pyridine carboxylate, ethyl 4-pyridine carboxylate, methyl phenyl acetate, ethyl phenyl acetate, methyl 2-pyridineacetate, ethyl 2-pyridineacetate, methyl 3-pyridineacetate, ethyl 3-pyridineacetate, methyl 4-pyridineacetate, ethyl 4-pyridineacetate, methyl 2-pyrrolecarboxylate, methyl 3-pyrrolecarboxylate, methyl 2-thiophenecarboxylate, and methyl 3-thiophenecarboxylate.

Examples of the carboxylic acid amide include, N,N-dimethylformamide, N,N-dimethylacetamide, N,N-dimethylbenzoic acid amide, N,N-dimethyl-2-pyridinecarboxylic acid amide, N,N-dimethyl-3-pyridinecarboxylic acid amide, N,N-dimethyl-4-pyridinecarboxylic acid amide, N,N-dimethyl-phenylacetic acid amide, N,N-dimethyl-2-pyridineacetic acid amide, N,N-dimethyl-3-pyridineacetic acid amide, N,N-dimethyl-4-pyridineacetic acid amide, N,N-dimethyl-2-pyrrolecarboxylic acid amide, N,N-dimethyl-3-pyrrolecarboxylic acid amide, N,N-dimethyl-2-thiophenecarboxylic acid amide, N,N-dimethyl-3-thiophenecarboxylic acid amide, N-methylformamide, N-methylacetamide, N-methylbenzoic acid amide, N-methyl-2-pyridinecarboxylic acid amide, N-methyl-3-pyridinecarboxylic acid amide, N-methyl-4-pyridinecarboxylic acid amide, N-methyl-phenylacetic acid amide, N-methyl-2-pyridineacetic acid amide, N-methyl-3-pyridineacetic acid amide, N-methyl-4-pyridineacetic acid amide, N-methyl-2-pyrrolecarboxylic acid amide, N-methyl-3-pyrrolecarboxylic acid amide, N-methyl-2-thiophenecarboxylic acid amide, N-methyl-3-thiophenecarboxylic acid amide, acetamide, benzoic acid amide, 2-pyridinecarboxylic acid amide, 3-pyridinecarboxylic acid amide, 4-pyridinecarboxylic acid amide, phenylacetic acid amide, 2-pyridineacetic acid amide, 3-pyridineacetic acid amide, 4-pyridineacetic acid amide, 2-pyrrolecarboxylic acid amide, 3-pyrrolecarboxylic acid amide, 2-thiophenecarboxylic acid amide, and 3-thiophenecarboxylic acid amide.

Examples of the amine include triethylamine, tri-n-propylamine, tri-n-butylamine, N,N-dimethylaniline, methyldiphenylamine, triphenylamine, dimethyl(2-pyridine)amine, dimethyl(3-pyridine)amine, dimethyl(4-pyridine)amine, methylbis(2-pyridine)amine, methylbis(3-pyridine)amine, methylbis(4-pyridine)amine, tris(2-pyridine)amine, tris(3-pyridine)amine, tris(4-pyridine)amine, diisopropylamine, di-n-propylamine, di-n-butylamine, N-methylaniline, methylphenylamine, diphenylamine, methyl(2-pyridine)amine, methyl(3-pyridine)amine, methyl(4-pyridine)amine, bis(2-pyridine)amine, n-propylamine, n-butylamine, aniline, (2-pyridine)amine, (3-pyridine)amine, (4-pyridine)amine,pyridine, 2-methylpyridine, 3-methylpyridine, 4-methylpyridine, 2-trifluoromethylpyridine, 3-trifluoromethylpyridine, 4-trifluoromethylpyridine, and N-methylpyrrole.

Examples of the phosphine include those where nitrogen of the amine is substituted with phosphorus.

Examples of the isonitrile include butylisocyanide, isobutylisocyanide, sec-butylisocyanide, t-butylisocyanide, phenylisocyanide, 2-tolylisocyanide, 3-tolylisocyanide, 4-tolylisocyanide, 2-pyridineisocyanide, 3-pyridineisocyanide, 4-pyridineisocyanide, and benzylisocyanide.

Examples of the ether include diethylether, di-n-propylether, di-n-butylether, diisobutylether, di-sec-butylether, di-t-butylether, anisol, diphenylether, furan, tetrahydrofuran, and dioxane.

Examples of the thioether include those where oxygen of the ether is substituted with sulfur.

Examples of the compounds containing a double bond and having 1 to 30 carbon atoms include ethylene, propylene, 1-butene, 1-pentene, 1-hexene, 1-heptene, 1-octene, 1-nonene, 1-decene, 1-eicosen, 2-butene, 2-pentene, 2-hexene, 2-heptene, 2-octene, 2-nonene, 2-decene, 2-eicosen, 3-heptene, 3-octene, 3-nonene, 3-decene, 3-eicosen, isobutene, styrene, α-methylstyrene, β-methylstyrene, butadiene, isoprene, and stilbene.

In addition, in the general formula (1), L¹ and L³ each preferably represent an aromatic hydrocarbon group or a heterocyclic group, for example, any one of the following structures. Of those structures, a phenyl group and a substituted phenyl group are preferable. Although M represents Ir in each of the following examples, similar examples can be given when M represents a metal atom except Ir. In addition, X represents an adjacent bonding group, that is, L² or L⁴.

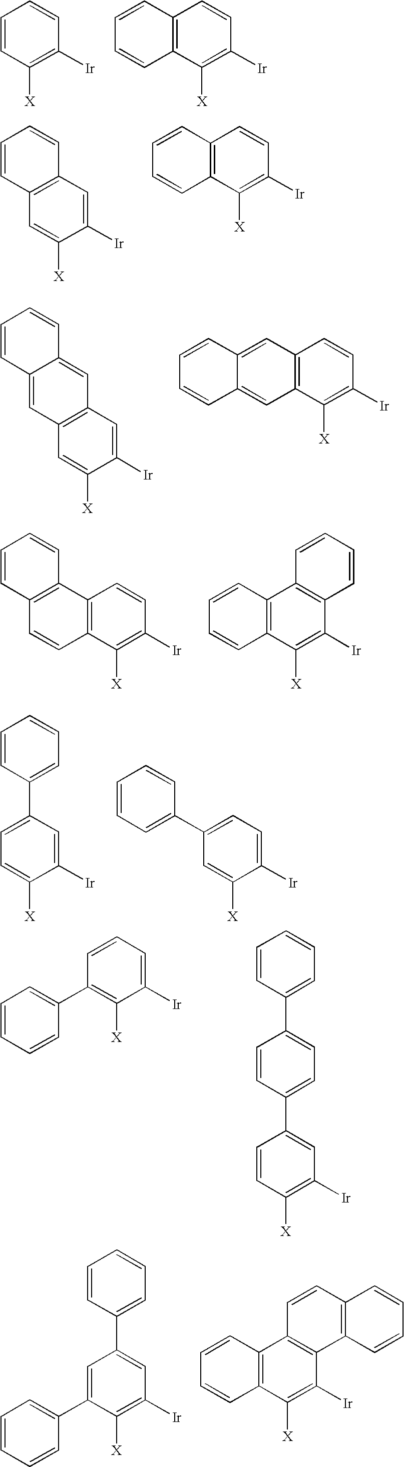

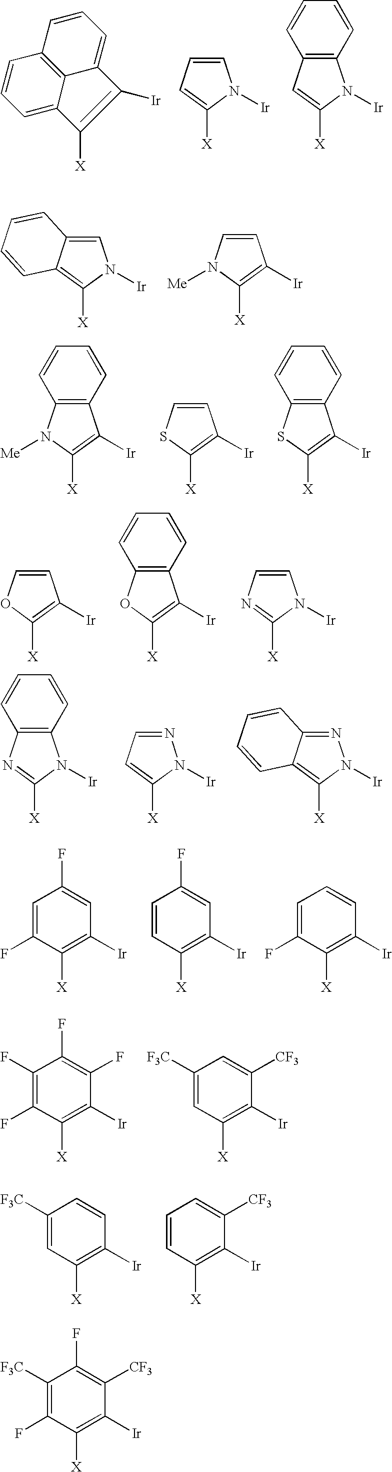

In addition, in the general formula (1), in ordinary cases, L₂ and L₄ each having carbene carbon are preferably groups that form stable carbene together with a metal. Specific examples of the carbene include diarylcarbene, cyclic diaminocarbene, imidazol-2-ylidene, 1,2,4-triazol-3-ylidene, 1,3-thiazol-2-ylidene, non-cyclic diaminocarbene, non-cyclic aminooxycarbene, non-cyclic aminothiocarbene, cyclic diborylcarbene, non-cyclic diborylcarbene, phosphinosilylcarbene, phosphinophosphinocarbene, sulfenyltrifluoromethylcarbene, and sulfenylpentafluorothiocarbene (Reference document: Chem. Rev. 2000, 100, p 39).

Of those, imidazol-2-ylidene, 1,2,4-triazol-3-ylidene, and cyclic diaminocarbene are preferable, and imidazol-2-ylidene and 1,2,4-triazol-3-ylidene are more preferable. Specific structures thereof are listed below. It should be noted that, in the following examples, an A ring represents an adjacent bonding group, that is, L¹ or L³.

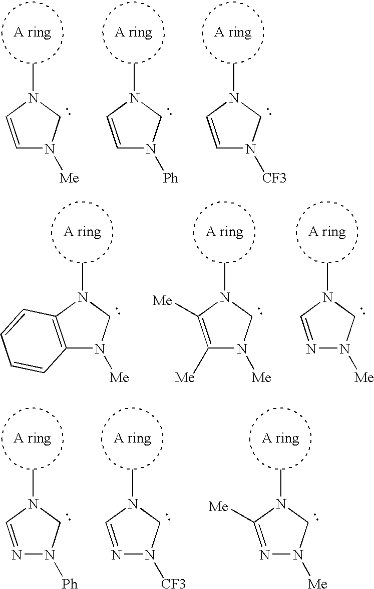

Further, specific preferable examples of the case where L² and L⁴ each represent a group free of carbene carbon are listed below. In the following examples, the carbon to be bonded to L¹ or L³ is preferably adjacent to a hetero atom coordinated to the metal M. Each of the following examples may be substituted.

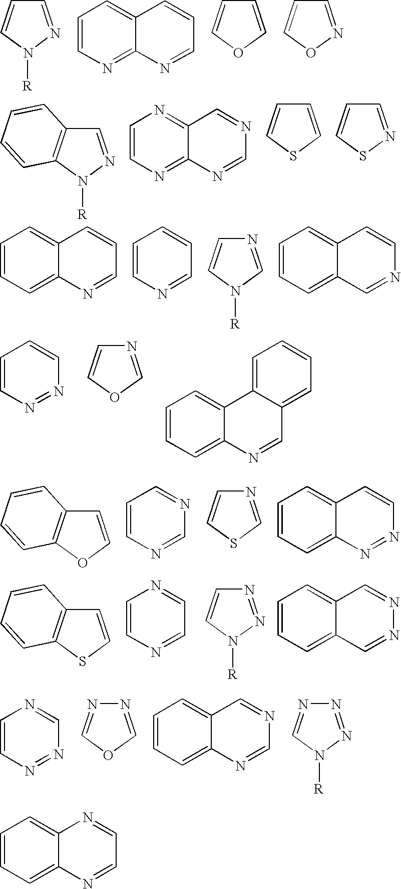

In addition, in the general formula (1), preferable examples of L⁵ include examples similar to the preferable examples described for L¹ and L³; a group obtained by removing X from each of the above examples is more preferable.

Preferable examples of L⁶ include compounds each having a pyridine ring-containing group, a pyrrole ring-containing group, an imidazole ring-containing group, a pyrazole ring-containing group, a 1,2,3-triazole ring-containing group, a 1,2,4-triazole ring-containing group, a thiophene ring-containing group, a furan ring-containing group, an oxazole ring-containing group, a thiazole ring-containing group, or a structure represented by R¹⁸₃N, R¹⁹₃P, C═N—R²⁰, R²¹₂O, R²²₂S, R²³R²⁴C═CR²⁵R²⁶, R²⁷COOR²⁸, R²⁹CONR³⁰R³¹ (R¹⁸ to R³¹ each independently represent any one of the examples similar to those described above for R¹ and R², and may be identical to or different from one another, and adjacent groups may be crosslinked with each other).

Further, when L⁵ and L⁶ are crosslinked with each other to form a structure of L⁵-L⁶, examples of the structure include structures obtained by crosslinking the preferable examples of L⁵ and L⁶ and examples similar to the preferable examples described above for L¹ and L³ and for L² and L⁴.

The transition metal complex compound represented by the general formula (1) of the present invention is preferably a transition metal complex compound having a metal carbene bond represented by the following general formula (2).

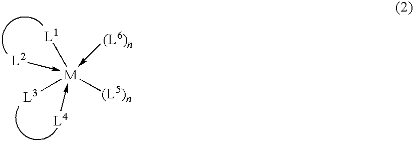

In the general formula (2), a bond indicated by a solid line means a covalent bond, a bond indicated by an arrow means a coordinate bond, and at least one of L²→M and L⁴→M represents a metal carbene bond; M and L¹ to L⁶ each have the same meaning as that described above; L¹-L² and L³-L⁴ each represent a crosslinking bidentate ligand, L⁵ and L⁶ each independently represent a monodentate ligand, or are crosslinked with each other to represent a crosslinking bidentate ligand (L⁵-L⁶), and two ligands in at least one of combinations of L¹ and L³, L¹ and L⁴, L² and L³, L² and L⁴, L¹ and L⁵, L¹ and L⁶, L² and L⁵, L² and L⁶, L³ and L⁵, L³ and L⁶, L⁴ and L⁵, and L⁴ and L⁶ are crosslinked with each other through a crosslinking group —Z¹— where Z¹ has the same meaning as that described above;

n represents an integer of 0 to 1, and 2+n represents a valence of the metal M; and

n represents 2 or more, L³'s and L⁴'s may be identical to or different from each other, or adjacent ligands may be crosslinked each other

In the general fomulae (1) and (2), in which (L¹-L²)M and/or (L³-L⁴)M each include/includes preferably a structure represented by the following general formula (3):

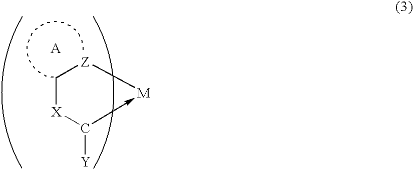

where:

a C (carbon atom)→M represents a metal carbene bond, and M represents the same as described above;

X represents a nitrogen-containing group (—NR¹—), a phosphorus-containing group (—PR¹—), oxygen (—O—), or sulfur (—S—), Y represents a nitrogen-containing group (—NR¹R²), a phosphorus-containing group (—PR¹), an oxygen-containing group (—OR¹), or a sulfur-containing group (—SR¹), and X and Y may be crosslinked with each other to form a ring structure; R¹ and R² each independently represent a hydrogen atom, an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 50 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkoxy group which has 1 to 30 carbon atoms and may have a substituent, an aryloxy group which has 6 to 30 ring carbon atoms and may have a substituent, an alkylamino group which has 3 to 30 carbon atoms and may have a substituent, an arylamino group which has 6 to 30 carbon atoms and may have a substituent, an alkylsilyl group which has 3 to 30 carbon atoms and may have a substituent, an arylsilyl group which has 6 to 30 carbon atoms and may have a substituent, or a carboxyl-containing group which has 1 to 30 carbon atoms and may have a substituent, and R¹ and R² may be crosslinked with each other; and Z represents an atom that forms a covalent bond with the metal M, the atom being a carbon, silicon, nitrogen, or phosphorus atom, and an A ring including Z represents an aromatic hydrocarbon group which has 3 to 40 ring carbon atoms and may have a substituent, or an aromatic heterocyclic group which has 3 to 40 ring atoms and which may have a substituent.

R¹ and R² each independently represent a hydrogen atom, an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 50 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and may have a substituent, an alkoxy group which has 1 to 30 carbon atoms and may have a substituent, an aryloxy group which has 6 to 30 ring carbon atoms and may have a substituent, an alkylamino group which has 3 to 30 carbon atoms and may have a substituent, an arylamino group which has 6 to 30 carbon atoms and may have a substituent, an alkylsilyl group which has 3 to 30 carbon atoms and may have a substituent, an arylsilyl group which has 6 to 30 carbon atoms and may have a substituent, or a carboxyl-containing group which has 1 to 30 carbon atoms and may have a substituent, and R¹ to R² may crosslink with one another.

For the alkyl group, an alkyl group having 1 to 10 carbon atoms is preferable, and examples thereof include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, a 3-methylpentyl group, a hydroxymethyl group, a 1-hydroxyethyl group, a 2-hydroxyethyl group, a 2-hydoxyisobutyl group, a 1,2-dihydroxyehtyl group, a 1,3-dihydroxyisopropyl group, a 2,3-dihydroxy-t-butyl group, a 1,2,3-trihydroxypropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 1,2-dinitroethyl group, a 2,3-dinitro-t-butyl group, a 1,2,3-trinitropropyl group, a cyclopentyl group, a cyclohexyl group, a cyclooctyl group, and a 3,5-tetramethylcyclohexyl group.

Of those, a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 1-pentylhexyl group, a 1-butylpentyl group, a 1-heptyloctyl group, a cyclohexyl group, a cyclooctyl group, and a 3,5-tetramethylcyclohexyl group are preferable.

For the halogenated alkyl group, a halogenated alkyl group having 1 to 10 carbon atoms is preferable, and examples thereof include a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, a fluoromethyl group, a 1-fluoromethyl group, a 2-fluoromethyl group, a 2-fluoroisobutyl group, a 1,2-difluoroethyl group, a difluoromethyl group, a trifluoromethyl group, a pentafluoroethyl group, a perfluoroisopropyl group, a perfluorbutyl group, and a perfluorocyclohexyl group.

Of those, a fluoromethyl group, a trifluoromethyl group, a pentafluoroethyl group, a perfluoroisopropyl group, a perfluorbutyl group, and a perfluorocyclohexyl group are preferable.

For the aromatic hydrocarbon group, a hydrocarbon group having 6 to 18 ring carbon atoms is preferable, and examples thereof include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, 4″-t-butyl-p-terphenyl-4-yl group, an o-cumenyl group, an m-cumenyl group, a p-cumenyl group, a 2,3-xylylenyl group, a 3,4-xylylenyl group, a 2,5-xylylenyl group, a mesitylenyl group, and a perfluorophenyl group.

Of those, a phenyl group, a 1-naphthyl group, a 2-naphthyl group, a 9-phenanthryl group, a 2-biphenylyl group, a 3-biphenylyl group, a 4-biphenylyl group, a p-tolyl group, and a 3,4-xylylenyl group are preferable.

Examples of the cycloalkyl group include a cyclopropyl group, a cyclobutyl group, a cyclopentyl group, a cyclohexyl group, a 4-methylcyclohexyl group, a 1-adamantyl group, a 2-adamantyl group, a 1-norbornyl group, and a 2-norbornyl group.

For the aralkyl group, an aralkyl group having 7 to 18 carbon atoms is preferable, and examples thereof include a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, a 1-pyrrolylmethyl group, a 2-(1-pyrrolyl)ethyl group, a p-methylbenzyl group, an m-methylbenzyl group, an o-methylbenzyl group, a p-chlorobenzyl group, an m-chlorobenzyl group, an o-chlorobenzyl group, a p-bromobenzyl group, an m-bromobenzyl group, an o-bromobenzyl group, a p-iodobenzyl group, an m-iodobenzyl group, an o-iodobenzyl group, a p-hydroxybenzyl group, an m-hydroxybenzyl group, an o-hydroxybenzyl group, a p-aminobenzyl group, an m-aminobenzyl group, an o-aminobenzyl group, a p-nitrobenzyl group, an m-nitrobenzyl group, an o-nitrobenzyl group, a p-cyanobenzyl group, an m-cyanobenzyl group, an o-cyanobenzyl group, a 1-hydroxy-2-phenylisopropyl group, and a 1-chloro-2-phenylisopropyl group. Of those, a benzyl group, a p-cyanobenzyl group, an m-cyanobenzyl group, an o-cyanobenzyl group, a 1-phenylethyl group, a 2-phenylethyl group, a 1-phenylisopropyl group, and a 2-phenylisopropyl group are preferable.

For the alkenyl group, an alkenyl group having 2 to 16 carbon atoms is preferable, and examples thereof include a vinyl group, an allyl group, a 1-butenyl group, a 2-butenyl group, a 3-butenyl group, a 1,3-butandienyl group, a 1-methylvinyl group, a styryl group, a 2,2-diphenylvinyl group, a 1,2-diphenylvinyl group, a 1-methylallyl group, a 1,1-dimethylallyl group, a 2-methylallyl group, a 1-phenylallyl group, a 2-phenylallyl group, a 3-phenylallyl group, a 3,3-diphenylallyl group, a 1,2-dimethylallyl group, a 1-phenyl-1-butenyl group, and a 3-phenyl-1-butenyl group. Of those, a styryl group, a 2,2-diphenylvinyl group, and a 1,2-diphenyl vinyl group are preferable.

For the heterocyclic group, a heterocyclic group having 3 to 18 ring atoms is preferable, and examples thereof include a 1-pyrrolyl group, a 2-pyrrolyl group, a 3-pyrrolyl group, a pyrazinyl group, a 2-pyridinyl group, a 1-imidazolyl group, a 2-imidazolyl group, a 1-pyrazolyl group, a 1-indolydinyl group, a 2-indolydinyl group, a 3-indolydinyl group, a 5-indolydinyl group, a 6-indolydinyl group, a 7-indolydinyl group, an 8-indolydinyl group, a 2-imidazopyridinyl group, a 3-imidazopyridinyl group, a 5-imidazopyridinyl group, a 6-imidazopyridinyl group, a 7-imidazopyridinyl group, an 8-imidazopyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a 2-quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a β-carbolin-1-yl group, a β-carbolin-3-yl group, a β-carbolin-4-yl group, a β-carbolin-5-yl group, a β-carbolin-6-yl group, a β-carbolin-7-yl group, a β-carbolin-6-yl group, a β-carbolin-9-yl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthrolin-2-yl group, a 1,7-phenanthrolin-3-yl group a 1,7-phenanthrolin-4-yl group, a 1,7-phenanthrolin-5-yl group, a 1,7-phenanthrolin-6-yl group, a 1,7-phenanthrolin-8-yl group, a 1,7-phenanthrolin-9-yl group, a 1,7-phenanthrolin-10-yl group, a 1,8-phenanthrolin-2-yl group, a 1,8-phenanthrolin-3-yl group, a 1,8-phenanthrolin-4-yl group, a 1,8-phenanthrolin-5-yl group, a 1,8-phenanthrolin-6-yl group, a 1,8-phenanthrolin-7-yl group, a 1,8-phenanthrolin-9-yl group, a 1,8-phenanthrolin-10-yl group, a 1,9-phenanthrolin-2-yl group, a 1,9-phenanthrolin-3-yl group, a 1,9-phenanthrolin-4-yl group, a 1,9-phenanthrolin-5-yl group, a 1,9-phenanthrolin-6-yl group, a 1,9-phenanthrolin-7-yl group, a 1,9-phenanthrolin-8-yl group, a 1,9-phenanthrolin-10-yl group, a 1,10-phenanthrolin-2-yl group, a 1,10-phenanthrolin-3-yl group, a 1,10-phenanthrolin-4-yl group, a 1,10-phenanthrolin-5-yl group, a 2,9-phenanthrolin-1-yl group, a 2,9-phenanthrolin-3-yl group, a 2,9-phenanthrolin-4-yl group, a 2,9-phenanthrolin-5-yl group, a 2,9-phenanthrolin-6-yl group, a 2,9-phenanthrolin-7-yl group, a 2,9-phenanthrolin-8-yl group, a 2,9-phenanthrolin-10-yl group, a 2,8-phenanthrolin-1-yl group, a 2,8-phenanthrolin-3-yl group, a 2,8-phenanthrolin-4-yl group, a 2,8-phenanthrolin-5-yl group, a 2,8-phenanthrolin-6-yl group, a 2,8-phenanthrolin-7-yl group, a 2,8-phenanthrolin-9-yl group, a 2,8-phenanthrolin-10-yl group, a 2,7-phenanthrolin-1-yl group, a 2,7-phenanthrolin-3-yl group, a 2,7-phenanthrolin-4-yl group, a 2,7-phenanthrolin-5-yl group, a 2,7-phenanthrolin-6-yl group, a 2,7-phenanthrolin-8-yl group, a 2,7-phenanthrolin-9-yl group, a 2,7-phenanthrolin-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxadinyl group, a 2-phenoxadinyl group, a 3-phenoxadinyl group, a 4-phenoxadinyl group, a 10-phenoxadinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrol-1-yl group, a 2-methylpyrrol-3-yl group, a 2-methylpyrrol-4-yl group, a 2-methylpyrrol-5-yl group, a 3-methylpyrrol-1-yl group, a 3-methylpyrrol-2-yl group, a 3-methylpyrrol-4-yl group, a 3-methylpyrrol-5-yl group, a 2-t-butylpyrrol-4-yl group, a 3-(2-phenylpropyl)pyrrol-1-yl group, a 2-methyl-1-indolyl group, a 4-methyl-1-indolyl group, a 2-methyl-3-indolyl group, a 4-methyl-3-indolyl group, a 2-t-butyl1-indolyl group, a 4-t-butyl1-indolyl group, a 2-t-butyl3-indolyl group, a 4-t-butyl3-indolyl group, pyrrolidine, pyrazolidine, and piperalyzine.

Of those, a 2-pyridinyl group, a 1-indolydinyl group, a 2-indolydinyl group, a 3-indolydinyl group, a 5-indolydinyl group, a 6-indolydinyl group, a 7-indolydinyl group, an 8-indolydinyl group, a 2-imidazopyridinyl group, a 3-imidazopyridinyl group, a 5-imidazopyridinyl group, a 6-imidazopyridinyl group, a 7-imidazopyridinyl group, an 8-imidazopyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 1-carbazolyl group, a 2-carbazolyl group, a 3-carbazolyl group, a 4-carbazolyl group, and a 9-carbazolyl group are preferable.

The alkoxy group and the aryloxy group are each a group represented by —OX¹, and examples of X¹ include examples similar to those described for the alkyl group, the halogenated alkyl group, and the aryl group.

The alkylamino group and the arylamino group are each a group represented by —NX¹X², and examples of each of X¹ and X² include examples similar to those described for the alkyl group, the halogenated alkyl group, and the aryl group.

Examples of the carboxyl-containing group include methyl ester, ethyl ester, and butyl ester.

Examples of the alkylsilyl group include a trimethylsilyl group, a triethylsilyl group, a t-butyldimethylsilyl group, a vinyldimethylsilyl group, and a propyldimethylsilyl group.

Examples of the arylsilyl group include a triphenylsilyl group, a phenyldimethylsilyl group, and a t-butyldiphenylsilyl group.

In addition, examples of the ring structure formed as a result of the crosslinking of X and Y described above include examples similar to those exemplified for the heterocyclic group.

Preferable examples of a carbene skeleton represented by —X—C—Y (corresponding to each of L² and L⁴) in the general formula (3) include examples similar to the preferable examples when L² and L⁴ in the general formula (1) each have carbene carbon.

In the general formula (3), Z represents an atom that forms a covalent bond with the metal M, the atom being a carbon, silicon, nitrogen, or phosphorus atom, and an A ring including Z represents an aromatic hydrocarbon group which has 3 to 40 ring carbon atoms and may have a substituent, or an aromatic heterocyclic group which has 3 to 40 ring atoms and which may have a substituent.

Examples of the aromatic hydrocarbon group include examples similar to those described above. Examples of the aromatic heterocyclic group include aromatic heterocyclic groups out of the examples of the heterocyclic group.

Of those, preferable examples of the A ring include examples similar to the preferable examples described for L¹ and L³ in the general formula (1).

In addition, the compound represented by the general formula (1) or (2) is preferably a transition metal complex compound having a metal carbene bond represented by the following general formula (4).

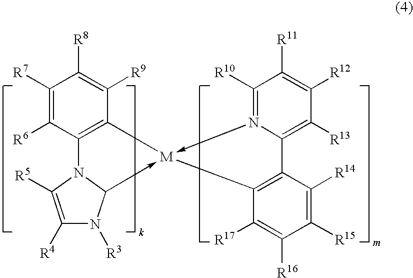

In the general formula (4), a C (carbon atom)→M represents a metal carbene bond, M represents a metal atom of iridium (Ir) or platinum (Pt), k represents an integer of 1 to 3, m represents an integer of 0 to 2, and k+m represents the valence of the metal

### M. At Least Two of (Substituted) N-phenyl-N′-R³-imidazol-2-ylidene-C²,C²′ groups

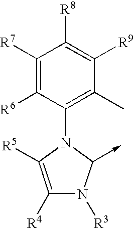

and (substituted) 2-phenylpyridine-N,C²′ groups

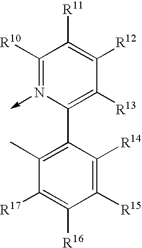

are crosslinked with each other through a crosslinking group —Z¹— (Z¹ has the same meaning as that described above).

In the general formula (4), R³ represents an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 30 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkylsilyl group which has 3 to 30 ring atoms and which may have a substituent, an arylsilyl group which has 6 to 30 carbon atoms and may have a substituent, or a carboxyl-containing group having 1 to 30 carbon atoms.

In the general formula (4), R⁴ to R¹⁷ each independently represent a hydrogen atom, a halogen atom (such as fluorine, bromine, iodine, or chlorine), a thiocyano group or a cyano group, a nitro group, a —S(═O)₂R¹ group or —S(═O)R¹ [R¹ has the same meaning as that described above], an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 30 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkoxy group which has 1 to 30 carbon atoms and may have a substituent, an aryloxy group which has 6 to 30 ring carbon atoms and may have a substituent, an alkylamino group which has 3 to 30 ring atoms and which may have a substituent, an alkylsilyl group which has 3 to 30 ring atoms and which may have a substituent, an arylsilyl group which has 6 to 30 carbon atoms and may have a substituent, or a carboxyl-containing group having 1 to 30 carbon atoms, and adjacent groups of R⁴ to R¹⁷ may be crosslinked with each other.

Specific examples of each of the alkyl group, the halogenated alkyl group, the aromatic hydrocarbon group, the cycloalkyl group, the aralkyl group, the alkenyl group, the heterocyclic group, the alkoxy group, the aryloxy group, the alkylamino group, the arylamino group, the alkylsilyl group, the arylsilyl group, and the carboxyl-containing group include examples similar to those described for R¹ and R² in the general formula (3).

A transition metal complex compound represented by the following general formula (5) in which M in the general formula (4) represents Ir is particularly preferable.

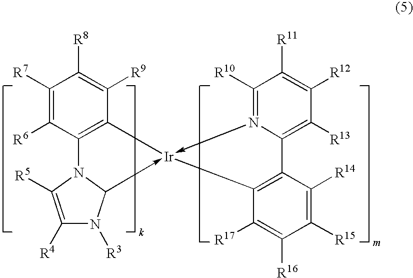

In the general formula (5), a C (carbon atom)→Ir represents a metal carbene bond, k, m, and R³ to R¹⁷ each have the same meaning as that described above, and at least two of (substituted) N-phenyl-N′-R³-imidazol-2-ylidene-C²,C²′ groups and (substituted) 2-phenylpyridine-N,C²′ groups are crosslinked with each other through a crosslinking group —Z¹— (Z¹ has the same meaning as that described above).

A substituent for each of the groups in the general formulae (1) to (5) is, for example, a substituted or unsubstituted aryl group having 5 to 50 ring carbon atoms, a substituted or unsubstituted alkyl group having 1 to 50 carbon atoms, a substituted or unsubstituted alkoxy group having 1 to 50 carbon atoms, a substituted or unsubstituted aralkyl group having 6 to 50 ring carbon atoms, a substituted or unsubstituted aryloxy group having 5 to 50 ring carbon atoms, a substituted or unsubstituted arylthio group having 5 to 50 ring carbon atoms, a substituted or unsubstituted alkoxycarbonyl group having 1 to 50 ring carbon atoms, an amino group, a halogen atom, a cyano group, a nitro group, a hydroxyl group, or a carboxyl group.

Of those, an alkyl group having 1 to 10 carbon atoms, a cycloalkyl group having 5 to 7 carbon atoms, or an alkoxy group having 1 to 10 carbon atoms is preferable, an alkyl group having 1 to 6 carbon atoms or a cycloalkyl group having 5 to 7 carbon atoms is more preferable, and a methyl group, an ethyl group, an n-propyl group, an isopropyl group, an n-butyl group, a sec-butyl group, a tert-butyl group, an n-pentyl group, an n-hexyl group, a cyclopentyl group, or a cyclohexyl group is particularly preferable.

Next, an example of a method of producing the transition metal complex compound represented by the general formula (1) of the present invention will be described below.

1. Method of Synthesizing Transition Metal Complex Compound Represented by General Formula (5) (k=3, m=0)

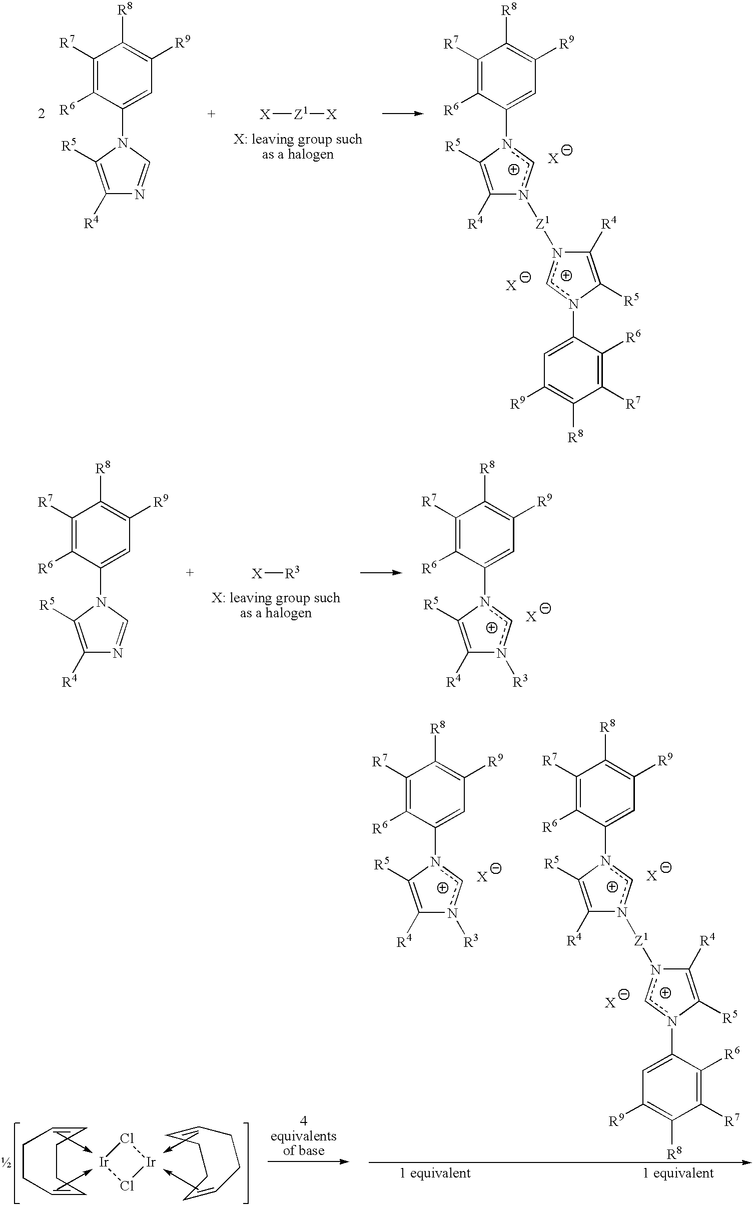

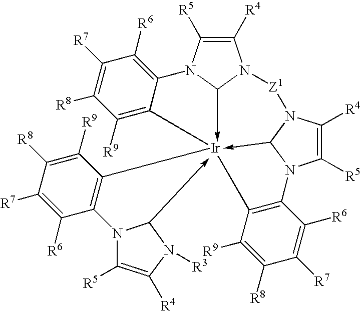

2. Method of Synthesizing Transition Metal Complex Compound Represented by General Formula (5) (k=2, m=1)

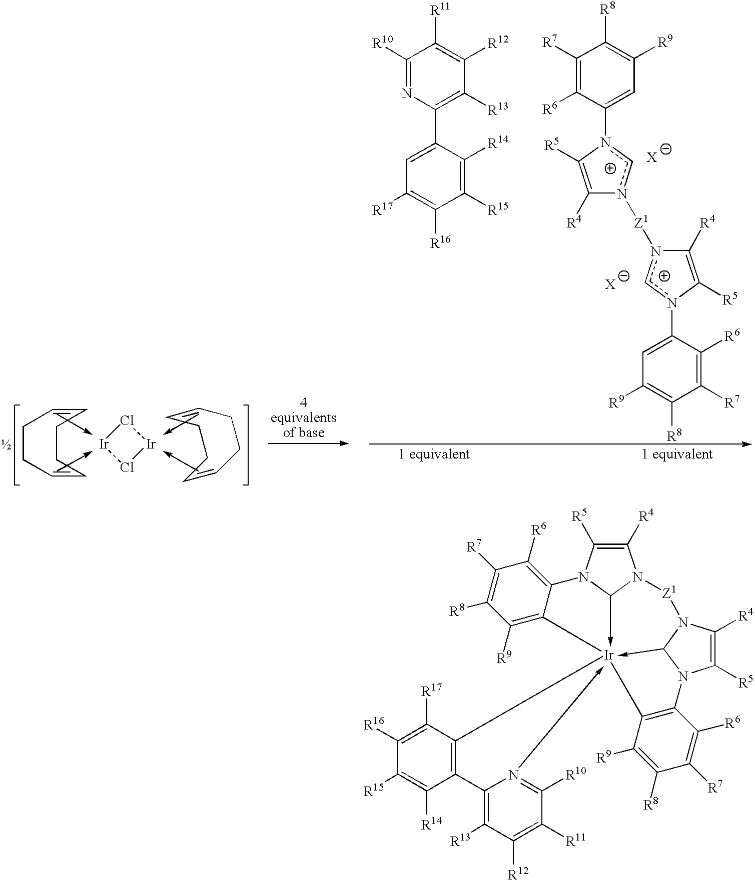

In each of the above examples 1 and 2., the ligands may be added in two steps (the order in which the ligands are added is arbitrary), that is, the compound may be synthesized in two stages.

Next, a general formula (6) will be described.

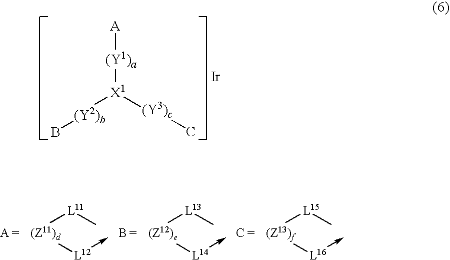

In the general formula (6), A represents a crosslinking bidentate ligand group formed of L¹¹-(Z¹¹)^{d}-L¹², B represents a crosslinking bidentate ligand group formed of L¹³-(Z¹²)ₑ-L¹⁴, C represents a crosslinking bidentate ligand group formed of L¹⁵-(Z¹³)_{f}-L¹⁶, L¹¹-, L¹³-, and L¹⁵- each represent a covalent bond to iridium (Ir) (L¹¹-Ir, L¹³-Ir, and L¹⁵-Ir), and L¹²→, L¹⁴→, and L¹⁶→ each represent a coordinate bond to Ir (L¹²→Ir, L¹⁴-Ir, and L¹⁶→Ir).

In the general formula (6), X¹ represents a crosslinking group formed of a non-cyclic structure having 1 to 18 atoms, the crosslinking group being a trivalent residue of a compound formed of an atom selected from the group consisting of a hydrogen atom, a carbon atom, a silicon atom, a nitrogen atom, a sulfur atom, an oxygen atom, a phosphorus atom, and a boron atom, and the crosslinking group may have a substituent.

Examples of X¹ described above include the following structures.

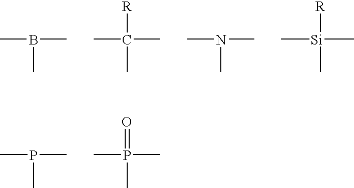

Of those, the following structures

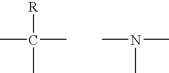

are preferable, and the following structure

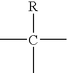

is more preferable.

Examples of R include examples similar to those described above for R¹, and R preferably represents, for example, a hydrogen atom, a methyl group, an ethyl group, an n-propyl group, an isopropyl group, an n-butyl group, an isobutyl group, a sec-butyl group, a t-butyl group, an n-pentyl group, an n-hexyl group, a cyclohexyl group, a phenyl group, a methoxy group, or an ethoxy group, or more preferably represents a hydrogen atom, a methyl group, an ethyl group, a t-butyl group, or a phenyl group.

In the general formula (6), Y¹ represents a crosslinking group for bonding X¹ and A, Y² represents a crosslinking group for bonding X¹ and B, Y³ represents a crosslinking group for bonding X¹ and C, Y¹ is bonded to L¹¹, L¹², or Z¹¹, Y² is bonded to L¹³, L¹⁴, or Z¹², Y³ is bonded to L¹⁵, L¹⁶, or Z¹³, and Y¹, Y², and Y³ each independently represent a divalent residue of a compound formed of an atom selected from the group consisting of a hydrogen atom, a carbon atom, a silicon atom, a nitrogen atom, a sulfur atom, an oxygen atom, a phosphorus atom, and a boron atom, and the divalent residue may have a substituent.

In the general formula (6), a, b, and c each independently represent an integer of 0 to 10, or preferably 0 to 3, and, when a, b, or c represents 2 or more, multiple Y¹'s, multiple Y²'s, or multiple Y³'s may be identical to or different from each other.

Specific examples of each of Y¹, Y², and Y³ include —CR¹R²—, —SiR¹R²—, —NR¹—, —O—, —S—, —PR¹—, and —BR¹—. R¹ and R² each independently have the same meaning as that described above, and may be identical to or different from each other. In addition, R¹ and R² may be crosslinked with X¹, or may be crosslinked with each other. When a, b, or c represents 2 or more, each of Y¹'s, each of Y²'s, or each of Y³'s can be arbitrarily selected from —CR¹R²—, —SiR¹R²—, —NR¹—, —O—, —S—, —PR¹—, and —BR¹— described above. In addition, in that case, R¹ and R² between adjacent Y¹'s, between adjacent Y²'s, or between adjacent Y³'s may be crosslinked with X, or may be crosslinked with each other.

A preferable specific structure for each of Y¹, Y², and Y³ is, for example, —CH₂—, —CMe₂-, —CMeH—, —CEtH—, —O—, —S—, —SiH₂—, —SiMe₂-, —SiMeH—, —SiEtH—, —NH—, —NMe-, —NEt-, —PH—, —PMe-, —PEt-, —BH—, —BMe-, or —BEt- (Me represents a methyl group, and Et represents an ethyl group).

In the general formula (6), Z¹¹ represents a crosslinking group for bonding L¹¹ and L¹², Z¹² represents a crosslinking group for bonding L¹³ and L¹⁴, Z¹³ represents a crosslinking group for bonding L¹⁵ and L¹⁶, Z¹¹, Z¹², and Z¹³ each independently represent a divalent residue of a compound formed of an atom selected from the group consisting of a hydrogen atom, a carbon atom, a silicon atom, a nitrogen atom, a sulfur atom, an oxygen atom, a phosphorus atom, and a boron atom, and the divalent residue may have a substituent, and, when Z¹¹ is directly bonded to Y¹, when Z¹² is directly bonded to Y², or when Z¹³ is directly bonded to Y³, Z¹¹, Z¹², and Z¹³ each represent a corresponding trivalent group.

In the general formula (6), d, e, and f each independently represent an integer of 0 to 10, or preferably 0 to 3, and, when d, e, or f represents 2 or more, multiple Z¹¹'s, multiple Z¹²'s, or multiple Z¹³'s may be identical to or different from each other.

In the general formula (6), L¹¹, L¹³, and L¹⁵ each independently represent a divalent aromatic hydrocarbon group which has 6 to 30 ring carbon atoms and may have a substituent, a divalent heterocyclic group which has 3 to 30 ring atoms and which may have a substituent, a divalent carboxyl-containing group which has 1 to 30 carbon atoms and may have a substituent, a divalent amino group- or hydroxyl group-containing hydrocarbon group which may have a substituent, a cycloalkylene group which has 3 to 50 ring carbon atoms and may have a substituent, an alkylene group which has 1 to 30 carbon atoms and may have a substituent, an alkenylene group which has 2 to 30 carbon atoms and may have a substituent, or an aralkylene group which has 7 to 40 carbon atoms and may have a substituent, and, when L¹¹ is directly bonded to Y¹, when L¹³ is directly bonded to Y², or when L¹⁵ is directly bonded to Y³, L¹¹, L¹³, and L¹⁵ each represent a corresponding trivalent group.

Examples of each of the divalent aromatic hydrocarbon group, the divalent heterocyclic group, the divalent carboxyl-containing group, the cycloalkylene group, the alkylene group, the alkenylene group, and the aralkylene group include examples obtained by making examples of each of the aromatic hydrocarbon group, the heterocyclic group, the carboxyl-containing group, the cycloalkyl group, the alkyl group, the alkenyl group, and the aralkyl group described above for R^{a} to Rⁱ divalent, and the same holds true for preferable examples of each of the groups.

In addition, examples of the divalent amino group- or hydroxyl group-containing hydrocarbon group include an amino group having a hydrocarbon group represented by each of L¹¹, L¹³, and L¹⁵ described above and a group obtained by substituting a hydrogen atom of the hydrocarbon group by a hydroxyl group.

In addition, L¹¹, L¹³, and L¹⁵ described above each preferably represent an aromatic hydrocarbon group or a heterocyclic group, for example, any one of the following structures. Of those structures, a phenyl group and a substituted phenyl group are preferable. It should be noted that, in each of the following examples, Y represents an adjacent bonding group, that is, L¹², L¹⁴, or L¹⁶.

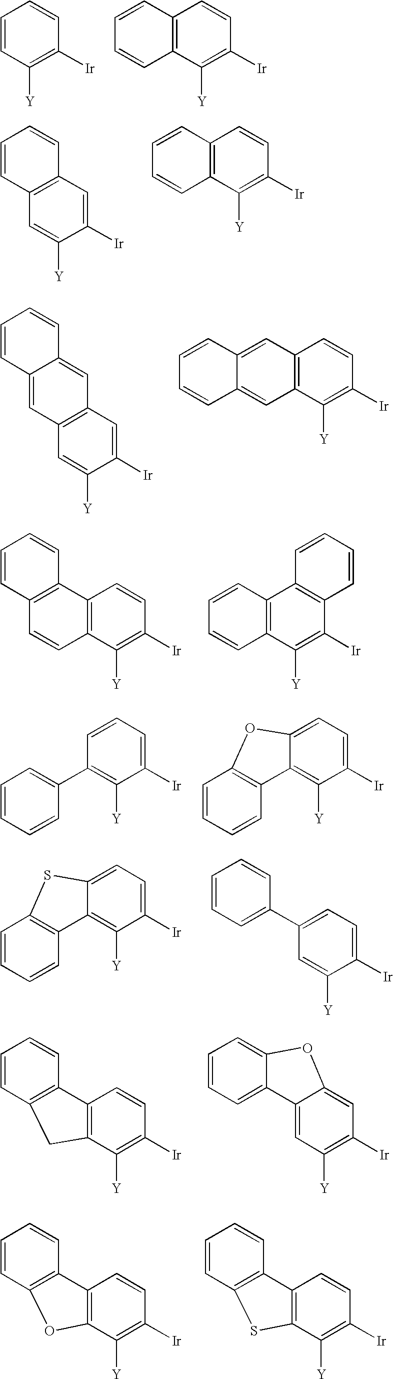

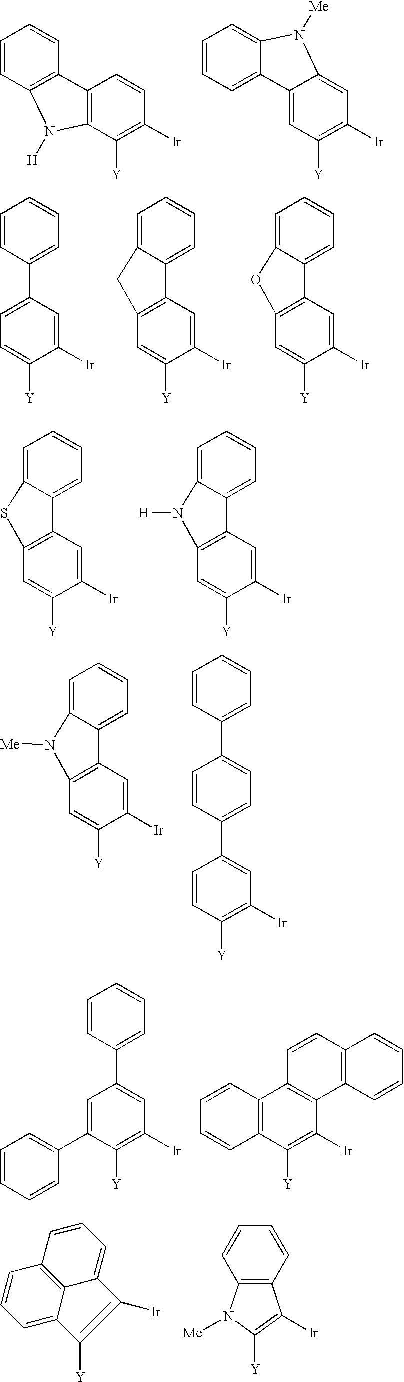

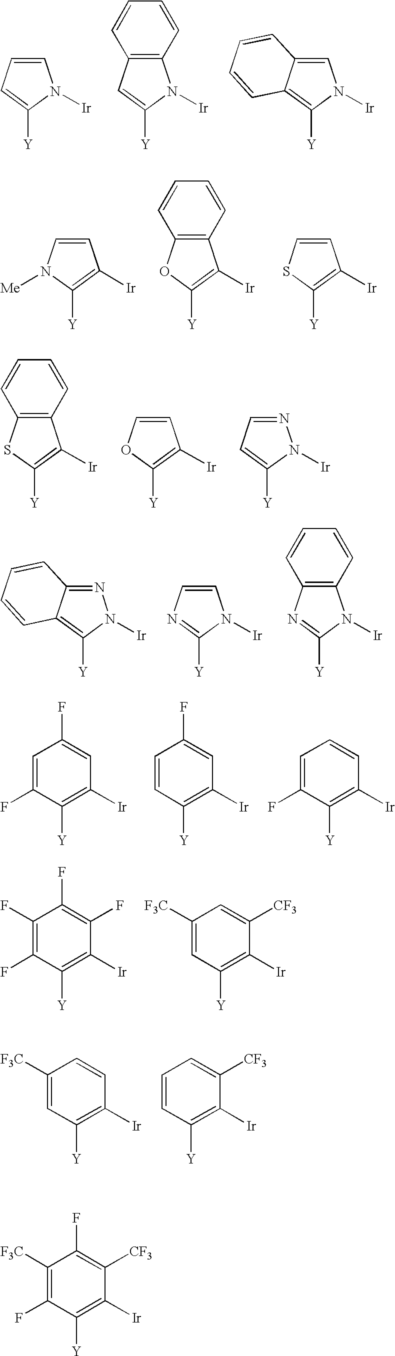

In the general formula (6), L¹², L¹⁴, and L¹⁶ each independently represent a monovalent group which has carbene carbon and which may have a substituent, or a monovalent heterocyclic group which has 3 to 30 ring atoms and which may have a substituent, and, when L¹² is directly bonded to Y¹, when L¹⁴ is directly bonded to Y², or when L¹⁶ is directly bonded to Y³, L¹², L¹⁴, and L¹⁶ each represent a corresponding divalent group. It is preferable that at least one of L¹², L¹⁴, and L¹⁶ represent a group having carbene carbon, and it is more preferable that L¹², L¹⁴, and L¹⁶ each represent a group having carbene carbon.

In addition, in ordinary cases, the monovalent group having carbene carbon is preferably one that forms stable carbene together with a metal. Specific examples of such group include monovalent groups such as diarylcarbene, cyclic diaminocarbene, imidazol-2-ylidene, 1,2,4-triazol-3-ylidene, 1,3-thiazol-2-ylidene, non-cyclic diaminocarbene, non-cyclic aminooxycarbene, non-cyclic aminothiocarbene, cyclic diborylcarbene, non-cyclic diborylcarbene, phosphinosilylcarbene, phosphinophosphinocarbene, sulfenyltrifluoromethylcarbene, and sulfenylpentafluorothiocarbene groups (reference: Chem. Rev. 2000, 100, p 39).

Of those, imidazol-2-ylidene, 1,2,4-triazol-3-ylidene, and cyclic diaminocarbene groups are preferable, and imidazol-2-ylidene and 1,2,4-triazol-3-ylidene groups are more preferable. Specific structures of them are listed below. It should be noted that, in each of the following examples, an A ring represents an adjacent bonding group, that is, L¹¹, L¹³, or L¹⁵, and R³ has the same meaning as that of each of R¹ and R² described above.

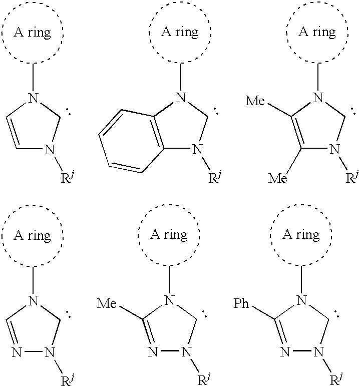

Further, specific preferable examples of the case where L¹², L¹⁴, and L¹⁶ each represent a group free of carbene carbon, that is, specific preferable examples of a heterocyclic group are listed below. In each of the following examples, carbon to be bonded to L¹¹, L¹³, or L¹⁵ is preferably adjacent to a hetero atom coordinated to iridium. Each of the following examples may be substituted.

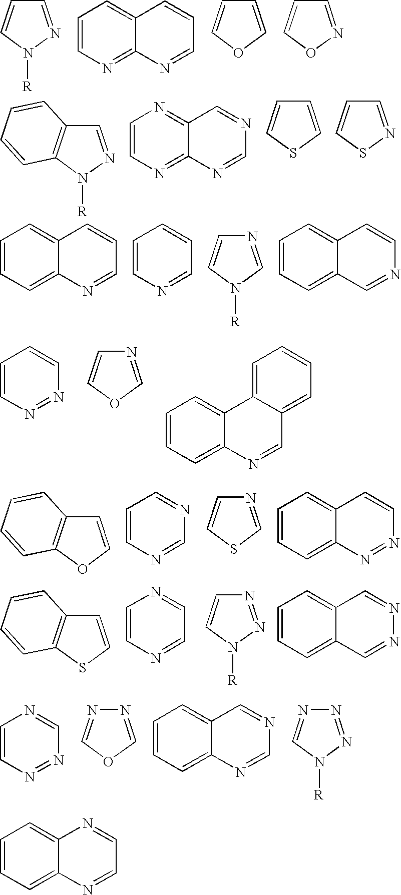

The total weight of atoms of which the following crosslinking site (7) in the general formula (6) is formed is preferably 200 or less, or more preferably 100 or less.

A reduction in total sum of the atomic weights of the crosslinking site (7) is advantageous for the maintenance of a purity at a high level in a sublimation process upon production of an organic EL device because the molecular weight of a complex reduces in an amount corresponding to the amount in which the total sum of the atomic weights is reduced when A, B, and C sites in the general formula (6) are identical to one another. Therefore, a reduction in total sum of the atomic weights of the crosslinking site has an increasing effect on the purity of the complex or of the organic EL device.

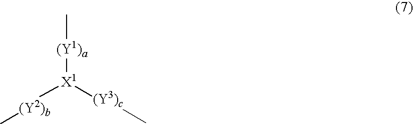

A substituent for each of the groups in the general formula (6) is, for example, a substituted or unsubstituted aryl group having 5 to 50 ring carbon atoms, a substituted or unsubstituted alkyl group having 1 to 50 carbon atoms, a substituted or unsubstituted alkoxy group having 1 to 50 carbon atoms, a substituted or unsubstituted aralkyl group having 6 to 50 ring carbon atoms, a substituted or unsubstituted aryloxy group having 5 to 50 ring carbon atoms, a substituted or unsubstituted arylthio group having 5 to 50 ring carbon atoms, a substituted or unsubstituted alkoxycarbonyl group having 1 to 50 ring carbon atoms, an amino group, a halogen atom, a cyano group, a nitro group, a hydroxyl group, or a carboxyl group.

Of those, an alkyl group having 1 to 10 carbon atoms, a cycloalkyl group having 5 to 7 carbon atoms, or an alkoxy group having 1 to 10 carbon atoms is preferable, an alkyl group having 1 to 6 carbon atoms or a cycloalkyl group having 5 to 7 carbon atoms is more preferable, and a methyl group, an ethyl group, an n-propyl group, an isopropyl group, an n-butyl group, a sec-butyl group, a tert-butyl group, an n-pentyl group, an n-hexyl group, a cyclopentyl group, or a cyclohexyl group is particularly preferable.

Next, a production process for an example of a method of producing the transition metal complex compound represented by the general formula (6) of the present invention will be shown below (reference: JACS 96, 16, 1974, p 5189)

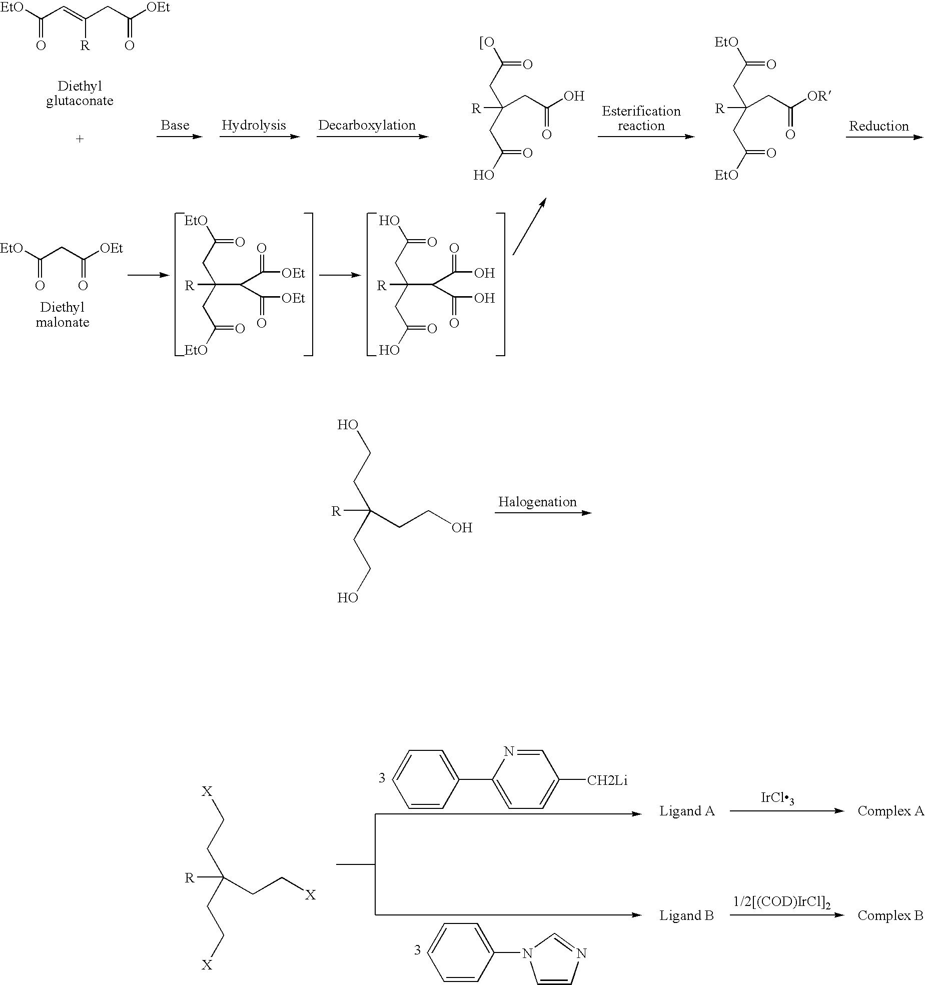

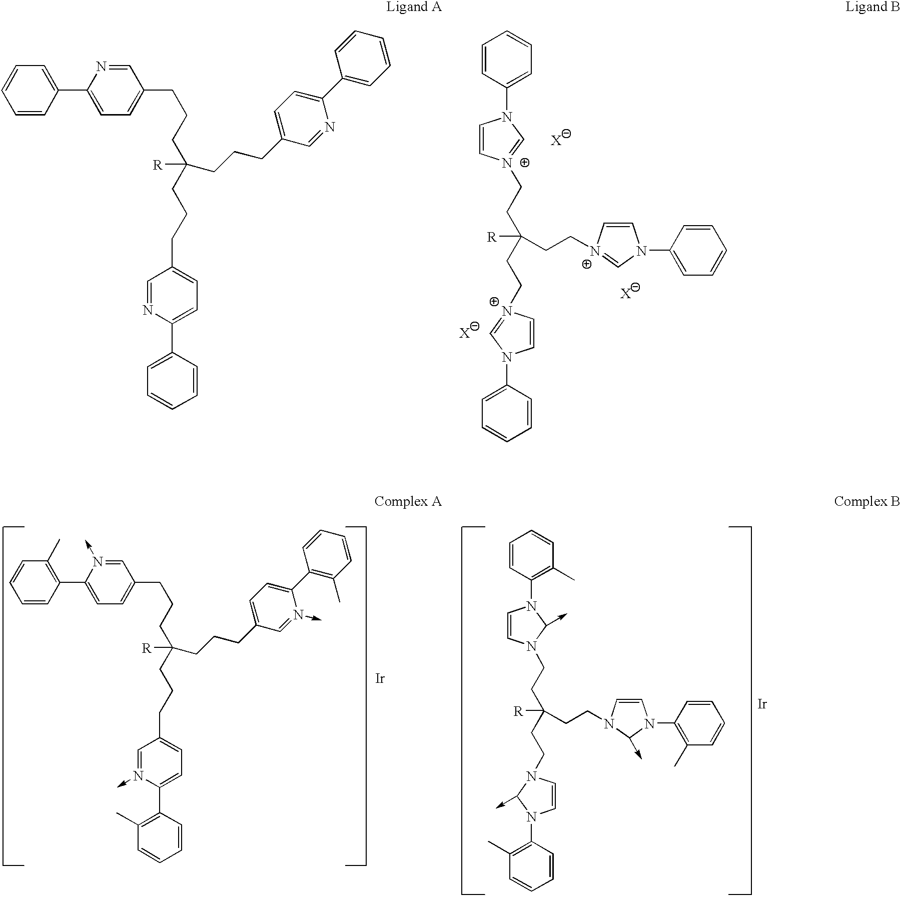

The organic EL device of the present invention is an organic EL device including an organic thin film layer formed of one or multiple layers having at least a light emitting layer, the organic thin film layer being interposed between a pair of electrodes formed of a cathode and an anode, in which at least one layer of the organic thin film layer contains the transition metal complex compound, preferably contains the transition metal complex compound represented by any one of general formulae (1), (2), (4), (5) and (6), and more preferably contains the transition metal complex compound represented by the general formulae (4) or (5).

The content of the metal complex compound of the present invention in the organic thin film layer is typically 0.1 to 100 wt %, or preferably 1 to 30 wt % with respect to the mass of the entirety of the light emitting layer.

In the organic EL device of the present invention, the light emitting layer preferably contains the transition metal complex compound of the present invention as a light emitting material or as a dopant. In addition, the light emitting layer is typically formed into a thin film by vacuum deposition or application; a layer containing the transition metal complex compound of the present invention is preferably formed into a film by application because the application can simplify a production process.

In the organic EL device of the present invention, when the organic thin film layer is of a single-layer type, the organic thin film layer is a light emitting layer, and the light emitting layer contains the transition metal complex compound of the present invention. In addition, examples of a multilayer type organic EL device include: an organic EL device having a constitution of (anode/hole injecting layer (hole transporting layer)/light emitting layer/cathode); (anode/light emitting layer/electron injecting layer (electron transporting layer)/cathode); and (anode/hole injecting layer (hole transporting layer)/light emitting layer/electron injecting layer (electron transporting layer)/cathode).

The anode of the organic EL device of the present invention supplies a hole to the hole injecting layer, the hole transporting layer, the light emitting layer, or the like, and is effective when the anode has a work function of 4.5 eV or more. Examples of a material that can be used for the anode include a metal, an alloy, a metal oxide, an electroconductive compound, and a mixture of them. Specific examples of a material for the anode include: conductive metal oxides such as tin oxide, zinc oxide, indium oxide, and indium tin oxide (ITO) ; metals such as gold, silver, chromium, and nickel; a mixture or laminate of the conductive metal oxides and the metals; inorganic conductive substances such as copper iodide and copper sulfide; organic conductive materials such as polyaniline, polythiophene, and polypyrrole; and a laminate of the conductive substances or materials and ITO. Of those, the conductive metal oxides are preferable, and ITO is particularly preferably used in terms of, for example, productivity, high conductivity, and transparency. The thickness of the anode can be appropriately selected depending on the material.

The cathode of the organic EL device of the present invention supplies an electron to the electron injecting layer, the electron transporting layer, the light emitting layer, or the like. Examples of a material that can be used for the cathode include a metal, an alloy, a metal halide, a metal oxide, an electroconductive compound, and a mixture of them. Specific examples of a material for the cathode include: alkali metals (such as Li, Na, and K), and fluorides or oxides of the metals; alkali earth metals (such as Mg and Ca), and fluorides or oxides of the metals; gold; silver; lead; aluminum; a sodium-potassium alloy or a sodium-potassium mixed metal; a lithium-aluminum alloy or a lithium-aluminum mixed metal; a magnesium-silver alloy or a magnesium-silver mixed metal; and rare earth metals such as indium and ytterbium. Of those, aluminum, the lithium-aluminum alloy or the lithium-aluminum mixed metal, the magnesium-silver alloy or the magnesium-silver mixed metal, or the like is preferable. The cathode may be structured by a single layer containing any one of the materials, or may be structured by laminating layers each containing anyone of the materials. For example, the cathode is preferably of a laminate structure of aluminum/lithium fluoride or of aluminum/lithium oxide. The thickness of the cathode can be appropriately selected depending on the material.

Each of the hole injecting layer and hole transporting layer of the organic EL device of the present invention only needs to have any one of a function of injecting a hole from the anode, a function of transporting a hole, and a function of blocking an electron injected from the cathode. Specific examples of a material for each of the layers include: carbazole derivatives; triazole derivatives; oxazole derivatives; oxadiazole derivatives; imidazole derivatives; polyarylalkane derivatives; pyrazoline derivatives; pyrazolone derivatives; phenylenediamine derivatives; arylamine derivatives; amino-substituted chalcone derivatives; styrylanthracene derivatives; fluorenone derivatives; hydrazone derivatives; stilbene derivatives; silazane derivatives; aromatic tertiary amine compounds; styrylamine compounds; aromatic dimethylidyne-based compounds; porphyrin-based compounds; polysilane-based compounds; poly(N-vinylcarbazole) derivatives; aniline-based copolymers; conductive and high-molecular-weight oligomers such as a thiophene oligomer and polythiophene; organic silane derivatives; and the transition metal complex compound of the present invention. In addition, each of the hole injecting layer and the hole transporting layer may be of a single-layered structure formed of one or two or more of the materials, or may be of a multi-layered structure formed of multiple layers identical to or different from each other in composition.

Each of the electron injecting layer and electron transporting layer of the organic EL device of the present invention only needs to have any one of a function of injecting an electron from the cathode, a function of transporting an electron, and a function of blocking a hole injected from the anode. Specific examples of a material for each of the layers include: triazole derivatives; oxazole derivatives; oxadiazole derivatives; imidazole derivatives; fluorenone derivatives; anthraquinodimethane derivatives; anthrone derivatives; diphenylquinone derivatives; thiopyranedioxide derivatives; carbodiimide derivatives; fluorenylidenemethane derivatives; distyrylpyrazine derivatives; aromatic tetracarboxylic anhydrides such as naphthalene and perylene; various metal complexes typified by metal complexes of phthalocyanine derivatives and 8-quinolinol derivatives, a metal phthalocyanine, and metal complexes using benzoxazole or benzothiazole as a ligand; organic silane derivatives; and the transition metal complex compound of the present invention. In addition, each of the electron injecting layer and the electron transporting layer may be of a single-layered structure formed of one or two or more of the materials, or may be of a multi-layered structure formed of multiple layers identical to or different from each other in composition.

Further, examples of an electron transporting material for use in each of the electron injecting layer and the electron transporting layer include the following compounds.

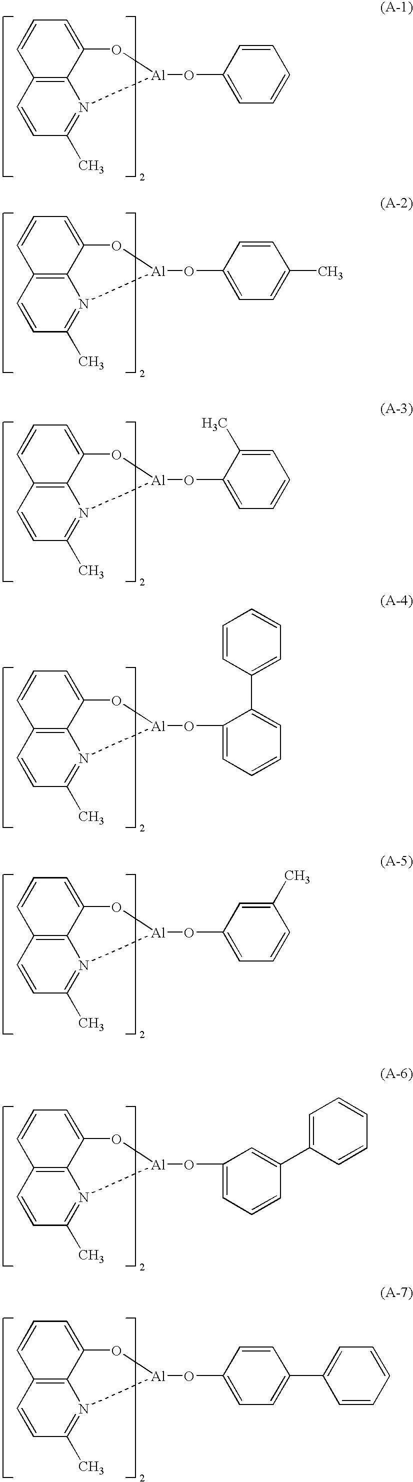

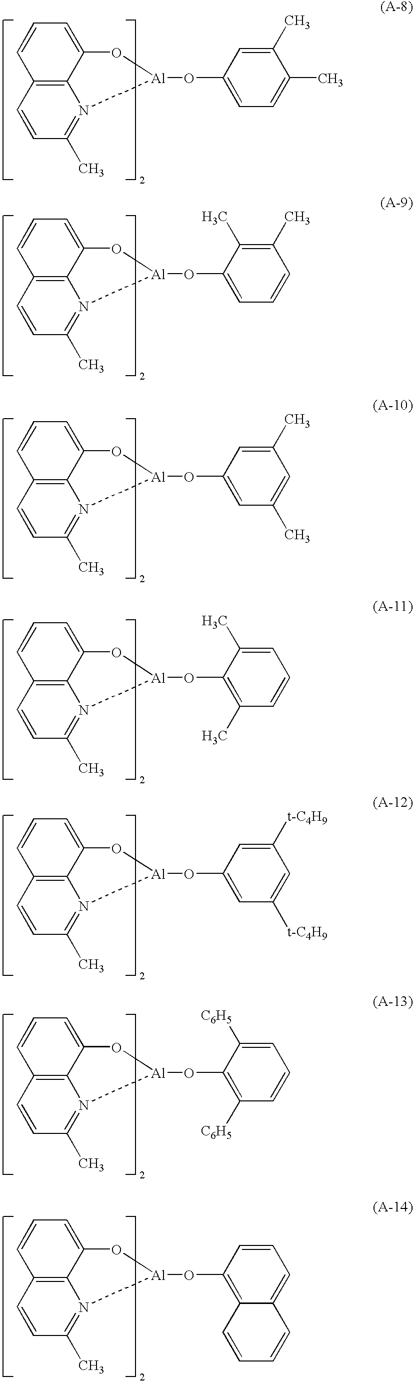

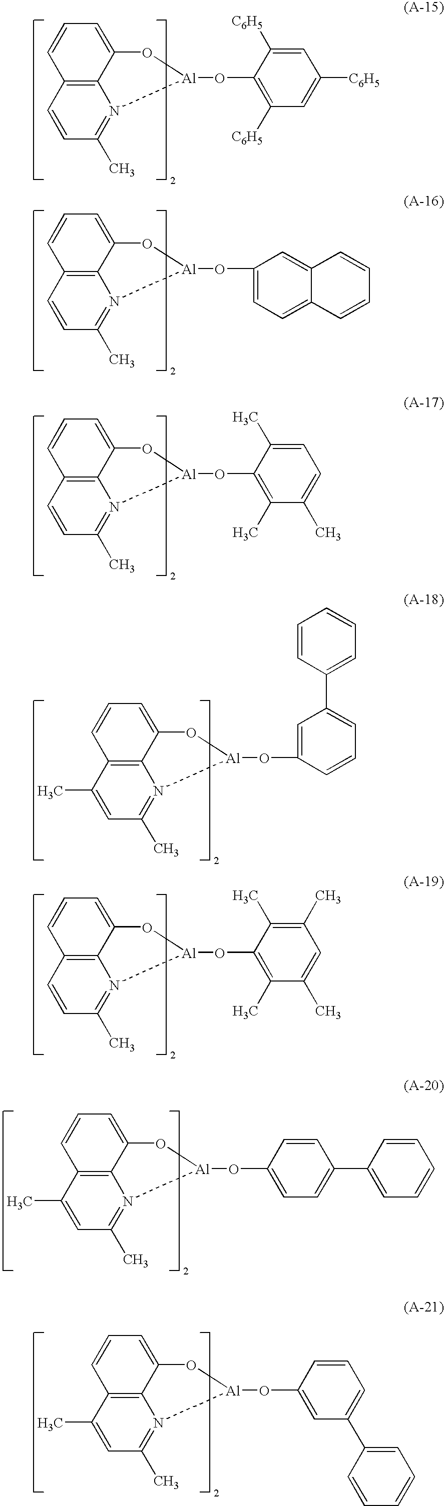

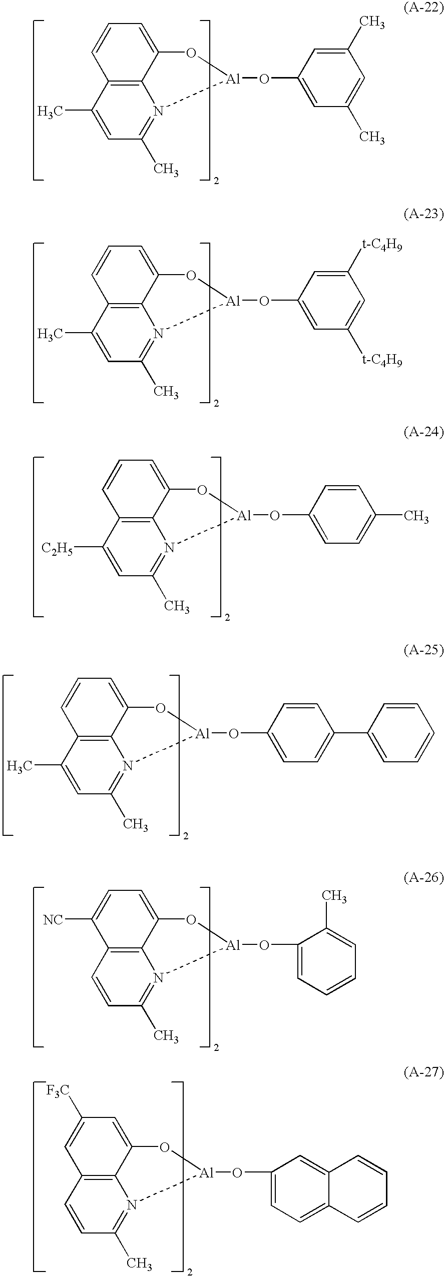

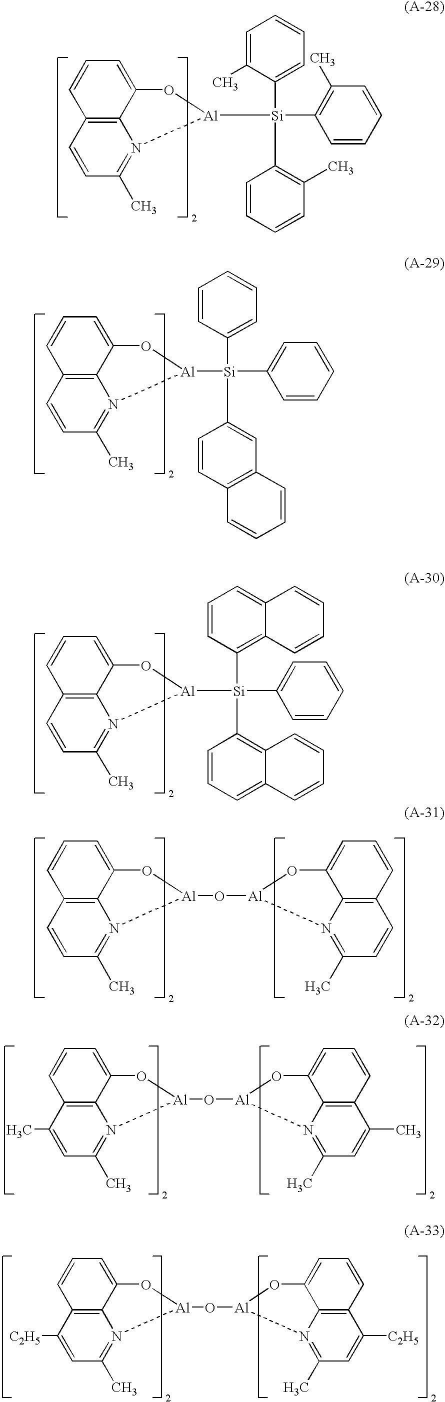

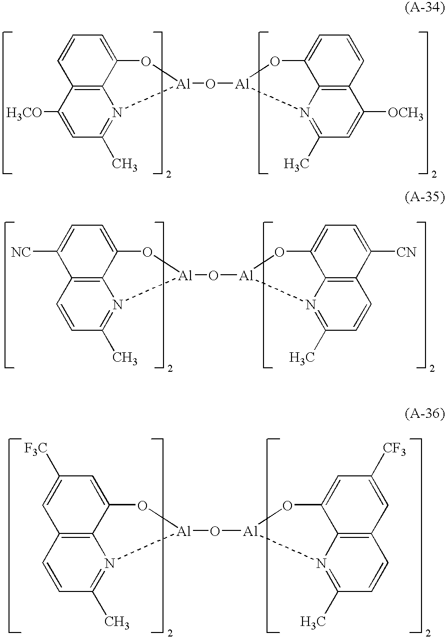

In the organic EL device of the present invention, at least one of the electron injecting layer and/or the electron transporting layer preferably contains a n-electron-deficient, nitrogen-containing heterocyclic derivative as a main component.

Preferable examples of the n-electron-deficient, nitrogen-containing heterocyclic derivative include: a derivative of a nitrogen-containing five-membered ring selected from the group consisting of a benzimidazole ring, a benztriazole ring, a pyridinoimidazole ring, a pyrimidinoimidazole ring, and a pyridazinoimidazole ring; and a nitrogen-containing six-membered ring derivative formed of a pyridine ring, a pyrimidine ring, a pyrazine ring, or a triazine ring. A preferable example of the structure of the nitrogen-containing five-membered ring derivative is one represented by the following general formula B-I. Preferable examples of the structure of the nitrogen-containing six-membered ring derivative include those represented by the following general formulae C-I, C-II, C-IV, C-V, and C-VI. Of those, the structures represented by the general formulae C-I and C-II are particularly preferable.

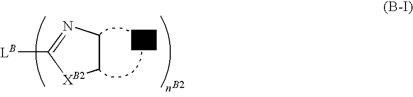

In the general formula (B-I), L^{B} represents a linking group having two or more valences. The linking group is preferably formed of carbon, silicon, nitrogen, boron, oxygen, sulfur, a metal, a metal ion, or the like, more preferably a carbon atom, a nitrogen atom, a silicon atom, a boron atom, an oxygen atom, a sulfur atom, an aromatic hydrocarbon ring, a heteroaromatic ring, and still more preferably a carbon atom, a silicon atom, an aromatic hydrocarbon ring, or a heteroaromatic ring.

L^{B} may have a substituent. For the substituent, an alkyl group, an alkenyl group, an alkynyl group, an aromatic hydrocarbon group, an amino group, an alkoxyl group, an aryloxyl group, an acyl group, an alkoxycarbonyl group, an aryloxycarbonyl group, an acyloxyl group, an acylamino group, an alkoxycarbonylamino group, an aryloxycarbonylamino group, a sulfonylamino group, a sulfamoyl group, a carbamoyl group, an alkylthio group, an arylthio group, a sulfonyl group, a halogen atom, a cyano group, and a heteroaromatic group are preferable. An alkyl group, an aryl group, an alkoxyl group, an aryloxyl group, a halogen atom, a cyano group, and a heteroaromatic group are more preferable. An alkyl group, an aryl group, an alkoxyl group, an aryloxyl group, and a heteroaromatic group are still more preferable, and an alkyl group, an aryl group, an alkoxyl group, and a heteroaromatic group are particularly preferable.

Specific examples of the linking group represented by L^{B} include the following.

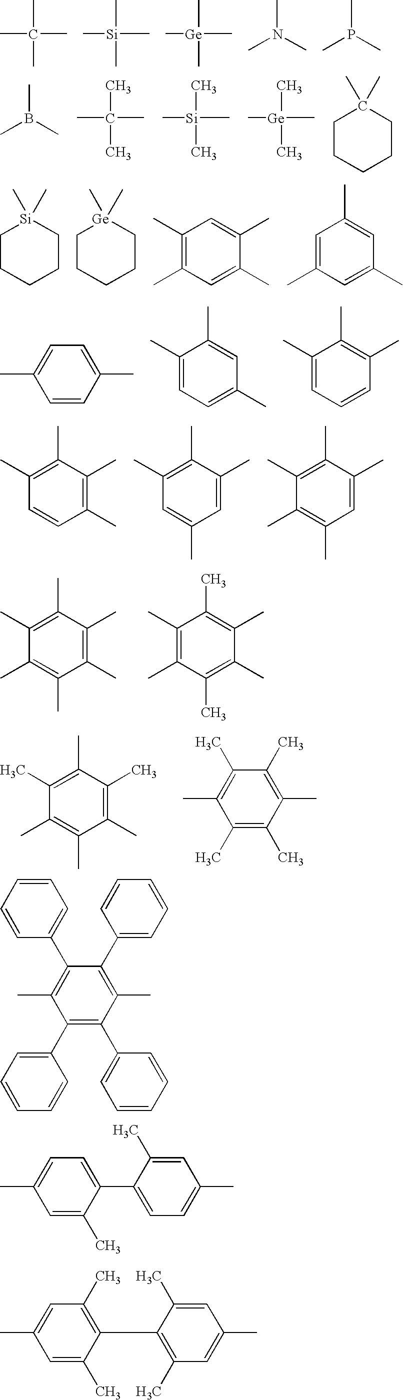

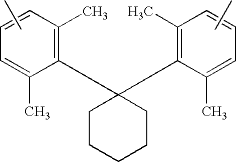

In the general formula (B-I), X^{B2} represents —O—, —S— or ═N—R^{B2}. R^{B2} represents a hydrogen atom, an aliphatic hydrocarbon group, an aryl group, or a heterocyclic group.

The aliphatic hydrocarbon group represented by R^{B2} is a linear, branched or cyclic alkyl group (an alkyl group preferably having 1 to 20 carbon atoms, more preferably 1 to 12 carbon atoms, or particularly preferably 1 to 8 carbon atoms, such as a methyl group, an ethyl group, an iso-propyl group, a tert-butyl group, an n-octyl group, an n-decyl group, an n-hexadecyl group, a cyclopropyl group, a cyclopentyl group, or a cyclohexyl group), an alkenyl group (an alkenyl group preferably having 2 to 20 carbon atoms, more preferably 2 to 12 carbon atoms, or particularly preferably 2 to 8 carbon atoms, such as a vinyl group, an allyl group, a 2-butenyl group, or a 3-pentenyl group), or an alkynyl group (an alkynyl group preferably having 2 to 20 carbon atoms, more preferably 2 to 12 carbon atoms, or particularly preferably 2 to 8 carbon atoms, such as a propargyl group or a 3-pentynyl group). Of those, an alkyl group is more preferable.

The aryl group represented by R^{B2} is a group having a single ring or a condensed ring. The aryl group preferably has 6 to 30 carbon atoms, more preferably has 6 to 20 carbon atoms, and still more preferably has 6 to 12 carbon atoms, and examples thereof include a phenyl group, a 2-methylphenyl group, a 3-methylphenyl group, a 4-methylphenyl group, a 2-methoxyphenyl group, a 3-trifluoromethylphenyl group, a pentafluorophenyl group, a 1-naphthyl group, and a 2-naphthyl group.

The heterocyclic group represented by R^{B2} has a single ring or a condensed ring (a heterocyclic group preferably having 1 to 20 carbon atoms, more preferably 1 to 12 carbon atoms, and still more preferably 2 to 10 carbon atoms), and is preferably a heteroaromatic group having at least one of a nitrogen atom, an oxygen atom, a sulfur atom, and a selenium atom. Examples of the heteroaromatic group include pyrrolidine, piperidine, piperazine, morpholine, thiophene, selenophene, furan, pyrrol, imidazole, pyrazole, pyridine, pyrazine, pyridazine, pyrimidine, triazole, triazine, indole, indazole, purine, thiazoline, thiazole, thiadiazole, oxazoline, oxazole, oxadiazole, quinoline, isoquinoline, phthalazine, naphthylidine, quinoxaline, quinazoline, cinnoline, puteridine, acridine, phenanthroline, phenazine, tetrazole, benzoimidazole, benzoxazole, benzothiazole, benzotriazole, tetrazaindene, carbazole, and azepine. Of those, furan, thiophene, pyridine, pyrazine, pyrimidine, pyridazine, triazine, quinoline, phthalazine, naphthylidine, quinoxaline, and quinazoline are preferable, furan, thiophene, pyridine, and quinoline are more preferable, and quinoline is still more preferable.

The aliphatic hydrocarbon group, the aryl group, and the heterocyclic group each of which is represented by R^{B2} may have a substituent, and examples of the substituent include the same substituents as those in the case of L^{B}.

Examples of R^{B2} preferably include an alkyl group, an aryl group, and a heteroaromatic group, more preferably an aryl group and a heteroaromatic group, and still more preferably an aryl group.

X^{B2} preferably represents —O— or ═N—R^{B2}, more preferably represents ═N—R^{B2}, or particularly preferably represents ═N—Ar^{B2} (where Ar^{B2} represents an aryl group (aryl group having preferably 6 to 30 carbon atoms, more preferably 6 to 20 carbon atoms, or still more preferably 6 to 12 carbon atoms) or a heteroaromatic group (heteroaromatic group having preferably 1 to 20 carbon atoms, more preferably 1 to 12 carbon atoms, or still more preferably 2 to 10 carbon atoms), or preferably represents an aryl group).

Z^{B2} represents a group of atoms necessary for forming an aromatic ring. The aromatic ring formed with the group of atoms represented by Z^{B2} may be any one of an aromatic hydrocarbon ring and a heteroaromatic ring. Specific examples of the aromatic ring include a benzene ring, a pyridine ring, a pyrazine ring, a pyrimidine ring, a pyridazine ring, a triazine ring, a pyrrole ring, a furan ring, a thiophene ring, a selenophene ring, a tellurophene ring, an imidazole ring, a thiazole ring, a selenazole ring, a tellurazole ring, a thiadiazole ring, an oxadiazole ring, and a pyrazole ring. Of those rings, a benzene ring, a pyridine ring, a pyrazine ring, a pyrimidine ring, and a pyridazine ring are preferable, and a benzene ring, a pyridine ring, and a pyrazine ring are more preferable. A benzene ring and a pyridine ring are still more preferable, and a pyridine ring is particularly preferable. The aromatic ring formed with the group of atoms represented by Z^{B2} may form a condensed ring with another ring, and may have a substituent. Preferable examples of the substituent include an alkyl group, an alkenyl group, an alkynyl group, an aryl group, an amino group, an alkoxyl group, an aryloxyl group, an acyl group, an alkoxycarbonyl group, an aryloxycarbonyl group, an acyloxyl group, an acylamino group, an alkoxycarbonylamino group, an aryloxycarbonylamino group, a sulfonylamino group, a sulfamoyl group, a carbamoyl group, an alkylthio group, an arylthio group, a sulfonyl group, a halogen atom, a cyano group, and a heterocyclic group. An alkyl group, an aryl group, an alkoxyl group, an aryloxyl group, a halogen atom, a cyano group, and a heterocyclic group are more preferable. An alkyl group, an aryl group, an alkoxyl group, an aryloxyl group, and a heteroaromatic group are still more preferable, and an alkyl group, an aryl group, an alkoxyl group, and a heteroaromatic group are particularly preferable.

n^{B2} represents an integer of 1 to 4 and preferably 2 to 3.

Of the compounds represented by the general formula (B-I), compounds represented by the following general formula (B-II) are more preferable.

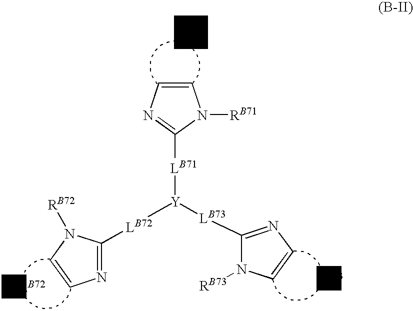

In the general formula (B-II), R^{B71}, R^{B72}, and R^{B73} each represent the same atom or group as those represented by R^{B2} in the general formula (B-I). The range of preferable examples of R^{B71}, R^{B72}, and R^{B73} is the same as in the case of R^{B2}.

Z^{B71}, Z^{B72}, and Z^{B73} each represent the same groups as those in the case of Z^{B2} in the general formula (B-I). The range of preferable examples of Z^{B71}, Z^{B72}, and Z^{B73} is the same as in the case of Z^{B2}.

L^{B71}, L^{B72}, and L^{B73} each represent a linking group, examples of which include the linking group described as the examples of the divalent linking group represented by L^{B} in the general formula (B-I). It is preferable that the linking group be a single bond, a divalent aromatic hydrocarbon cyclic group, a divalent heteroaromatic group, or a combination of those groups, and more preferably a single bond. The linking group represented by L^{B71}, L^{B72} and L^{B73} may have a substituent. Examples of the substituent include the same substituents as those in the case of L^{B} in the general formula (B-I).

Y represents a nitrogen atom, a 1,3,5-benzentriyl group, or a 2,4,6-triazintriyl group. 1,3,5-benzentriyl group may have a substituent at 2,4,6-positions. Examples of the substituent include an alkyl group, an aromatic hydrocarbon cyclic group, and a halogen atom.

Specific examples of the five-membered nitrogen-containing ring derivative represented by the general formula (B-I) and (B-II) are shown in the following, but limited to the compounds shown as the examples.

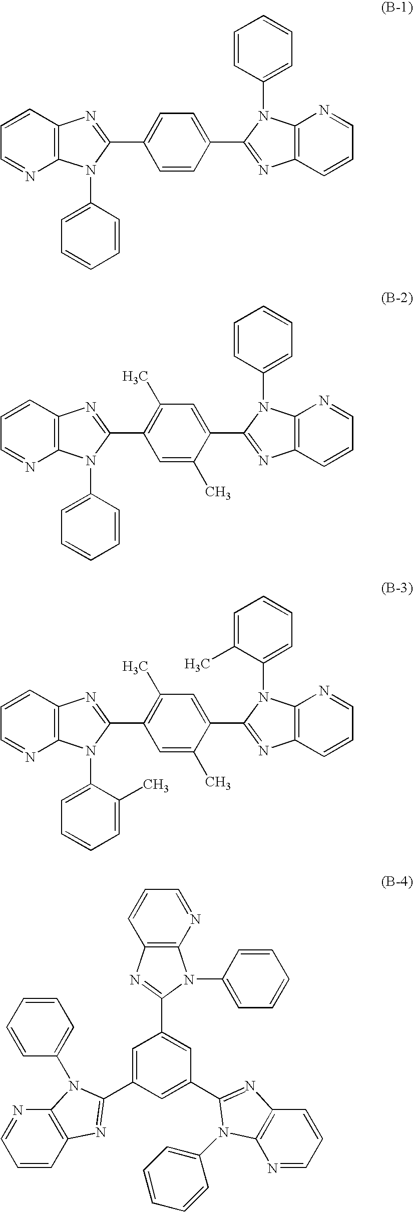

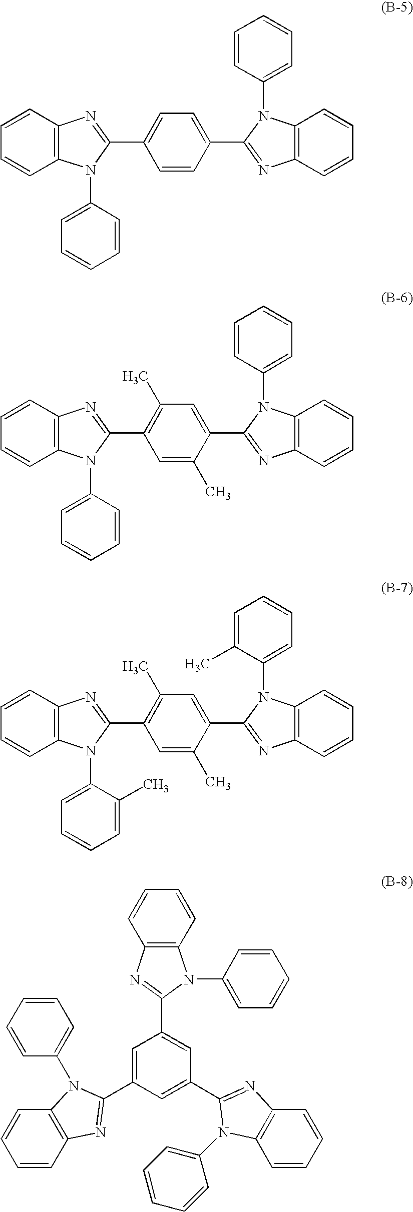

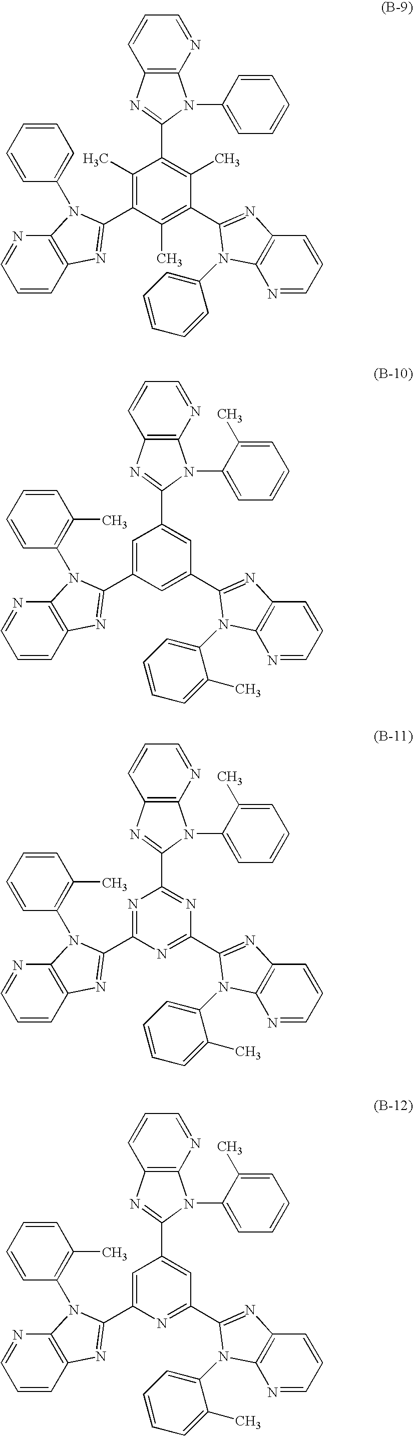

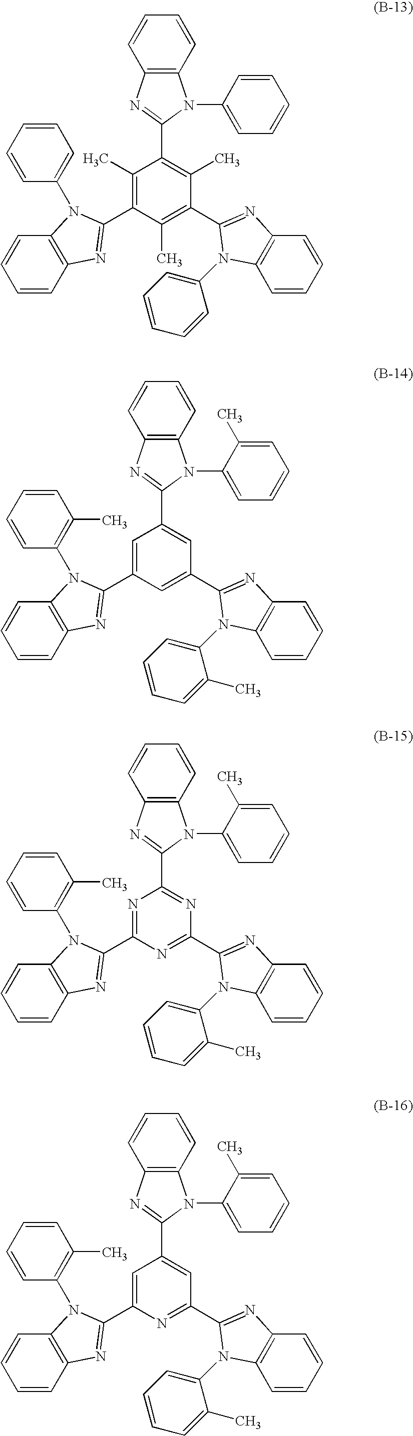

(Cz-)nA (C-I)

Cz(-A)m (C-II)

where Cz represents a substituted or unsubstituted carbazolyl group, an arylcarbazolyl group, or a carbazolylalkylene group, A represents a group formed of a site represented by the following general formula (A), and n and m each represent an integer of 1 to 3:

(M)p-(L)q-(M′)r (A)

where M and M′ each independently represent a nitrogen-containing heteroaromatic ring which is formed of 2 to 40 carbon atoms and may have a substituent, and M and M′ may be identical to or different from each other, L represents a single bond, an arylene group having 6 to 30 carbon atoms, a cycloalkylene group having 5 to 30 carbon atoms, or a heteroaromatic ring which has 2 to 30 carbon atoms and may have a substituent bonded to the ring, and p represents an integer of 0 to 2, q represents an integer of 1 or 2, and r represents an integer of 0 to 2 provided that p +r is equal to or larger than 1.

The bonding manner of each of the general formulae (C-I) and (C-II) is specifically represented as shown in the following table depending on a number represented by each of the parameters n and m.

TABLE 1

| n = m = 1 | n = 2 | n = 3 | m = 2 | m = 3 |
|---|---|---|---|---|
| Cz—A | Cz—A—Cz | 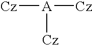 | A—Cz—A | 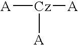 |

In addition, the bonding manner of the group represented by the general formula (A) is specifically any one of the forms shown in the items (1) to (16) in the following table depending on a number represented by each of the parameters p, q, and r.

TABLE 2

| No | p | q | r | Bonding manner |
|---|---|---|---|---|
| (1) | 0 | 1 | 1 | L—M′ |
| (2) | 0 | 1 | 2 | L—M′—M′, M′—L—M′ |
| (3) | 0 | 2 | 1 | L—L—M′, L—M′—L |
| (4) | 0 | 2 | 2 | 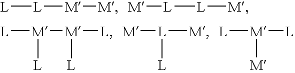 |
| (5) | 1 | 1 | 0 | Identical to (1) (M′ is exchanged for M) |
| (6) | 1 | 1 | 1 | M—L—M′ |
| (7) | 1 | 1 | 2 | 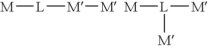 |
| (8) | 1 | 2 | 0 | Identical to (3) (M′ is exchanged for M) |
| (9) | 1 | 2 | 1 | M—L—L—M′, L—M—L—M′, M—L—M′—L |
| (10) | 1 | 2 | 2 | 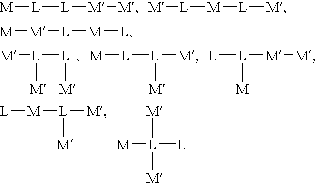 |
| (11) | 2 | 1 | 0 | Identical to (2) (M′ is exchanged for M) |
| (12) | 2 | 1 | 1 | Identical to (7) (M′ is exchanged for M) |

TABLE 3

| | | | | |
|---|---|---|---|---|
| (13) | 2 | 1 | 2 | 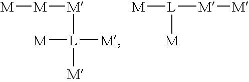 |
| (14) | 2 | 2 | 0 | Identical to (4) (M′ is exchanged for M) |
| (15) | 2 | 2 | 1 | Identical to (10) (M′ is exchanged for M) |
| (16) | 2 | 2 | 2 | 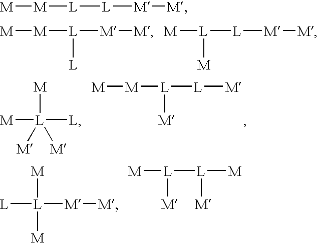 |

When Cz is bonded to A in each of the general formulae (C-I) and (C-II), Cz may be bonded to any one of M, L, and M′ representing A. For example, in Cz-A for m=n=1, in the case of p=q=r=1 (the item (6) in the table), A represents M-L-M′, so three bonding manners are available: Cz-M-L-M′, M-L(-Cz)-M′, and M-L-M′-Cz. In addition, similarly, for example, in Cz-A-Cz for n=2 in the general formula (C-1), in the case of p=q=1 and r=2 (the item (7) in the table), A represents M-L-M′-M′ or M-L(-M′)-M′, so the following bonding manners are available.

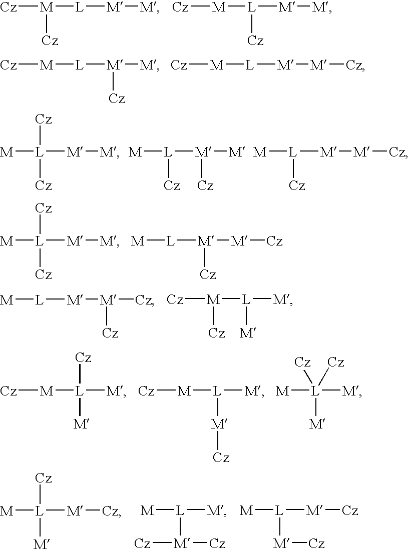

Specific examples of the structure represented by each of the general formulae (C-I) and (C-II) include the following structures. However, the structure is not limited to the examples.

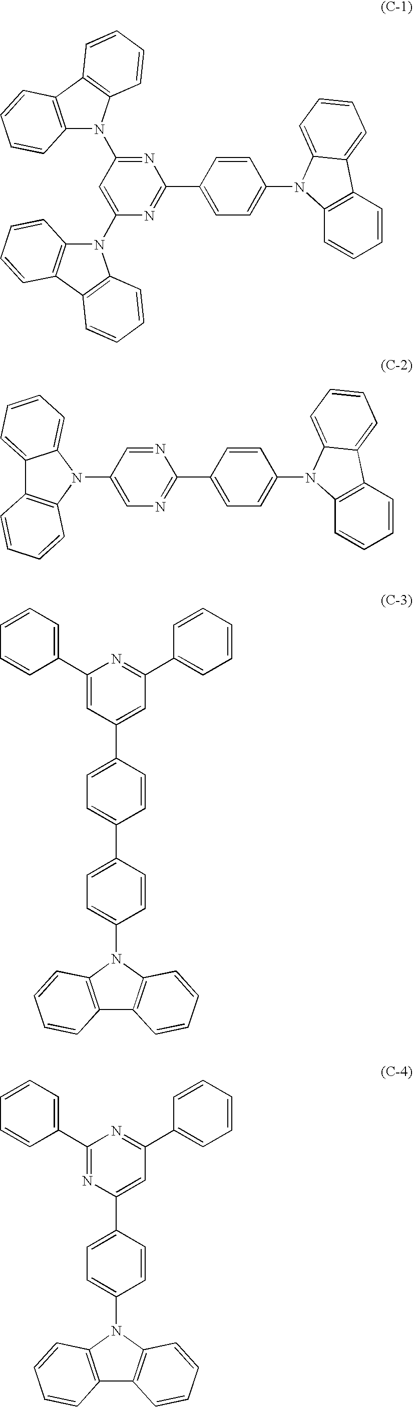

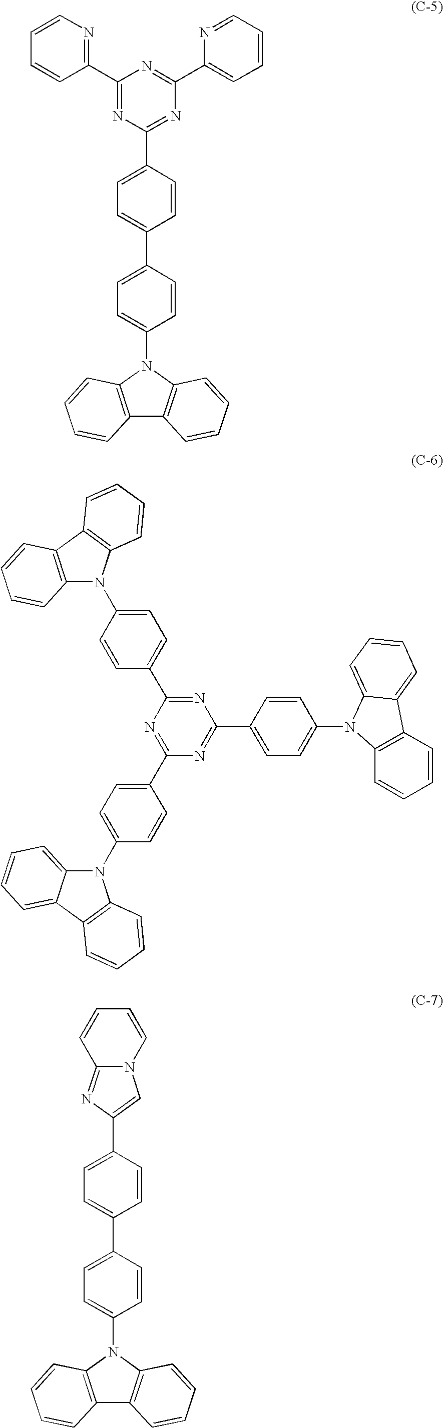

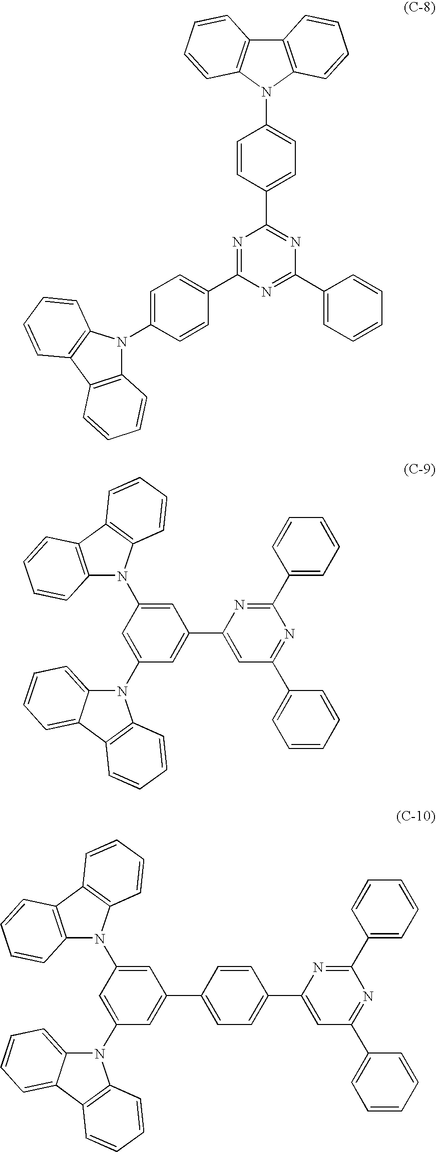

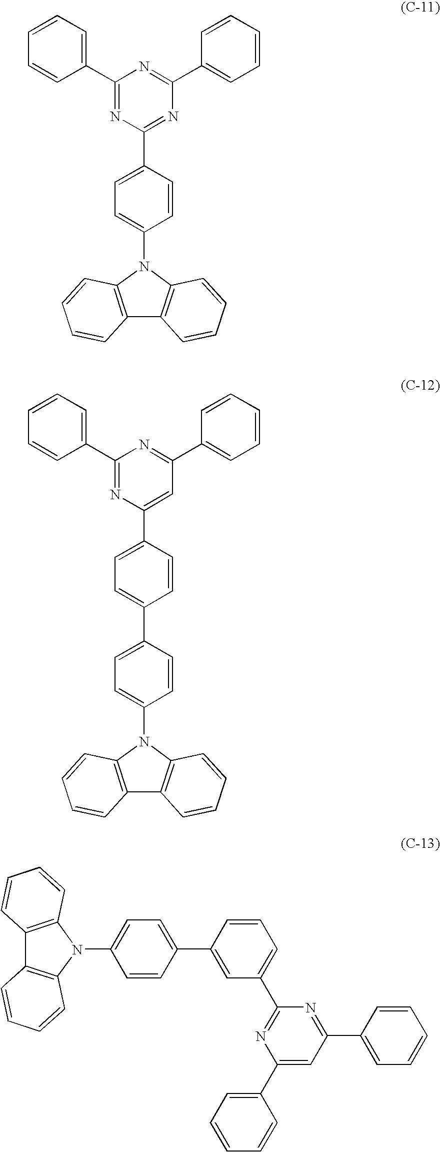

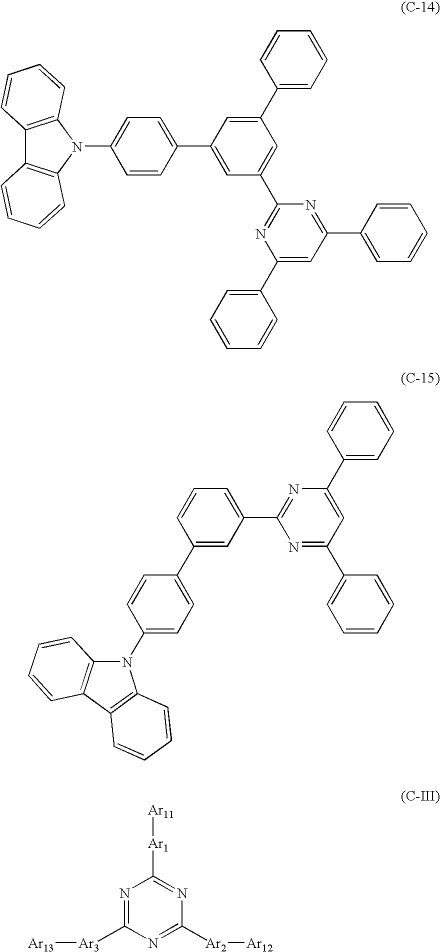

where Ar₁₁ to Ar₁₃ each represent a group similar to R^{B2} of the general formula (B-I), and specific examples of Ar₁₁ to Ar₁₃ include examples similar to those of R^{B2}, and Ar₁ to Ar₃ each represent a group obtained by making a group similar to R^{B2} of the general formula (B-I) divalent, and specific examples of Ar₁ to Ar₃ include examples obtained by making examples of R^{B2} divalent.

A specific example of the general formula (C-III) is shown below. However, the formula is not limited to the example.

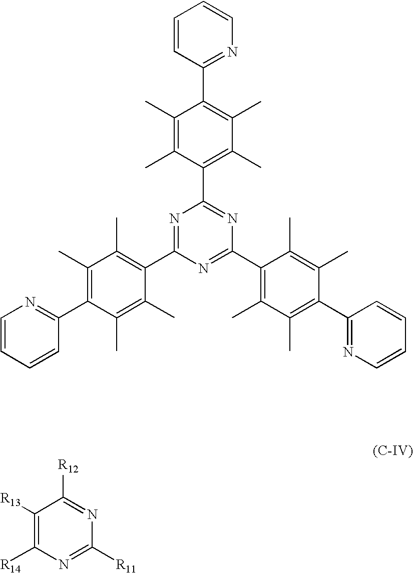

where R₁₁ to R₁₄ each represent a group similar to R^{B2} of the general formula (B-I), and specific examples of R₁₁ to R₁₄ include examples similar to those of R^{B2}.

Specific examples of the general formula (C-IV) are shown below. However, the formula is not limited to the examples.

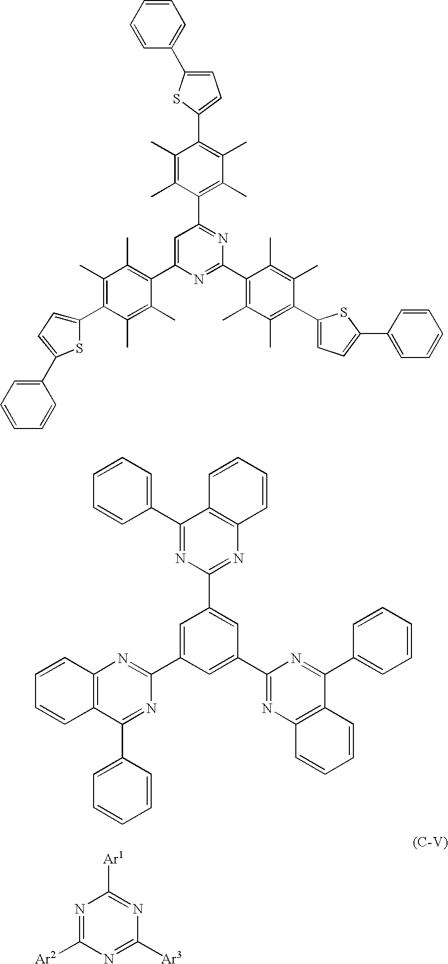

where Ar¹ to Ar³ each represent a group similar to R^{B2} of the general formula (B-I), and specific examples of Ar¹ to Ar³ include examples similar to those of R^{B2}.

A specific example of the general formula (C-V) is shown below. However, the formula is not limited to the example.

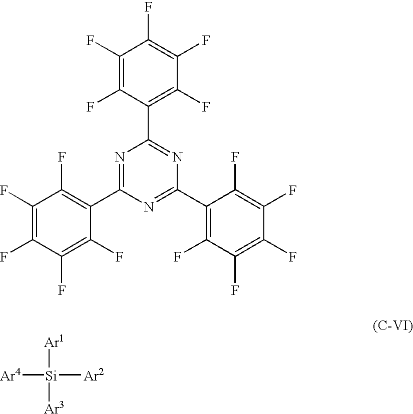

where Ar¹ to Ar⁴ each represent a group similar to R^{B2} of the general formula (B-I), and specific examples of Ar¹ to Ar⁴ include examples similar to those of R^{B2}.

A specific example of the general formula (C-VI) is shown below. However, the formula is not limited to the example.

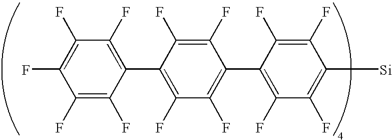

In addition, in the organic EL device of the present invention, an insulating or inorganic compound of an semi-conductor is preferably used as a substance constituting the electron injecting or transporting layer. When the electron injecting or transporting layer is formed of an insulator or a semiconductor, a current leak can be effectively prevented, and electron injecting property can be improved. It is preferable that at least one metal compound selected from the group consisting of alkali metal chalcogenides, alkaline earth metal chalcogenides, alkali metal halides, and alkaline earth metal halides be used as such the insulator. It is preferable that the electron injecting or transporting layer be formed of the above-mentioned alkali metal chalcogenide since the electron injecting property can be improved.

To be specific, preferable examples of the alkali metal chalcogenide include Li₂O, LiO, Na₂S, Na₂Se, and NaO. Preferable examples of the alkaline earth metal chalcogenide include CaO, BaO, SrO, BeO, BaS, and CaSe. Preferable examples of the alkali metal halide include LiF, NaF, KF, LiCl, KCl, and NaCl. Preferable examples of the alkaline earth metal halide include fluorides such as CaF₂, BaF₂, SrF₂, MgF₂, and BeF₂, and halides other than the fluorides.

Further, examples of the semiconductor for constituting the electron injecting or transporting layer include oxides, nitrides, and oxide nitrides containing at least one element selected from the group consisting of Ba, Ca, Sr, Yb, Al, Ga, In, Li, Na, Cd, Mg, Si, Ta, Sb, and Zn, which are used alone or in combination of two or more. It is preferable that the inorganic compound constituting the electron transporting layer be in the form of a fine crystalline or amorphous insulating thin film. When the electron transporting layer is formed of the above-mentioned insulating thin film, a more uniform thin film can be formed, and defective pixels such as dark spots can be decreased. Examples of the inorganic compound include the alkali metal chalcogenides, the alkaline earth metal chalcogenides, the alkali metal halides, and the alkaline earth metal halides which are described above.

Further, in the organic EL device of the present invention, at least one of the electron injecting layer and/or the electron transporting layer may contain a reducing dopant having a work function of 2.9 eV or less. The term “reducing dopant” as used herein refers to a compound that increases the efficiency with which an electron is injected.

In addition, in the present invention, a reducing dopant is preferably added to an interfacial region between the cathode and the organic thin film layer so that at least part of an organic layer in the interfacial region is reduced and turned into an anion. A preferable reducing dopant is at least one compound selected from the group consisting of an alkali metal, an oxide of an alkali earth metal, an alkali earth metal, a rare earth metal, an oxide of an alkali metal, a halide of an alkali metal, an oxide of an alkali earth metal, a halide of an alkali earth metal, an oxide or halide of a rare earth metal, an alkali metal complex, an alkali earth metal complex, and a rare earth metal complex. To be specific, a preferable reducing dopant is at least one alkali metal selected from the group consisting of Na (work function: 2.36 eV), K (work function: 2.28 eV), Rb (work function: 2.16 eV), and Cs (work function: 1.95 eV) or at least one alkali earth metal selected from the group consisting of Ca (work function: 2.9 eV), Sr (work function: 2.0 to 2.5 eV), and Ba (work function: 2.52 eV) ; a reducing dopant having a work function of 2.9 eV is particularly preferable. Of those, a more preferable reducing dopant is at least one alkali metal selected from the group consisting of K, Rb, and Cs, a still more preferable reducing dopant is Rb or Cs, and the most preferable reducing dopant is Cs. Those alkali metals each have a particularly high reducing ability. The addition of a relatively small amount of each of those alkali metals to a region into which an electron is injected can improve the emission luminance and lifetime of the organic EL device.

Preferable examples of the alkali earth metal oxide include BaO, SrO, CaO, BaₓSr₁₋ₓO (0<x<1) obtained by mixing BaO and SrO, and BaₓCa₁₋ₓO (0<x<1) obtained by mixing BaO and CaO. Examples of an alkali oxide or an alkali fluoride include LiF, Li₂O, and NaF. The alkali metal complex, the alkali earth metal complex, and the rare earth metal complex are not particularly limited as long as each of them contains as a metal ion, an alkali metal ion, an alkali earth metal ion, and a rare earth metal ion, respectively. In addition, examples of a ligand include, but not limited to, quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzoimidazole, hydroxybenzotriazole, hydroxy fluborane, bipyridyl, phenanthroline, phthalocyanine, porphyrin, cyclopentadiene, β-diketones, azomethines, and derivatives of them.

In addition, the reducing dopant is preferably formed into a layer shape or an island shape. The thickness of the reducing dopant to be used in a layer shape is preferably 0.05 to 8 nm.

A preferable approach to forming an electron injecting or transporting layer containing the reducing dopant is a method involving: depositing organic matter as a light emitting material or electron injecting material for forming the interfacial region simultaneously with the deposition of the reducing dopant by a resistance heating deposition method; and dispersing the reducing dopant in the organic matter. A molar concentration ratio between the reducing dopant to be dispersed and the organic matter is 100:1 to 1:100, or preferably 5:1 to 1:5. Upon formation of the reducing dopant into a layer shape, the light emitting material or the electron injecting material is formed into a layer shape to serve as an interfacial organic layer, and then the reducing dopant is deposited alone by the resistance heating deposition method to be formed into a layer shape having a thickness of preferably 0.5 nm to 15 nm. Upon formation of the reducing dopant into an island shape, the light emitting material or the electron injecting material is formed to serve as an interfacial organic layer, and then the reducing dopant is deposited alone by the resistance heating deposition method to be formed into an island shape having a thickness of preferably 0.05 to 1 nm.

The light emitting layer of the organic EL device of the present invention has: a function with which a hole can be injected from the anode or the hole injecting layer and an electron can be injected from the cathode or the electron injecting layer upon application of an electric field; a function of moving injected charge (the electron and the hole) with the force of the electric field; and a function with which a field for recombination between the electron and the hole is provided so that the recombination can lead to light emission. The light emitting layer of the organic EL device of the present invention preferably contains at least the transition metal complex compound of the present invention, and may contain a host material using the transition metal complex compound as a guest material. Examples of the host material include a host material having a carbazole skeleton, a host material having a diarylamine skeleton, a host material having a pyridine skeleton, a host material having a pyrazine skeleton, a host material having a triazine skeleton, and a host material having an arylsilane skeleton. The energy level of the lowest triplet excited state (Tl) of the host material is preferably larger than the Tl level of the guest material. The host material may be a low-molecular-weight compound, or may be a high-molecular-weight compound. In addition, a light emitting layer in which the host material is doped with a light emitting material such as the transition metal complex compound can be formed by, for example, the co-deposition of the host material and the light emitting material.

A method of forming each of the layers in the organic EL device of the present invention is not particularly limited. Various methods such as a vacuum deposition method, an LB method, a resistance heating deposition method, an electron beam method, a sputtering method, a molecular lamination method, a coating method (such as a spin coating method, a cast method, or a dip coating method), an ink-jet method, and a printing method can be employed. In the present invention, a coating method as an application method is preferable.

Further, the organic thin film layer containing the transition metal complex compound of the present invention can be formed in accordance with a conventionally known method such as the vacuum deposition method, the molecular beam epitaxy method (i.e., MBE method), or the coating method such as the dipping method, the spin coating method, the casting method, a bar coat method, and a roll coat method, each of which uses a solution with a substance dissolved in a solvent.

Each layer can be formed by the coating method, which involves: dissolving the transition metal complex compound of the present invention in a solvent to prepare an application liquid; applying the application liquid onto a desired layer (or electrode); and drying the liquid. The application liquid may contain a resin, and the resin may be in a dissolved state or in a dispersed state in the solvent. A disconjugate polymer (such as polyvinyl carbazole) or a conjugate polymer (such as a polyolefin-based polymer) can be used as the resin. To be specific, examples of the resin include polyvinyl chloride, polycarbonate, polystyrene, polymethyl methacrylate, polybutyl methacrylate, polyester, polysulfone, polyphenylene oxide, polybutadiene, poly(N-vinylcarbazole), a hydrocarbon resin, a ketone resin, a phenoxy resin, polyamide, ethyl cellulose, vinyl acetate, an ABS resin, polyurethane, a melamine resin, an unsaturated polyester resin, an alkyd resin, an epoxy resin, and a silicone resin.

In addition, the thickness of each organic layer of the organic EL device of the present invention is not particularly limited. In general, however, an excessively small thickness is apt to generate defects such as a pinhole, and an excessively large thickness requires a high applied voltage, thereby resulting in poor efficiency. Accordingly, the thickness is preferably in the range of several nanometers to 1 μm in ordinary cases.

### Examples

Next, the present invention will be described in more detail by way of examples.

### Example 1

### Synthesis of Transition Metal Complex Compound 1

### (i) Synthesis of Crosslinking Ligand Precursor (Compound a)

A crosslinking ligand precursor (Compound a) was synthesized through the following reaction process.

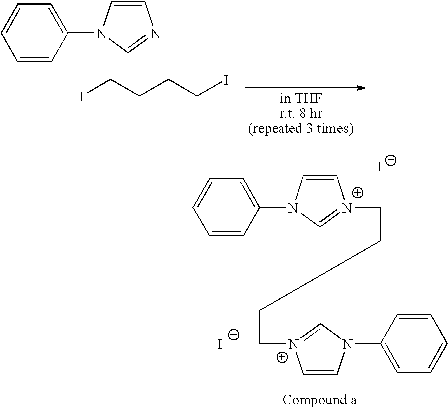

100 ml of tetrahydrofuran (THF) were added to 5.00 g of N-phenylimidazole (molecular weight 144.18, 34.7 mmol) and 5.05 g of 1,4-diiodobutane (molecular weight 309.92, 16.3 mmol), and the mixture was stirred at room temperature for 8 hours. The produced white solid (Compound a) was separated by filtration, and the filtrate was stirred for an additional 8 hours (the operation was repeated twice), whereby a total of 5.50 g of Compound a were obtained (56% yield).

(ii) Synthesis of Ligand Precursor (Compound b)

A ligand precursor (Compound b) was synthesized through the following reaction process.

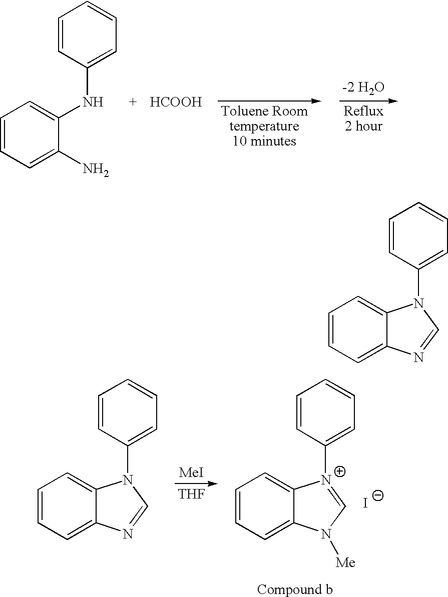

100 ml of toluene were added to 9.21 g of N-phenyl-o-phenylenediamine (molecular weight 184.24, 50 mmol), and then 4.60 g of formic acid (molecular weight 46.03, 100 mmol) were added to the mixture. The resultant mixture was stirred at room temperature, whereby a solid was immediately produced. After that, the resultant was subjected to a reaction under reflux for 2 hours. After the completion of the reaction, toluene was removed by distillation under reduced pressure, and a target product (N-phenylbenzimidazole) was purified by silica gel column chromatography (developing solvent: 95% of methylene chloride/5% of methanol, Rf value about 0.2). The target product was recovered in an amount of 5.60 g (molecular weight 194.24, 58% yield).

50 ml of tetrahydrofuran as a solvent were added to 1.60 g of N-phenylbenzimidazole (molecular weight 194.24, 8.24 mmol) thus obtained. Next, 2.34 g of methyl iodide (molecular weight 141.94, 16.5 mmol) were added to the mixture, and the whole was stirred at room temperature for 8 hours. The produced white solid (Compound b) was separated by filtration, and the filtrate was stirred for an additional 8 hours (the operation was repeated twice), whereby a total of 2.22 g of Compound b were obtained (molecular weight 336.18, 80% yield).

(iii) Synthesis of Transition Metal Complex Compound 1

Transition Metal Complex Compound 1 was synthesized through the following reaction process.

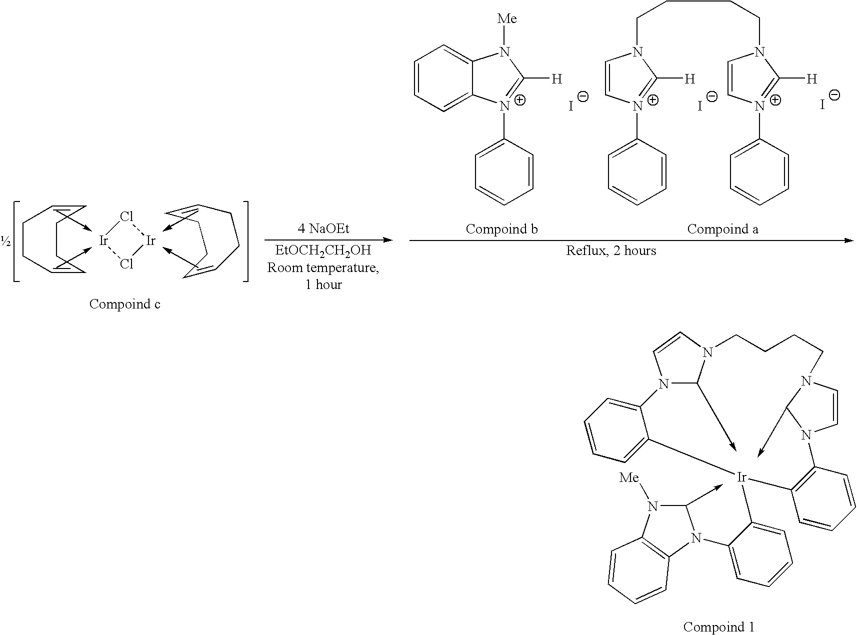

All reactions were performed in a stream of argon. 150 ml of 2-ethoxyethanol as a solvent were added to 0.672 g of Compound c (molecular weight 671.70, 1.00 mmol). Next, 0.626 g of sodium ethoxide (molecular weight 68.05, 9.20 mmol) was added to the mixture, and the whole was stirred at room temperature for 1 hour. 0.807 g of Compound b (molecular weight 336.18, 2.40 mmol) was added to the resultant mixture. Next, 1.44 g of Compound a (molecular weight 598.26, 2.40 mmol) were added to the resultant mixture, and the whole was subjected to a reaction under reflux for 2 hours. 2-ethoxyethanol as a solvent was removed from the resultant reaction liquid by distillation under reduced pressure and heat, and the remainder was cooled. After that, 100 ml of methylene chloride were added to the remainder, and a solid component was separated by filtration. Next, the filtrate was removed by distillation under reduced pressure, and the remainder was dissolved in 5 ml of methylene chloride. Subsequently, 100 ml of hexane were added to the solution to precipitate a solid. The solid component was purified by silica gel column chromatography (developing solvent: methylene chloride, Rf value about 0.8). As a result, 0.34 g of Compound 1 was obtained (molecular weight 739.89, 23% yield). Transition Metal Complex Compound 1 thus obtained was a mixture of two kinds of isomers.

The following items (1) to (4) of the resultant compound were measured.

### <Various Results of Measurement>

(1) FD-MS (field desorption mass spectrum) measurement: the maximum peak value was 740, and coincided with a calculated value (calculated value M⁺ (molecular ion peak)=740).

The FD-MS measurement (field desorption ionization mass spectrometry) was performed under the following conditions.
Device: HX 110 (manufactured by JEOL Ltd.)
Conditions: acceleration voltage 8 kV
   scan range m/z=50 to 1,500
   emitter kind carbon
   emitter current 0 mA→2 mA/min→40 mA (held for 10 minutes)

(2) ¹H-NMR (500 MHz) spectrum measurement: see FIG. 1 Device: DRX500 (manufactured by JEOL Ltd.) Measurement solvent: solvent CD₂Cl₂ (deuterated methylene chloride), reference 5.32 ppm

The structure of Compound 1 was identified from the results of the above measurements (1) and (2).

(3) ¹³C-NMR (125 MHz) spectrum measurement: see a first table Device: DRX500 (manufactured by JEOL Ltd.) Measurement solvent: solvent CD₂Cl₂ (deuterated methylene chloride), reference 54.0 ppm

A total of 72 kinds of peaks were observed in ¹³C-NMR (see the first table). The foregoing means that Compound 1 having 36 kinds of carbon in different environments was obtained in the form of a mixture of two kinds of isomers. Of the peaks, a total of eight peaks originating from a butylene chain crosslinking site were observed, and were classified into four kinds at α-position of nitrogen (52.63 ppm, 50.88 ppm, 48.56 ppm, 48.34 ppm) and four kinds at β-position of nitrogen (30.46 ppm, 29.96 ppm, 27.01 ppm, 25.33 ppm). In addition, a total of six kinds of carbene carbon were observed, and were classified into the kinds of carbene carbon of an imidazol-2-ylidene site (177.42 ppm, 175.77 ppm, 175.07 ppm, 173.22 ppm) and two kinds of carbene carbon of a benzimidazol-2-ylidene site (190.38 ppm, 185.84 ppm).

TABLE 4
First table

| No | 13C-NMR(ppm) |
|---|---|
| #1 | 25.33 |
| #2 | 27.01 |
| #3 | 29.96 |
| #4 | 30.46 |
| #5 | 33.18 |
| #6 | 33.48 |
| #7 | 48.34 |
| #8 | 48.56 |
| #9 | 50.88 |
| #10 | 52.63 |
| #11 | 109.91 |
| #12 | 110.05 |
| #13 | 110.77 |
| #14 | 110.84 |
| #15 | 111.01 |
| #16 | 111.20 |
| #17 | 111.40 |
| #18 | 111.45 |
| #19 | 111.95 |
| #20 | 112.04 |
| #21 | 114.41 |
| #22 | 114.58 |
| #23 | 116.02 |
| #24 | 116.36 |
| #25 | 120.19 |
| #26 | 120.39 |
| #27 | 120.45 |
| #28 | 120.57 |
| #29 | 120.64 |
| #30 | 120.82 |
| #31 | 120.95 |
| #32 | 121.05 |
| #33 | 121.09 |
| #34 | 121.19 |
| #35 | 122.04 |
| #36 | 122.04 |
| #37 | 122.87 |
| #38 | 122.96 |
| #39 | 124.02 |
| #40 | 124.20 |
| #41 | 125.02 |
| #42 | 125.29 |
| #43 | 125.50 |
| #44 | 125.52 |
| #45 | 133.00 |
| #46 | 133.47 |
| #47 | 136.76 |
| #48 | 137.49 |
| #49 | 137.59 |
| #50 | 137.79 |
| #51 | 138.51 |
| #52 | 138.54 |
| #53 | 140.18 |
| #54 | 140.22 |
| #55 | 147.02 |
| #56 | 147.58 |
| #57 | 148.00 |
| #58 | 148.08 |
| #59 | 148.56 |
| #60 | 148.77 |
| #61 | 149.76 |
| #62 | 150.00 |
| #63 | 150.52 |
| #64 | 150.67 |
| #65 | 151.06 |
| #66 | 152.26 |
| #67 | 173.22 |
| #68 | 175.07 |
| #69 | 175.77 |
| #70 | 177.42 |
| #71 | 185.84 |
| #72 | 190.38 |

(4) Two-dimensional NMR (C-H COSY and H-H COSY) measurement:

The two-dimensional NMR (C-H COSY and H-H COSY) of a butylene chain site was measured, and chemical shift values for the two kinds of isomers were determined as described below.

### <Isomer 1>

NMR chemical shift value (in ppm unit)

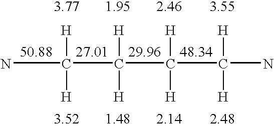

### <Isomer 2>

NMR chemical shift value (in ppm unit)

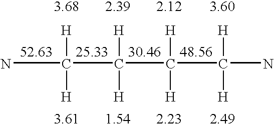

The identification of the structure of Compound 1 was attained by the results of the above measurements (1) to (4).

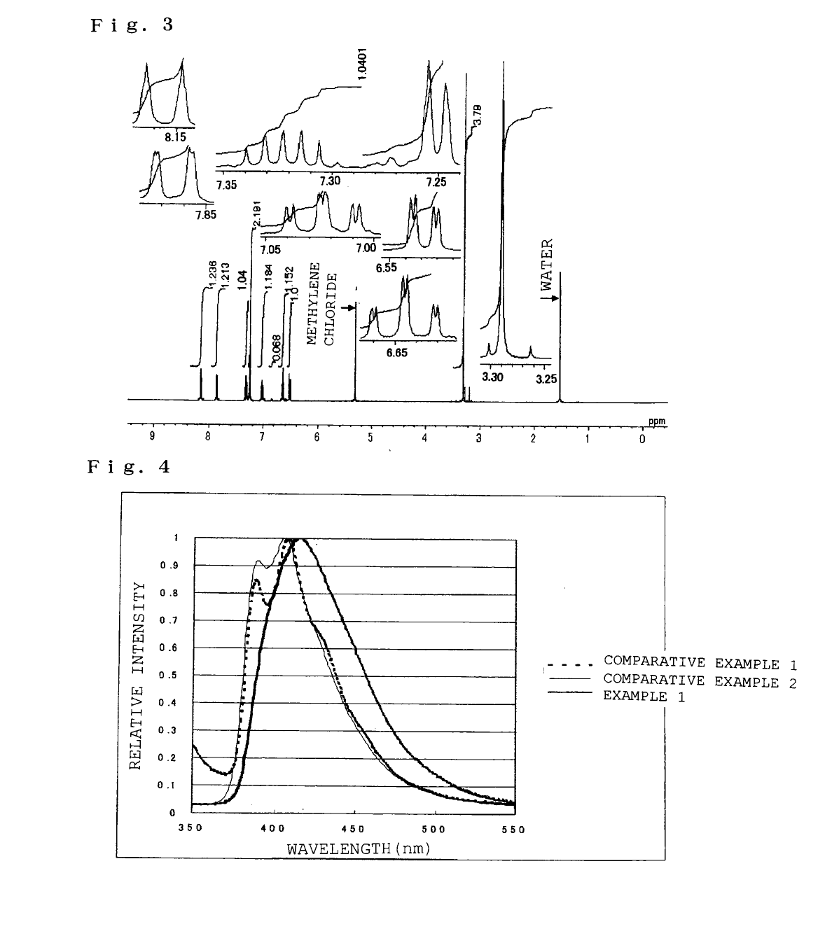

(5) Measurement of emission spectrum (room temperature): see FIG. 4 Device: F-4500 spectrofluorometer Measurement solvent: methylene chloride

FIG. 4 shows that light in an ultraviolent region to blue region was emitted in a solution state.

### Comparative Example 1

### Synthesis of Comparative Compound 1

### (i) Synthesis of Ligand (Compound d)

A ligand (Compound d) was synthesized through the following reaction process.

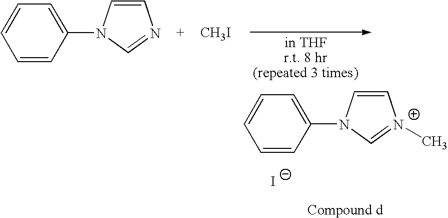

100 ml of tetrahydrofuran were added to 5.00 g of N-phenylimidazole (molecular weight 144.18, 34.7 mmol) and 9.85 g of methyl iodide (molecular weight 141.94, 69.4 mmol), and the mixture was stirred at room temperature for 8 hours. The produced white solid (Compound d) was separated by filtration, and the filtrate was stirred for an additional 8 hours (the operation was repeated twice), whereby a total of 9.93 g of Compound d were obtained (molecular weight 286.12, 95% yield).

(ii) Synthesis of Comparative Compound 1

Comparative Compound 1 was synthesized through the following reaction process.

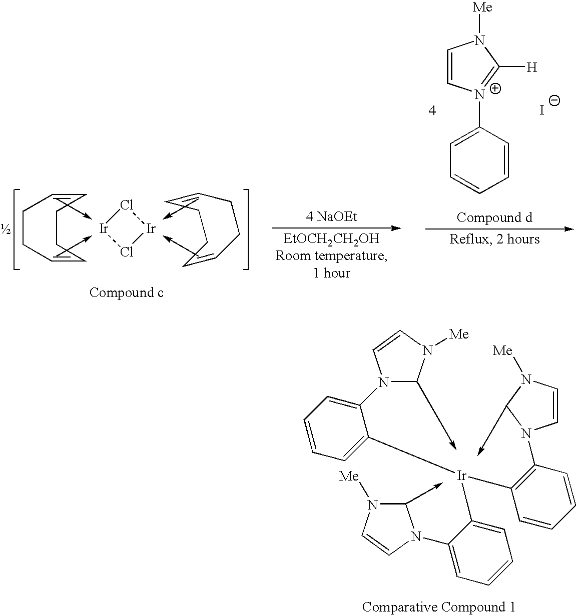

All reactions were performed in a stream of argon. 50 ml of 2-ethoxyethanol as a solvent were added to 0.672 g of Compound c (molecular weight 671.70, 1.00 mmol). Next, 0.626 g of sodium ethoxide (molecular weight 68.05, 9.20 mmol) was added to the mixture, and the whole was stirred at room temperature for 1 hour. 2.06 g of Compound d (molecular weight 286.11, 7.20 mmol) was added to the resultant mixture and the whole was subjected to a reaction under reflux for 2 hours. 2-ethoxyethanol as a solvent was removed from the resultant reaction liquid by distillation under reduced pressure and heat, and the remainder was cooled. After that, 100 ml of methylene chloride were added to the remainder, and a solid component was separated by filtration. Next, the filtrate was removed by distillation under reduced pressure, and the remainder was dissolved in 5 ml of methylene chloride. Subsequently, 100 ml of hexane were added to the solution to precipitate a solid. The solid component was purified by silica gel column chromatography (developing solvent: methylene chloride, Rf value about 0.8). As a result, 0.850 g of Comparative Compound 1 was obtained (molecular weight 663.79, 64% yield). Comparative Complex Compound 1 thus obtained was a mixture of two kinds of isomers (a facial body and a meridional body).

facial body: such a structure that, when three equivalent ligands are present in a transition metal complex compound formed of a regular octahedral structure, an angle formed between any two of the ligands is 90°, and the ligands are placed on the same side meridional body: such a structure that an angle formed between two of three equivalent ligands in a transition metal complex compound formed of a regular octahedral structure is 180°

The following measurements (1) to (3) of the resultant compound were performed under the same conditions as those of Example 1.

### <Various Results of Measurement>

(1) FD-MS measurement: the maximum peak value was 644, and coincided with a calculated value (calculated value M⁺ (molecular ion peak)=644).

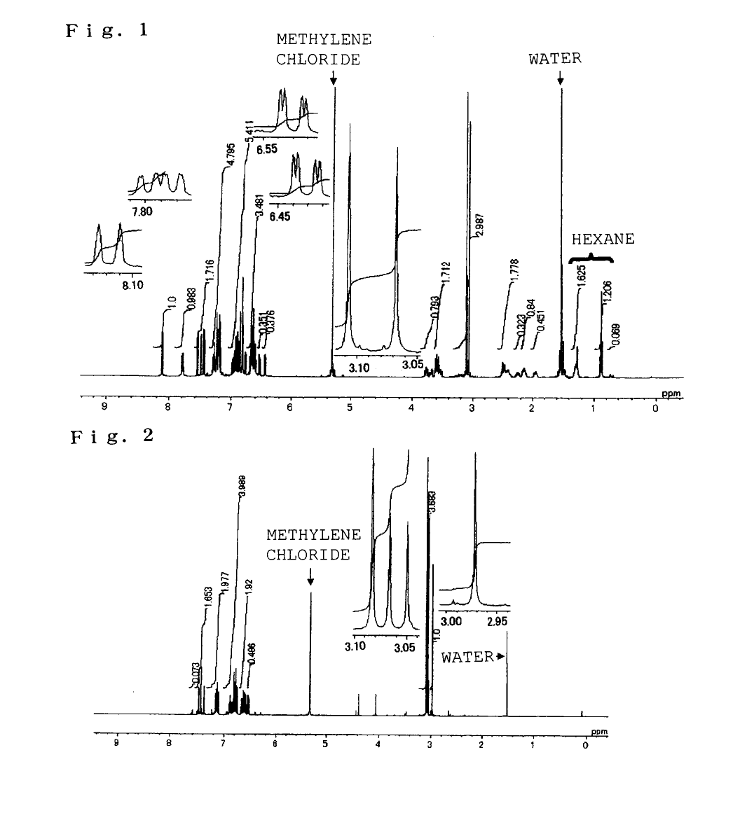

(2) ¹H-NMR (500 MHz) spectrum measurement: see FIG. 2

The structure of Comparative Compound 1 was identified from the results of the above measurements (1) and (2).

(3) Emission spectrum measurement (room temperature):see FIG. 4

### Comparative Example 2

### Synthesis of Comparative Compound 2

Comparative Compound 2 was synthesized through the following reaction process.

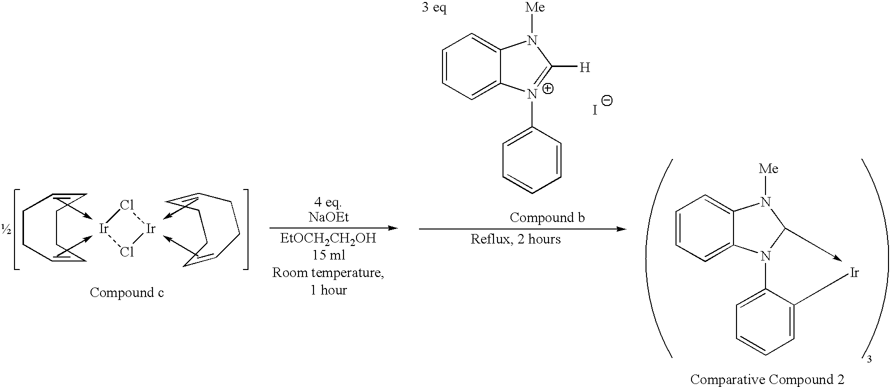

All reactions were performed in a stream of argon. 50 ml of 2-ethoxyethanol as a solvent were added to 0.302 g of Compound c (molecular weight 671.70, 0.45 mmol). Next, 0.306 g of sodium ethoxide (molecular weight 68.05, 4.50 mmol) was added to the mixture, and the whole was stirred at room temperature for 1 hour. 1.08 g of Compound b (molecular weight 300.14, 3.60 mmol) were added to the resultant mixture, and the whole was subjected to a reaction under reflux for 2 hours. A solid component was separated by filtration from the resultant reaction liquid, and was sufficiently washed with 2-ethoxyethanol, ethanol, and hexane, whereby 0.45 g of Comparative Compound 2 as a target product was obtained (molecular weight 813.97, 61% yield). Comparative Compound 2 thus obtained was a facial body.

The following measurements (1) to (3) of the resultant compound were performed under the same conditions as those of Example 1.

### <Various Results of Measurement>

(1) FD-MS measurement: the maximum peak value was 814, and coincided with a calculated value (calculated value M⁺ (molecular ion peak)=814).

(2) ¹H-NMR (500 MHz) spectrum measurement: see FIG. 3

The structure of Comparative Compound 2 was identified from the results of the above measurements (1) and (2).

(3) Emission spectrum measurement (room temperature): see FIG. 4

### Example 2

### Synthesis of Transition Metal Complex Compound 2

(i) Synthesis of Cross-Linking Group Site (Compound e)

1.25 g (molecular weight 336.89, 3.71 mmol) of the following Compound e was synthesized in accordance with the methods disclosed in documents (1974, J. Am. Chem. Soc., vol. 96, 16th edition, p 5189 and 1996, Bull. Chem. Soc. JAPAN vol. 69, p 3317).

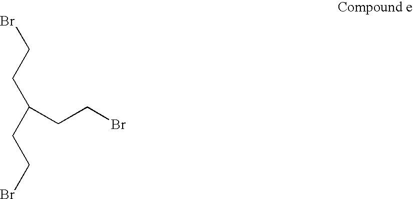

(ii) Synthesis of Ligand (Compound f)

A ligand (Compound f) was synthesized through the following reaction process.

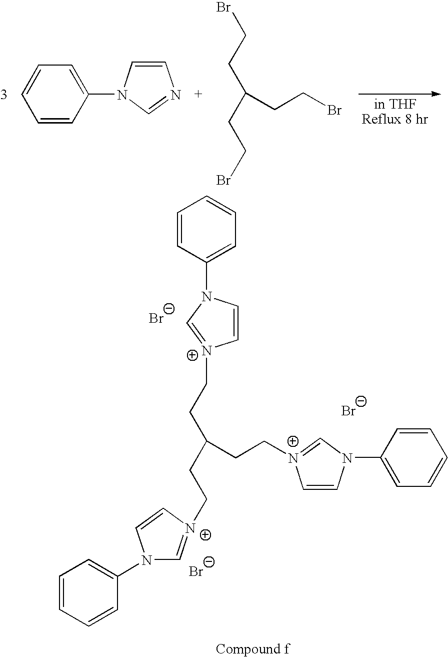

40 ml of tetrahydrofuran were added to 1.93 g of N-phenylimidazole (molecular weight 144.18, 13.4 mmol) and 1.25 g of Compound e (molecular weight 336.89, 3.71 mmol), and the mixture was refluxed for 8 hours. The produced white solid was separated by filtration, whereby 1.19 g of Compound f were obtained (molecular weight 769.41, 1.54 mmol, 32% yield).

(iii) Synthesis of Transition Metal Complex Compound 2

Transition Metal Complex Compound 2 was synthesized through the following reaction process.

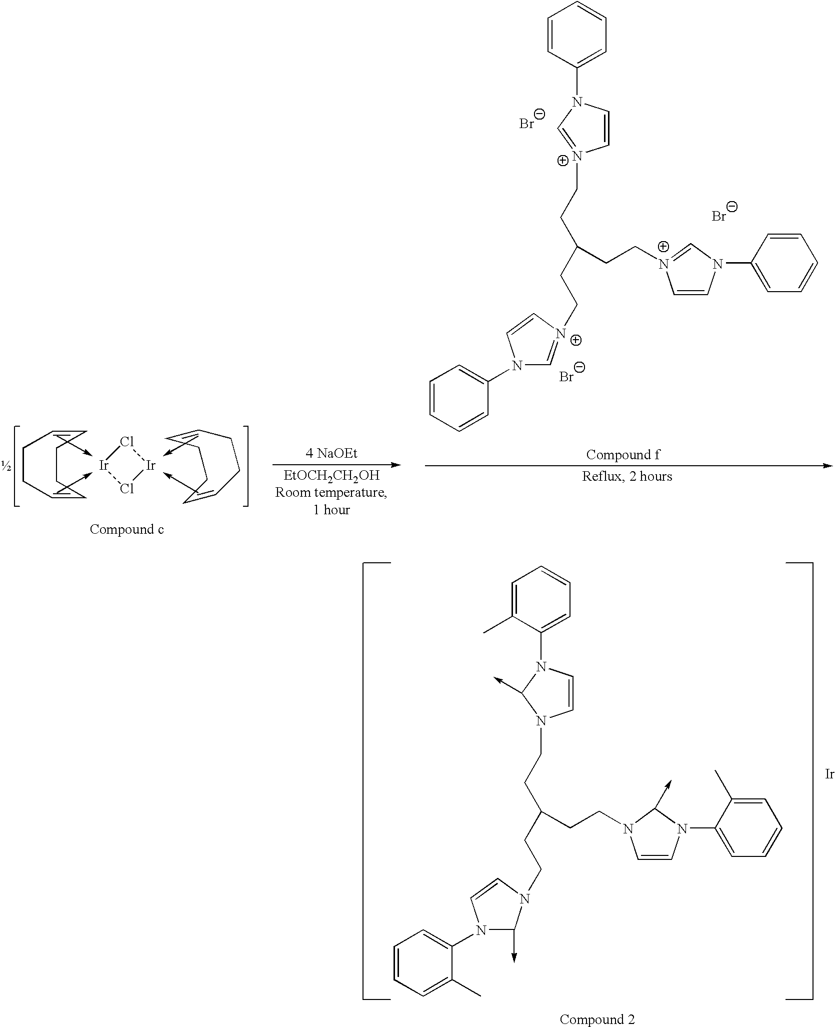

All reactions were performed in a stream of argon. 30 ml of 2-ethoxyethanol as a solvent were added to 0.517 g of Compound c (molecular weight 671.70, 0.77 mmol). Next, 0.419 g of sodium ethoxide (molecular weight 68.05, 6.16 mmol) was added to the mixture, and the whole was stirred at room temperature for 1 hour. 1.19 g of Compound f (molecular weight 769.41, 1.54 mmol) was added to the resultant mixture and the whole was subjected to a reaction under reflux for 2 hours. 2-ethoxyethanol as a solvent was removed from the resultant reaction liquid by distillation under reduced pressure and heat, and the remainder was cooled. After that, 60 ml of methylene chloride were added to the remainder, and a solid component was separated by filtration. Next, the filtrate was removed by distillation under reduced pressure, and the remainder was dissolved in 10 ml of methylene chloride. Subsequently, 50 ml of hexane were added to the solution to precipitate a solid. The solid component was purified by silica gel column chromatography (developing solvent: methylene chloride, Rf value about 0.8). As a result, 0. 069 g of Compound 2 was obtained (molecular weight 715.87, 0.096 mmol, 5% yield).

Compound 2 thus obtained was subjected to FD-MS. As a result, the measured maximum peak value of the compound was 716, and coincided with a calculated value (calculated value M⁺ (molecular ion peak)=716). In addition, as a result of the emission spectrum analysis of the compound at room temperature, the compound had local maximum emission peak wavelengths (λmax) of 388 nm and 407 nm.

### Example 3

### Synthesis of Transition Metal Complex Compound 3

Transition Metal Complex Compound 3 was synthesized through the following reaction process.

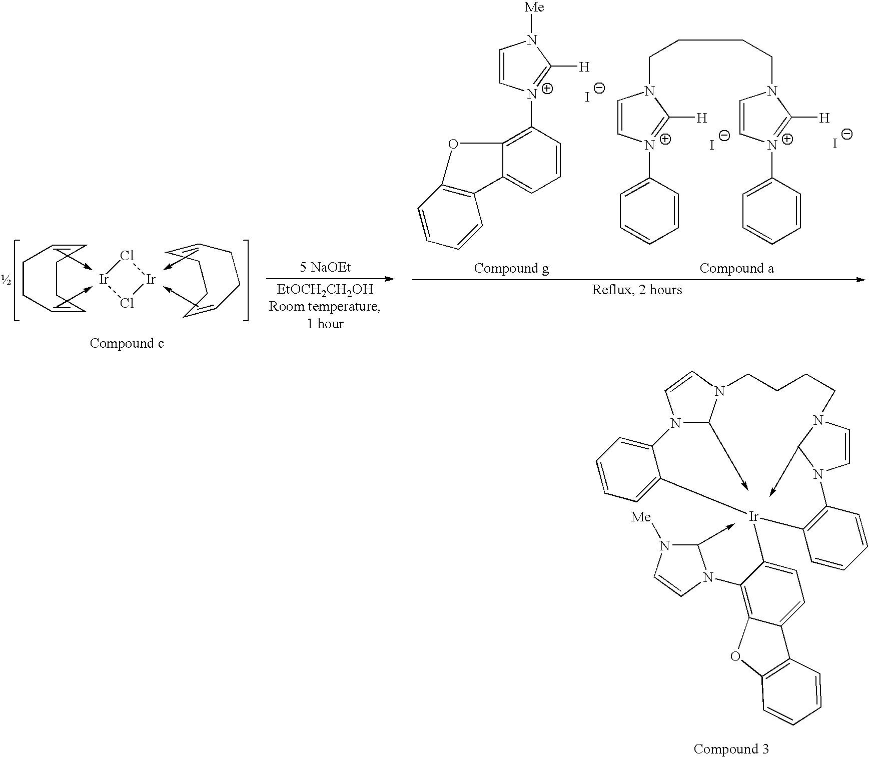

All reactions were performed in a stream of argon. 21 ml of 2-ethoxyethanol as a solvent were added to 0.140 g of Compound c (molecular weight 671.70, 0.209 mmol). Next, 0.142 g of sodium ethoxide (molecular weight 68.05, 2.09 mmol) was added to the mixture, and the whole was stirred at room temperature for 1 hour. 0.157 g of Compound g (molecular weight 376.19, 0.418 mmol) was added to the resultant mixture. Next, 0.250 g of Compound a (molecular weight 598.26, 0.418 mmol) were added to the resultant mixture, and the whole was subjected to a reaction under reflux for 2 hours. 2-ethoxyethanol as a solvent was removed from the resultant reaction liquid by distillation under reduced pressure and heat. The solid component was purified by silica gel column chromatography (developing solvent: methylene chloride, Rf value about 0.8). As a result, 0.013 g of Compound 3 was obtained (molecular weight 779.91, 4% yield).

Compound 3 thus obtained was subjected to FD-MS. As a result, the measured maximum peak value of the compound was 780, and coincided with a calculated value (calculated value M⁺=780). In addition, as a result of the emission spectrum analysis of the compound at room temperature, the compound had maximum emission peak wavelengths of 449 nm. Transition Metal Complex Compound 3 thus obtained was a mixture of two kinds of isomers (a facial body and a meridional body).

The above results of the measurement revealed that the linking (crosslinking) of the ligands of a complex was able to lengthen the luminous wavelength of the complex. The phenomenon is useful as a technology for adjusting the luminous wavelength to a desired one, and is useful particularly in leading a material having a luminous wavelength in an ultraviolet region to a material having a luminous wavelength in a blue color region. The utilization of the technology can provide a material for an organic electroluminescence device excellent in luminous efficiency and emitting blue light.

### INDUSTRIAL APPLICABILITY

As described above in detail, the transition metal complex compound of the present invention is extremely useful as a material for an organic EL device requested to have high luminous efficiency and a long emission lifetime, and to emit blue light. In addition, the transition metal complex compound of the present invention is a compound obtained by leading a conventional material having a luminous wavelength in an ultraviolet region to a material having a luminous wavelength in a blue color region as a result of the transformation of the molecular skeleton of the conventional material.

1. A transition metal complex compound comprising a ligand having three or more coordination sites formed of a combination of covalent bonds and/or coordinate bonds.

2. A transition metal complex compound comprising a ligand having four or more coordination sites formed of a combination of covalent bonds and/or coordinate bonds.

3. The transition metal complex compound according to claim 1, wherein the transition metal complex compound has a metal carbene bond.

4. The transition metal complex compound according to claim 3, wherein a metal of the transition metal complex compound comprises iridium.

5. A transition metal complex compound having a metal carbene bond represented by the following general formula (1): 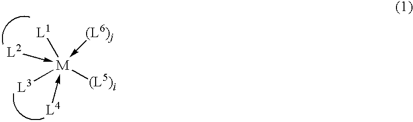
where:
a bond indicated by a solid line (—) means a covalent bond, a bond indicated by an arrow (→) means a coordinate bond, and at least one of L²→M and L⁴→M represents a metal carbene bond;
M represents a metal atom of iridium (Ir) or platinum (Pt);
L¹-L² and L³-L⁴ each represent a crosslinking bidentate ligand, L⁵ and L⁶ each independently represent a monodentate ligand, or are crosslinked with each other to represent a crosslinking bidentate ligand (L⁵-L⁶), and two ligands in at least one of combinations of L¹ and L³, L¹ and L⁴, L² and L³, L² and L⁴, L¹ and L⁵, L¹ and L⁶, L² and L⁵ , L² and L⁶, L³ and L⁵, L³ and L⁶, L⁴ and L⁵, and L⁴ and L⁶ are crosslinked with each other through a crosslinking group —Z¹— where Z¹ represents a divalent residue formed of a compound selected from an aromatic hydrocarbon, a heterocyclic group, an alkane, an alkene, and a compound obtained by substituting a carbon atom of each of the aromatic hydrocarbon, the heterocyclic group, the alkane, and the alkene by any one of a silicon atom, a nitrogen atom, a sulfur atom, an oxygen atom, a phosphorus atom, and a boron atom, or formed of a combination of two or more of these compounds, and the divalent residue may have a substituent;
when multiple crosslinking groups —Z¹-'s are present, the crosslinking groups may be identical to or different from each other;
i represents an integer of 0 to 1, 2+i represents a valence of the metal M, j represents an integer of 0 to 4, and, when i or j represents 2 or more, L⁵'s or L⁶'s may be identical to or different from each other, or adjacent ligands may be crosslinked with each other;
L¹ and L³ each independently represent a divalent aromatic hydrocarbon group which has 6 to 30 ring carbon atoms and may have a substituent, a divalent heterocyclic group which has 3 to 30 ring atoms and which may have a substituent, a divalent carboxyl-containing group which has 1 to 30 carbon atoms and may have a substituent, a divalent amino group- or hydroxyl group-containing hydrocarbon group which may have a substituent, a cycloalkylene group which has 3 to 50 ring carbon atoms and may have a substituent, an alkylene group which has 1 to 30 carbon atoms and may have a substituent, an alkenylene group which has 2 to 30 carbon atoms and may have a substituent, or an aralkylene group which has 7 to 40 carbon atoms and may have a substituent;
L² and L⁴ each independently represent a monovalent group which has carbene carbon and which may have a substituent, a monovalent aromatic hydrocarbon group which has 6 to 30 ring carbon atoms and may have a substituent, or a monovalent heterocyclic group which has 3 to 30 ring atoms and which may have a substituent, and at least one of L² and L⁴ represent a monovalent group which has carbene carbon and which may have a substituent;
L⁵ represents a monovalent aromatic hydrocarbon group which has 6 to 30 ring carbon atoms and may have a substituent, a monovalent heterocyclic group which has 3 to 30 ring atoms and which may have a substituent, a monovalent carboxyl group which has 1 to 30 carbon atoms and may have a substituent, a monovalent amino group- or hydroxyl group-containing hydrocarbon group which may have a substituent, a cycloalkyl group which has 3 to 50 ring carbon atoms and may have a substituent, an alkyl group which has 1 to 30 carbon atoms and may have a substituent, an alkenyl group which has 2 to 30 carbon atoms and may have a substituent, or an aralkyl group which has 7 to 40 carbon atoms and may have a substituent, and, when L⁵ and L⁶ are crosslinked with each other, L⁵ represents a divalent group of each of the groups; and
L⁶ represents a heterocyclic ring which has 3 to 30 ring carbon atoms and may have a substituent, a carboxylate which has 1 to 30 carbon atoms and may have a substituent, a carboxylic amide having 1 to 30 carbon atoms, an amine which may have a substituent, a phosphine which may have a substituent, an isonitrile which may have a substituent, an ether which has 1 to 30 carbon atoms and may have a substituent, a thioether which has 1 to 30 carbon atoms and may have a substituent, or a double bond-containing compound which has 1 to 30 carbon atoms and may have a substituent, and, when L⁵ and L⁶ are crosslinked with each other, L⁶ represents a monovalent group of each of the compounds.

6. The transition metal complex compound having a metal carbene bond according to claim 5, wherein the transition metal complex compound is represented by the following general formula (2): 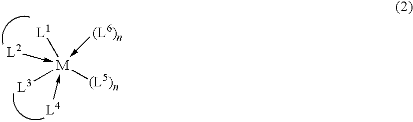
where:
a bond indicated by a solid line means a covalent bond, a bond indicated by an arrow means a coordinate bond, and at least one of L²→M and L⁴→M represents a metal carbene bond;
M, and L¹ to L⁶ each have the same meaning as that described above;
L¹-L² and L³-L⁴ each represent a crosslinking bidentate ligand, L⁵ and L⁶ each independently represent a monodentate ligand, or are crosslinked with each other to represent a crosslinking bidentate ligand (L⁵-L⁶), and two ligands in at least one of combinations of L¹ and L³, L¹ and L⁴, L² and L³, L² and L⁴, L¹ and L⁵, L¹ and L⁶, L² and L⁵, L² and L⁶, L³ and L⁵, L³ and L⁶, L⁴ and L⁵, and L⁴ and L⁶ are crosslinked with each other through a crosslinking group —Z¹— where Z¹ has the same meaning as that described above; and
n represents an integer of 0 to 1, and 2+n represents a valence of the metal M.

7. The transition metal complex compound having a metal carbene bond according to claim 5, wherein (L¹-L²)M and/or (L³-L⁴)M each comprise/comprises a structure represented by the following general formula (3): 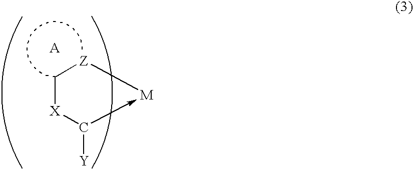
where:
a C (carbon atom)→M represents a metal carbene bond, and M represents a metal atom of Ir or Pt;
X represents a nitrogen-containing group (—NR¹—), a phosphorus-containing group (—PR¹—), oxygen (—O—), or sulfur (—S—), Y represents a nitrogen-containing group (—NR¹R²), a phosphorus-containing group (—PR¹), an oxygen-containing group (—OR¹), or a sulfur-containing group (—SR¹), and X and Y may be crosslinked with each other to form a ring structure;
R¹ and R² each independently represent a hydrogen atom, an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 50 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkoxy group which has 1 to 30 carbon atoms and may have a substituent, an aryloxy group which has 6 to 30 ring carbon atoms and may have a substituent, an alkylamino group which has 3 to 30 carbon atoms and may have a substituent, an arylamino group which has 6 to 30 carbon atoms and may have a substituent, an alkylsilyl group which has 3 to 30 carbon atoms and may have a substituent, an arylsilyl group which has 6 to 30 carbon atoms and may have a substituent, or a carboxyl-containing group which has 1 to 30 carbon atoms and may have a substituent, and R¹ and R² may be crosslinked with each other; and
Z represents an atom that forms a covalent bond with the metal M, the atom being a carbon, silicon, nitrogen, or phosphorus atom, and an A ring including Z represents an aromatic hydrocarbon group which has 3 to 40 ring carbon atoms and may have a substituent, or an aromatic heterocyclic group which has 3 to 40 ring atoms and which may have a substituent.

8. The transition metal complex compound having the metal carbene bond according to claim 5, wherein M represents Ir.

9. The transition metal complex compound having the metal carbene bond according to claim 5, wherein the transition metal complex compound is represented by the following general formula (4): 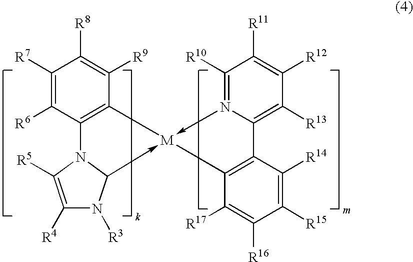
where:
a C (carbon atom)→M represents a metal carbene bond, and M represents a metal atom of Ir or Pt;
k represents an integer of 1 to 3, m represents an integer of 0 to 2, and k+m represents a valence of the metal M;
at least two of (substituted) N-phenyl-N—R³-imidazol-2-ylidene-C²,C^{2,}groups 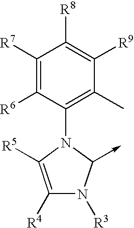
and (substituted) 2-phenylpyridine-N,C^{2,}groups 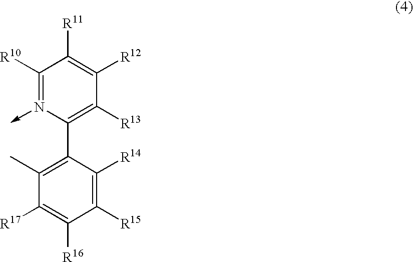
are crosslinked with each other through a crosslinking group —Z1- where Z1 has the same meaning as that described above;
R³ represents an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 30 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkylsilyl group which has 3 to 30 ring atoms and which may have a substituent, an arylsilyl group which has 6 to 30 carbon atoms and may have a substituent, or a carboxyl-containing group having 1 to 30 carbon atoms; and
R⁴ to R¹⁷ each independently represent a hydrogen atom, a halogen atom, a thiocyano group or a cyano group, a nitro group, a —S(═O)₂R¹ group or —S(═O)R¹ where R¹ has the same meaning as that described above, an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 30 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkoxy group which has 1 to 30 carbon atoms and may have a substituent, an aryloxy group which has 6 to 30 ring carbon atoms and may have a substituent, an alkylamino group which has 3 to 30 ring atoms and which may have a substituent, an alkylsilyl group which has 3 to 30 ring atoms and which may have a substituent, an arylsilyl group which has 6 to 30 carbon atoms and may have a substituent, or a carboxyl-containing group having 1 to 30 carbon atoms, and adjacent groups of R⁴ to R¹⁷ may be crosslinked with each other.

10. The transition metal complex compound having the metal carbene bond according to claim 9, wherein the transition metal complex compound is represented by the following general formula (5) wherein M represents Ir: 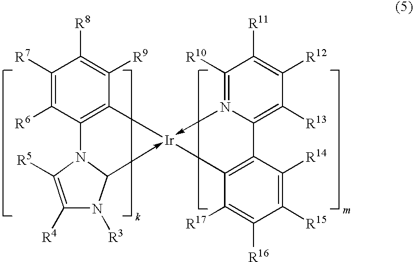
where:
a C (carbon atom)→Ir represents a metal carbene bond;
k, m, and R³ to R¹⁷ each have the same meaning as that described above; and
at least two of (substituted) N-phenyl-N′—R³-imidazol-2-ylidene-C²,C^{2,}groups and (substituted) 2-phenylpyridine-N,C^{2,}groups are crosslinked with each other through a crosslinking group —Z¹— where Z¹ has the same meaning as that described above.

11. A transition metal complex compound represented by the following general formula (6): 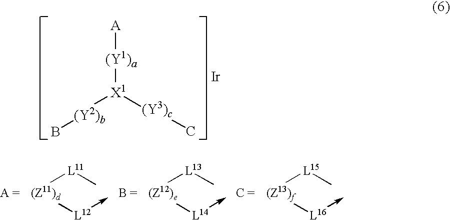
where:
A represents a crosslinking bidentate ligand group formed of L11-(Z¹¹)_{d}-L¹²,B represents a crosslinking bidentate ligand group formed of L¹³-(Z¹²)ₑ-L¹⁴, and C represents a crosslinking bidentate ligand group formed of L¹⁵-(Z¹³)_{f}-L¹⁶;
L¹¹-, L¹³-, and L¹⁵- each represent a covalent bond to iridium (Ir) (L¹¹-Ir, L¹³-Ir, and L¹⁵-Ir), and L¹²→, L¹⁴→, and L¹⁶→ each represent a coordinate bond to Ir (L¹²→Ir, L¹⁴→Ir, and L¹⁶→Ir);
X¹ represents a crosslinking group formed of a non-cyclic structure having 1 to 18 atoms, the crosslinking group being a trivalent residue of a compound formed of an atom selected from the group consisting of a hydrogen atom, a carbon atom, a silicon atom, a nitrogen atom, a sulfur atom, an oxygen atom, a phosphorus atom, and a boron atom, and the crosslinking group may have a substituent;
Y¹ represents a crosslinking group for bonding X¹ and A, Y² represents a crosslinking group for bonding X¹ and B, and Y³ represents a crosslinking group for bonding X¹ and C, and Y¹ is bonded to L¹¹, L¹², or Z¹¹, Y² is bonded to L¹³, L¹⁴, or Z¹², and Y³ is bonded to L¹⁵, L¹⁶, or Z¹³;
Y¹, Y², and Y³ each independently represent a divalent residue of a compound formed of an atom selected from the group consisting of a hydrogen atom, a carbon atom, a silicon atom, a nitrogen atom, a sulfur atom, an oxygen atom, a phosphorus atom, and a boron atom, and the divalent residue may have a substituent;
a, b, and c each independently represent an integer of 0 to 10, and, when a, b, or c represents 2 or more, multiple Y¹'s, multiple Y²'s, or multiple Y³'s may be identical to or different from each other;
Z¹¹ represents a crosslinking group for bonding L¹¹ and L¹², Z¹² represents a crosslinking group for bonding L¹³ and L¹⁴, and Z¹³ represents a crosslinking group for bonding L¹⁵ and L¹⁶, and Z¹¹, Z¹², and Z¹³ each independently represent a divalent residue of a compound formed of an atom selected from the group consisting of a hydrogen atom, a carbon atom, a silicon atom, a nitrogen atom, a sulfur atom, an oxygen atom, a phosphorus atom, and a boron atom, and the divalent residue may have a substituent;
when Z¹¹ is directly bonded to Y¹, when Z¹² is directly bonded to Y², or when Z¹³ is directly bonded to Y³, Z¹¹, Z¹², and Z¹³ each represent a corresponding trivalent group;
d, e, and f each independently represent an integer of 0 to 10, and, when d, e, or f represents 2 or more, multiple Z¹¹'s, multiple Z¹²'s, or multiple Z¹³'s may be identical to or different from each other;
L¹¹, L¹³, and L¹⁵ each independently represent a divalent aromatic hydrocarbon group which has 6 to 30 ring carbon atoms and may have a substituent, a divalent heterocyclic group which has 3 to 30 ring atoms and which may have a substituent, a divalent carboxyl-containing group which has 1 to 30 carbon atoms and may have a substituent, a divalent amino group- or hydroxyl group-containing hydrocarbon group which may have a substituent, a cycloalkylene group which has 3 to 50 ring carbon atoms and may have a substituent, an alkylene group which has 1 to 30 carbon atoms and may have a substituent, an alkenylene group which has 2 to 30 carbon atoms and may have a substituent, or an aralkylene group which has 7 to 40 carbon atoms and may have a substituent, and, when L¹¹ is directly bonded to Y¹, when L¹³ is directly bonded to Y², or when L¹⁵ is directly bonded to Y³, L¹¹, L¹³, and L¹⁵ each represent a corresponding trivalent group; and
L¹², L¹⁴, and L¹⁶ each independently represent a monovalent group which has carbene carbon and which may have a substituent, or a monovalent heterocyclic group which has 3 to 30 ring atoms and which may have a substituent, and, when L¹² is directly bonded to Y¹, when L¹⁴ is directly bonded to Y², or when L¹⁶ is directly bonded to Y³, L¹², L¹⁴, and L¹⁶ each represent a corresponding divalent group.

12. The transition metal complex compound according to claim 11, wherein the crosslinking group X¹ is formed of any one of the following structures: 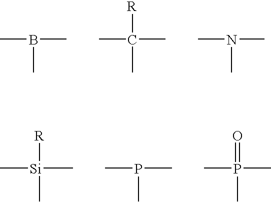
where R represents a hydrogen atom, an alkyl group which has 1 to 30 carbon atoms and may have a substituent, a halogenated alkyl group which has 1 to 30 carbon atoms and may have a substituent, an aromatic hydrocarbon group which has 6 to 30 ring carbon atoms and may have a substituent, a cycloalkyl group which has 3 to 50 ring carbon atoms and may have a substituent, an aralkyl group which has 7 to 40 carbon atoms and may have a substituent, an alkenyl group which has 2 to 30 carbon atoms and may have a substituent, a heterocyclic group which has 3 to 30 ring atoms and which may have a substituent, an alkoxy group which has 1 to 30 carbon atoms and may have a substituent, an aryloxy group which has 6 to 30 ring carbon atoms and may have a substituent, an alkylamino group which has 3 to 30 carbon atoms and may have a substituent, an arylamino group which has 6 to 30 carbon atoms and may have a substituent, an alkylsilyl group which has 3 to 30 carbon atoms and may have a substituent, an arylsilyl group which has 6 to 30 carbon atoms and may have a substituent, or a carboxyl-containing group which has 1 to 30 carbon atoms and may have a substituent.

13. The transition metal complex compound according to claim 11, wherein the crosslinking group X¹ is formed of any one of the following structures: 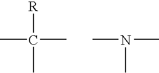
where R has the same meaning as that described above.

14. The transition metal complex compound according to claim 11, wherein the crosslinking group X¹ is formed of the following structure: 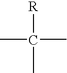
where R has the same meaning as that described above.

15. The transition metal complex compound according to claim 11, wherein a total weight of atoms of which the following crosslinking site (7) in the general formula (6) is formed is 200 or less.

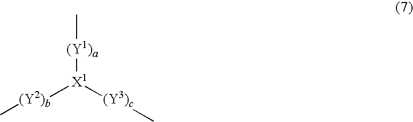

16. The transition metal complex compound according to claim 15, wherein the total weight of the atoms of which the crosslinking site (7) is formed is 100 or less.

17. An organic electroluminescence device comprising an organic thin film layer formed of one or more layers including at least a light emitting layer, the organic thin film layer being interposed between an anode and a cathode, wherein at least one layer of the organic thin film layer contains the transition metal complex compound according to claim 1.

18. An organic electroluminescence device comprising an organic thin film layer formed of one or more layers including at least a light emitting layer, the organic thin film layer being interposed between an anode and a cathode, wherein the light emitting layer contains the transition metal complex compound according to claim 1, as a light emitting material.

19. An organic electroluminescence device comprising an organic thin film layer formed of one or more layers including at least a light emitting layer, the organic thin film layer being interposed between an anode and a cathode, wherein the light emitting layer contains the transition metal complex compound according to claim 1, as a dopant.

20. An organic electroluminescence device according to claim 17, further comprising: an electron injecting layer and/or an electron transporting layer placed between the light emitting layer and the cathode; wherein the electron injecting layer and/or the electron transporting layer each contain/contains a n-electron-deficient, nitrogen-containing heterocyclic derivative as a main component.

21. An organic electroluminescence device according to claim 17, further comprising a reducing dopant added to an interfacial region between the cathode and the organic thin film layer.

22. An organic electroluminescence device comprising an organic thin film layer formed of one or more layers including at least a light emitting layer, the organic thin film layer being interposed between an anode and a cathode, wherein at least one layer of the organic thin film layer contains a transition metal complex compound comprising a ligand having three or more coordination sites formed of a combination of covalent bonds and/or coordinate bonds, and
wherein the transition metal complex compound comprises the transition metal complex compound represented by the general formula (4) according to claim 9.

23. An organic electroluminescence device comprising an organic thin film layer formed of one or more layers including at least a light emitting layer, the organic thin film layer being interposed between an anode and a cathode, wherein at least one layer of the organic thin film layer contains a transition metal complex compound comprising a ligand having three or more coordination sites formed of a combination of covalent bonds and/or coordinate bonds, and
wherein the transition metal complex compound comprises the transition metal complex compound represented by the general formula (5) according to claim 10.
